(19) United States
(12) Patent Application Publication
(10) Pub. No.: US 2025/0366366 A1
(43) Pub. Date: Nov. 27, 2025

(54) ORGANIC ELECTRONIC ELEMENT AND AN ELECTRONIC DEVICE THEREOF

(71) Applicant: DUK SAN NEOLUX CO., LTD., Cheonan-si (KR)

(72) Inventors: Hyeng Gun SONG, Cheonan-si (KR); Dong Hyun KIM, Cheonan-si (KR); Hyung Dong LEE, Cheonan-si (KR)

(73) Assignee: DUK SAN NEOLUX CO., LTD., Cheonan-si (KR)

(21) Appl. No.: 19/212,199

(22) Filed: May 19, 2025

(30) Foreign Application Priority Data
May 22, 2024 (KR) 10-2024-0066712

(51) Int. Cl. H10K 85/60; H10K 50/11

(52) U.S. Cl. CPC H10K 85/636; H10K 85/633; H10K 50/11; H10K 85/615; H10K 85/626; H10K 85/655; H10K 85/6572; H10K 85/6574

(57) ABSTRACT

Provided is an organic electronic element comprising a first electrode; second electrode; and an organic material layer comprising an emitting layer formed between the first electrode and the second electrode; wherein the organic material layer comprises a hole transport layer formed between the first electrode and the emitting layer, and an emitting auxiliary layer formed between the hole transport layer and the emitting layer, and by controlling the amount of holes injected into the emitting layer, the driving voltage of the organic electronic element can be lowered and the emitting-efficiency and lifetime can be improved.

### BACKGROUND

### Technical Field

The present invention relates to an organic electronic element and an electronic device thereof.

### Background Art

In general, organic light emitting phenomenon refers to a phenomenon that converts electric energy into light energy by using an organic material. An organic electronic element using an organic light emitting phenomenon usually has a structure including an anode, a cathode, and an organic material layer interposed therebetween. Here, in order to increase the efficiency and stability of the organic electronic element, the organic material layer is often composed of a multi-layered structure composed of different materials, and for example, may include a hole injection layer, a hole transport layer, an emitting layer, an electron transport layer, an electron injection layer etc.

In general, electrons are transferred from the electron transport layer to the emitting layer, and holes are transferred from the hole transport layer to the emitting layer to generate excitons by recombination.

However, since the material used in the hole transport layer must have a low HOMO value, most of them have a low T1 value, which causes excitons generated in the emitting layer to diffused to the hole transport layer, resulting in charge unbalance within the emitting layer and causing light emission at the hole transport layer interface. To solve the problem of luminescence in such hole transport layers, organic electronic elements that form multiple hole transport layers or form an emitting-auxiliary layer between the hole transport layer and the emitting layer are being proposed.

By using an emitting-auxiliary layer, problems such as light emission in the hole transport layer and charge unbalance within the emitting layer can be solved. However, in order to achieve the goal of high brightness, hole injection and transport between the hole transport layer and the emitting-auxiliary layer or between the emitting-auxiliary layer and the emitting layer should be controlled, and in particular, the interaction between the hole transport layer and the emitting-auxiliary layer determine significant role.

In the design of the emitting-auxiliary layer inserted between the hole transport layer and the emitting layer in organic electronic elements, it is essential to reduce the device driving voltage and improve the Luminescence efficiency, power efficiency, color purity, and operating lifetime. Currently, organic electronic elements are susceptible to interface degradation caused by parasite excitons generated along the interface between the emitting-auxiliary layer and the emitting layer due to trapping of holes accumulated at the interface, which may lead to a reduction in the operating lifetime of the organic electronic element. Accordingly, comprehensive research into the suppression of interfacial excitons is required.

### DETAILED DESCRIPTION OF THE INVENTION

### Summary

The present invention aims to provide an organic electronic element comprising a compound capable of reducing the driving voltage of the element and improving the luminescence efficiency, color purity, stability and lifetime of the element, and an electronic device thereof

### Technical Solution

In one aspect, the organic electronic element according to the present invention provides an organic electronic element comprising a first electrode; second electrode; and an organic material layer comprising an emitting layer formed between the first electrode and the second electrode; wherein the organic material layer comprises a hole transport layer formed between the first electrode and the emitting layer, and an emitting-auxiliary layer formed between the hole transport layer and the emitting layer, and wherein the organic electronic element has capacitance characteristics satisfying Equation 2.

$${V}_{cmax} - {V}_{c ( 0.8 nF )} \leq 1.3 V \qquad [ Equation 2 ]$$

In another aspect, the present invention provides an electronic device comprising the organic electronic element.

### Effects of the Invention

The present invention can achieve high luminescence efficiency, low driving voltage, and high thermal stability of an element by controlling the amount of holes injected into an emitting layer, and can significantly improve the color purity and lifetime of the element.

### BRIEF DESCRIPTION OF THE DRAWINGS

FIG. 1 illustrates an example of an organic light emitting diode according to the present invention.

FIG. 2 shows the results of a capacitance measurement experiment of an organic electronic element according to one embodiment of the present invention.

FIG. 3 is a graph showing the lifetime of an organic electronic element according to the V_{Cmax}-V_{C(0.8 nF)} value according to one embodiment of the present invention.

FIG. 4 is a graph showing the efficiency of an organic electronic element according to the V_{Cmax}-V_{C(0.8 nF)} value according to one embodiment of the present invention.

### DETAILED DESCRIPTION OF THE INVENTION

Hereinafter, some embodiments of the present invention will be described in detail. Further, in the following description of the present invention, a detailed description of known functions and configurations incorporated herein will be omitted when it may make the subject matter of the present invention rather unclear.

In addition, terms, such as first, second, A, B, (a), (b) or the like may be used herein when describing components of the present invention. Each of these terminologies is not used to define an essence, order or sequence of a corresponding component but used merely to distinguish the corresponding component from other component(s). It should be noted that if a component is described as being “connected”, “coupled”, or “connected” to another component, the component may be directly connected or connected to the other component, but another component may be “connected”, “coupled” or “connected” between each component.

As used in the specification and the accompanying claims, unless otherwise stated, the following is the meaning of the term as follows.

Unless otherwise stated, the term “halo” or “halogen”, as used herein, includes fluorine(F), bromine(Br), chlorine(Cl), or iodine(I).

Unless otherwise stated, the term “alkyl” or “alkyl group”, as used herein, has a single bond of 1 to 60 carbon atoms, 1 to 30 carbon atoms, 1 to 25 carbon atoms, 1 to 18 carbon atoms, or 1 to 12 carbon atoms, and means saturated aliphatic functional radicals including a linear alkyl group, a branched chain alkyl group, a cycloalkyl group (alicyclic), an cycloalkyl group substituted with a alkyl or an alkyl group substituted with a cycloalkyl.

Unless otherwise stated, the term “alkenyl” or “alkynyl”, as used herein, has double or triple bonds of 2 to 60 carbon atoms, 2 to 30 carbon atoms, 2 to 25 carbon atoms, 2 to 18 carbon atoms, 2 to 12 carbon atoms, but is not limited thereto, and includes a linear or a branched chain group.

Unless otherwise stated, the term “cycloalkyl”, as used herein, means alkyl forming a ring having 3 to 60 carbon atoms, 3 to 30 carbon atoms, 3 to 25 carbon atoms, 3 to 18 carbon atoms, 3 to 12 carbon atoms, but is not limited thereto.

Unless otherwise stated, the term “alkoxyl group”, “alkoxy group” or “alkyloxy group”, as used herein, means an alkyl group bonded to oxygen radical, but is not limited thereto, and has 1 to 60 carbon atoms, 1 to 30 carbon atoms, 1 to 25 carbon atoms, 1 to 18 carbon atoms, or 1 to 12 carbon atoms.

Unless otherwise stated, the term “aryloxyl group” or “aryloxy group”, as used herein, means an aryl group bonded to oxygen radical, but is not limited thereto, and has 6 to 60 carbon atoms, 6 to 30 carbon atoms, 6 to 25 carbon atoms, 6 to 18 carbon atoms, or 6 to 12 carbon atoms.

Unless otherwise specified, the terms “aryl group” and “arylene group” used in the present invention have 6 to 60 carbon atoms, 6 to 30 carbon atoms, 6 to 25 carbon atoms, 6 to 18 carbon atoms, or 6 to 12 carbon atoms, respectively, but are not limited thereto. In the present invention, an aryl group or arylene group refers to an aromatic group of a single ring or multiple rings, and contain aromatic rings formed by bonding or reacting with adjacent substituents. For example, the aryl group may be a phenyl group, a biphenyl group, a fluorene group, or a spirofluorene group.

The prefix “aryl” or “ar” means a radical substituted with an aryl group. For example, an arylalkyl may be an alkyl substituted with an aryl, and an arylalkenyl may be an alkenyl substituted with aryl, and a radical substituted with an aryl has a number of carbon atoms as defined herein.

Also, when prefixes are named subsequently, it means that substituents are listed in the order described first. For example, an arylalkoxy means an alkoxy substituted with an aryl, an alkoxylcarbonyl means a carbonyl substituted with an alkoxyl, and an arylcarbonylalkenyl also means an alkenyl substituted with an arylcarbonyl, wherein the arylcarbonyl may be a carbonyl substituted with an aryl.

Unless otherwise stated, the term “heterocyclic group”, as used herein, contains one or more heteroatoms, but is not limited thereto, has 2 to 60 carbon atoms, 2 to 30 carbon atoms, 2 to 25 carbon atoms, 2 to 18 carbon atoms, 2 to 12 carbon atoms, and includes any one of a single ring or multiple ring, and may include heteroaliphatic ring and heteroaromatic ring. Also, the heterocyclic group may also be formed by bonding with an adjacent group.

Unless otherwise stated, the term “heteroatom”, as used herein, represents at least one of N, O, S, P, or Si.

Also, “heterocyclic group” refers to a single ring containing heteroatoms, a ring aggregate, multiple fused ring systems, spiro compounds, etc. Additionally, compounds containing heteroatom groups such as SO₂, P═O, etc., such as the compounds below, instead of carbon forming a ring, may also be included in the heterocyclic group. For example, “heterocyclic group” includes the following compound.

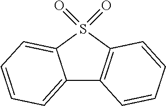 [SMILES: O=S1(=O)c2ccccc2-c2ccccc21]

The term “aliphatic ring group” used in the present invention refers to cyclic hydrocarbons excluding aromatic hydrocarbons, and includes single rings, ring aggregates, fused multiple ring systems, spiro compounds, etc., and means a ring having 3 to 60 carbon atoms, 3 to 30 carbon atoms, 3 to 25 carbon atoms, 3 to 18 carbon atoms, 3 to 12 carbon atoms, but is not limited thereto. For example, even when benzene, an aromatic ring, and cyclohexane, a non-aromatic ring, are fused, it is an aliphatic ring.

Unless otherwise stated, the term “fluorenyl group”, “fluorenylene group” or “fluorentriyl group” as used herein, means a monovalent, divalent or trivalent functional group, in which R, R′ and R″ are all hydrogen in the following structures, and the term “substituted fluorenyl group”, “substituted fluorenylene group” or “substituted fluorentriyl group” means that at least one of the substituents R, R′ and R″ is a substituent other than hydrogen, and include those in which R and R′ are bonded to each other to form a spiro compound together with the carbon to which they are bonded. In this specification, fluorenyl group, fluorenylene group, and fluorenetriyl group may all be referred to as fluorene groups, regardless of valence.

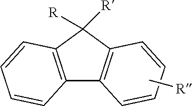

The term “spiro compound”, as used herein, has a ‘spiro union’, and a spiro union means a connection formed by 2 rings sharing only one atom. Wherein, the atoms shared between the 2 rings are called ‘spiro atoms’, and depending on the number of spiro atoms contained in a compound, they are called ‘monospiro-’, ‘dispiro-’, and ‘trispiro-’ compounds, respectively.

Unless otherwise stated, the term “aliphatic” as used herein means an aliphatic hydrocarbon having 1 to 60 carbon atoms, 1 to 30 carbon atoms, 1 to 25 carbon atoms, 1 to 18 carbon atoms or 1 to 12 carbon atoms, and “aliphatic ring” means an aliphatic hydrocarbon ring having 3 to 60 carbon atoms, 3 to 30 carbon atoms, 3 to 25 carbon atoms, 3 to 18 carbon atoms or 3 to 12 carbon atoms.

Unless otherwise stated, the term “ring”, as used herein, means an aliphatic ring having 3 to 60 carbon atoms, 3 to 30 carbon atoms, 3 to 25 carbon atoms, 3 to 18 carbon atoms or 3 to 12 carbon atoms; or an aromatic ring having 6 to 60 carbon atoms, 6 to 30 carbon atoms, 6 to 25 carbon atoms, 6 to 18 carbon atoms, or 6 to 12 carbon atoms; or a heterocyclic having 2 to 60 carbon atoms, 2 to 30 carbon atoms, 2 to 25 carbon atoms, 2 to 18 carbon atoms, 2 to 12 carbon atoms, or a fused ring formed by the combination thereof, and includes a saturated or unsaturated ring.

Other hetero compounds or hetero radicals other than the above-mentioned hetero compounds include, but are not limited thereto, one or more heteroatoms.

Also, unless expressly stated, as used herein, “substituted” in the term “substituted or unsubstituted” means substituted with one or more substituents selected from the group consisting of deuterium, halogen, an amino group, a nitrile group, a nitro group, a C₁-C₂₀ alkyl group, a C₁-C₂₀ alkoxyl group, a C₁-C₂₀ alkylamine group, a C₁-C₂₀ alkylthiopen group, a C₆-C₂₀ arylthiopen group, a C₂-C₂₀ alkenyl group, a C₂-C₂₀ alkynyl group, a C₃-C₂₀ cycloalkyl group, a C₆-C₂₀ aryl group, a C₆-C₂₀ aryl group substituted by deuterium, a C₈-C₂₀ arylalkenyl group, a silane group, a boron group, a germanium group, and a C₂-C₂₀ heterocyclic group, but is not limited to these substituents.

In this specification, the ‘group name’ corresponding to the aryl group, arylene group, heterocyclic group, etc., as examples of each symbol and its substituent, may be written as the ‘name of the group reflecting the valence’, but is written as the ‘parent compound name’. For example, in the case of ‘phenanthrene’, a type of aryl group, the name of the group may be written by distinguishing the valence, such as the monovalent ‘group’ is ‘phenanthryl’ and the divalent group is ‘phenanthrylene’, but may be written as ‘phenanthrene’, which is the name of the parent compound, regardless of the valence. Similarly, in the case of pyrimidine, it can be written as ‘pyrimidine’ regardless of the valence, or it can be written as the ‘name of the group’ of the valence, such as pyrimidineyl group in the case of monovalent group, pyrimidineylene in the case of divalent group, etc. Additionally, in this specification, when describing compound names or substituent names, numbers or alphabets indicating positions may be omitted. For example, pyrido[4,3-d]pyrimidine to pyridopyrimidine, benzofuro[2,3-d]pyrimidine to benzofuropyrimidine, 9,9-dimethyl-9H-fluorene can be described as dimethylfluorene, etc. Therefore, both benzo[g]quinoxaline and benzo[f]quinoxaline can be described as benzoquinoxaline.

Also, unless there is an explicit explanation, the formula used in the present invention is the same as the definition of the substituent by the exponent definition of the following formula.

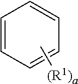

Here, when a is an integer of 0, the substituent R¹ is absent, when a is an integer of 1, the sole substituent R¹ is linked to any one of the carbon constituting the benzene ring, when a is an integer of 2 or 3, each is combined as follows, where R¹ may be the same or different from each other, when a is an integer of 4 to 6, it is bonded to the carbon of the benzene ring in a similar manner, while the indication of the hydrogen bonded to the carbon forming the benzene ring is omitted.

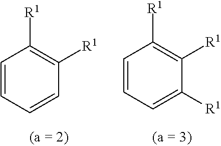

Unless otherwise expressly stated, the terms “ortho”, “meta”, and “para” used in the present invention refer to the substitution positions of all substituents, and the ortho position refers to a compound in which the position of the substituent is immediately adjacent, for example, when benzene is used, it means 1 or 2 position, and the meta position is the next substitution position of the neighbor substitution position, when benzene as an example stands for 1 or 3 position, and the para position is the next substitution position of the meta position, which means 1 and 4 position when benzene is taken as an example. A more detailed example of the substitution position is as follows, and it can be confirmed that the ortho-, and meta-position are substituted by non-linear type and para-positions are substituted by linear type.

### [Example of Ortho-Position]

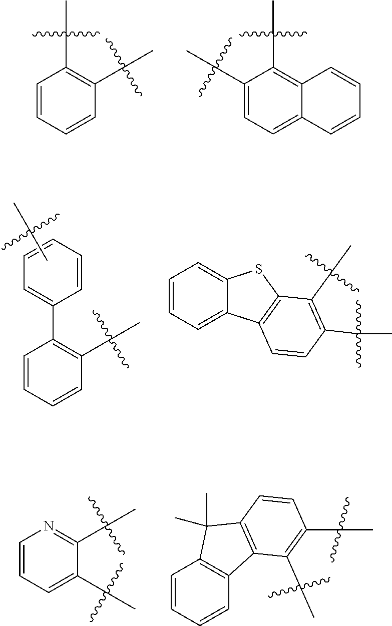

### [Example of Meta-Position]

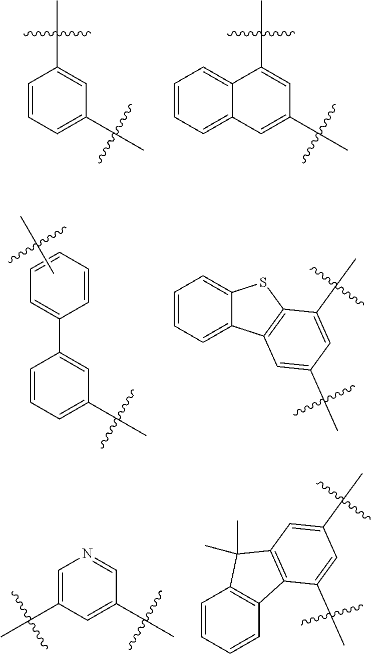

### [Example of Para-Position]

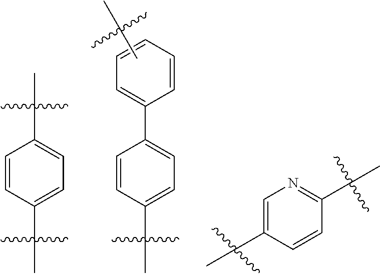

Hereinafter, an organic electronic element according to one aspect of the present invention will be described.

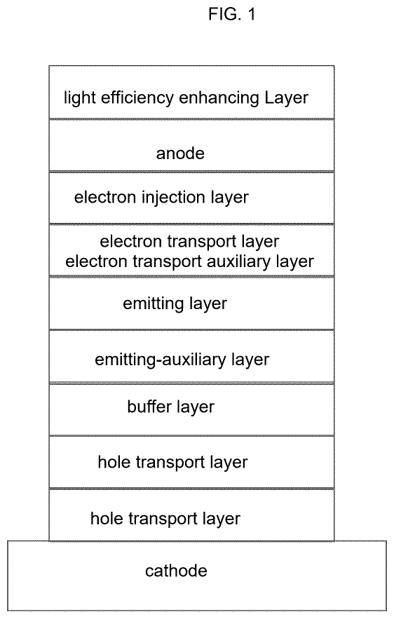

Referring to FIG. 1, an organic electronic element according to one embodiment of the present invention comprises a first electrode, a second electrode and an organic material layer formed between the first electrode and the second electrode formed on a substrate (not shown).

Wherein, the first electrode may be an anode (positive electrode), and the second electrode may be a cathode (negative electrode). In the case of an inverted organic electronic element, the first electrode may be a cathode, and the second electrode may be an anode.

The organic material layer comprises a hole transport layer, an emitting layer, an electron transport layer, and an emitting-auxiliary layer is formed between the hole transport layer and the emitting layer.

The organic material layer may comprise a hole injection layer between the first electrode and the hole transport layer, and an electron injection layer between the second electrode and the electron transport layer. Additionally, a buffer layer can be formed between the hole transport layer and the emitting-auxiliary layer.

Although not shown in FIG. 1, an electron transport auxiliary layer may be additionally formed between the emitting layer and the electron transport layer.

Also, the organic electronic element according to an embodiment of the present invention may further comprise a protective layer or a light efficiency enhancing layer. Wherein the light efficiency enhancing layer is formed on one of both surfaces of the first electrode that is not in contact with the organic material layer or on one of both surfaces of the second electrode that is not in contact with the organic material layer.

According to one embodiment of the present invention, the interaction between the hole transport layer and the emitting-auxiliary layer in the organic electronic element can be determined through capacitance measurement. When the difference between the voltage at which the capacitance reaches its maximum (hereinafter referred to as VCmax) and the initial voltage at which the capacitance begins to increase (hereinafter VC(0.8 nF) is large, hole accumulation between the hole transport layer and the auxiliary emission layer begins at a relatively low voltage.

As a result, the amount of holes trapped in both the auxiliary emission layer and the emitting layer increases. This leads to a charge unbalance between holes and electrons in the emitting layer.

This can cause non-radiative decay to be generated, which can lead to a decrease in the charge carrier balance. It can be predicted that the efficiency decreases due to a decrease in charge carrier balance through Equation 1.

$${η}_{EQE} = γ \cdot {η}_{S / T} \cdot {q}_{eff} \cdot {η}_{out} \qquad [ Equation 1 ]$$

η_{EQE}: External Quantum Efficiency (%)
γ: Carrier (hole-electron) balance (%)
η_{S/T}: Exciton generation rate according to singlet/triplet spin-orbit rules (%)
q_{eff}: Radiation Quantum Efficiency (%)
ηₒᵤₜ: External exciton extraction efficiency (%)

$${η}_{IQE} = γ \cdot {η}_{S / T} \cdot {q}_{eff} \qquad [ Equation 3 ]$$

η_{IQE}: Internal quantum efficiency (%)

$${η}_{EQE} = {η}_{IQE} \cdot {η}_{out} \qquad [ Equation 4 ]$$

More specifically, the unbalance of the charge carrier balance causes a decrease in γ (carrier balance) in Equation 1, which causes a problem of a decrease in the luminescence efficiency of the organic electronic element, and as the accumulation of holes increases with voltage, the exciton formation region moves along the interface of the emitting-auxiliary layer and the emitting layer, which causes degradation of the interface and can lead to a decrease in the lifetime of the organic electronic element. Therefore, when the energy levels or intrinsic properties of the material (mobility, interface properties, etc.) are optimally combined between the hole transport layer, the buffer layer, and the emitting-auxiliary layer, the characteristics and stability of the organic electronic element can be improved without causing hole accumulation at the interface between the emitting-auxiliary layer and the emitting layer.

At this time, the capacitance characteristics of the organic electronic element satisfy Equation 2.

$${V}_{cmax} - {V}_{c ( 0.8 nF )} \leq 1.3 V \qquad [ Equation 2 ]$$

Wherein,
1) V_{Cmax} is the voltage value at which the capacitance of organic electronic element is measured to be maximum.
2) V_{C(0.8 nF)} is the voltage value at which the capacitance of organic electronic element becomes 0.8 nF.

Capacitance refers to the amount of charge stored inside between the electrodes at both ends of an organic electronic element. The element's capacitance increases according to the voltage, and when holes and electrons in the organic electronic element begin to recombinant to form excitons, the capacitance stored inside decreases due to the carriers (holes and electrons) being consumed. The unit of capacitance is F (farad), which means storing or releasing 1 C of charge at a voltage of 1V. The capacitance of organic electronic element is in the range of nF (n(nano 1.0×10⁻⁹)F).

As can be seen from Equation 2, V_{Cmax}-V_{C(0.8 nF)} value is preferably 1.3 V or less, more preferably 1.1 V or less, even more preferably 1.0 V or less, and even more preferably 0.8 V or less. When the V_{Cmax}-V_{C(0.8 nF)} value exceeds 1.3 V, it causes unnecessary charge accumulation at the interface due to an increase in trapped holes. This shows an unstable panel structure with reduced luminescence efficiency and lifetime due to the formation of an exciton recombination zone moving to the interface of the emitting-auxiliary layer and the deterioration of the charge carrier balance. That is, after the voltage V_{Cmax}, the consumption of accumulated holes and the rapid generation of excitons cause interface degradation and efficiency roll-off. The more stable the structure of the organic electronic element, the more V_{c(0.8 nF)} is delayed, which delays charge accumulation at the interface. Therefore, when the V_{Cmax}-V_{C(0.8 nF)} value is less than 1.3 V, V_{c(0.8 nF)} is delayed, which allows for high efficiency and increased lifetime.

Additionally, it is preferable that the V_{Cmax} is the driving voltage range of the organic electronic element which is ±0.5 V of Vₜᵤᵣₙ₋ₒₙ. That is, the range of V_{Cmax} is preferably ±0.5 V of Vₜᵤᵣₙ₋ₒₙ, which is the point at which the exciton of the organic electronic element is formed, more preferably ±0.45 V, and even more preferably ±0.4 V. The Vₜᵤᵣₙ₋ₒₙ refers to the voltage at which exciton recombination (1˜5 nit) of the organic electronic element begins. When the V_{Cmax} value is as above, Vₜᵤᵣₙ₋ₒₙ, where the internally charged carriers reach their maximum point, is close to the point where exciton recombination begins, and when an exciton is formed, the internally charged holes and electrons are quickly depleted.

Additionally, it is preferable that the range of the V_{C(0.8 nF)} is the driving voltage range of the organic electronic element having a current density (mA/cm²) range of 1.0×10⁻⁷ to 1.0×10⁻⁴ mA/cm². Preferably 8.0×10⁻⁶ to 1.0×10⁻⁴ mA/cm², and more preferably 5.0×10⁻⁶ to 9.0×10⁻⁵ mA/cm². Current density is the current-voltage characteristic of organic electronic elements and means the amount of current per unit area with units of mA/cm².

The capacitance used in this specification is a numerical value representing the capacitance in an organic electronic element having 2 electrodes.

In organic electronic elements, the stored capacity can change depending on the permittivity of the internal organic material layers, such as the hole injection layer, hole transport layer, emitting-auxiliary layer, emitting layer, electron transport layer, and electron injection layer, as well as the polarization and transition dipole moment. Additionally, a buffer layer may be further included between the hole transport layer and the emitting-auxiliary layer.

$$C = \frac{{ε}_{0} {ε}_{r}}{d} A$$

C: Capacitance
ε₀: Permittivity of vacuum
εᵣ: Dielectric constant of internal organic material between anode and cathode
A: area

An ALPHA-AN Analyzer impedance meter was used to measure capacitance (F), which represents the ratio of the amount of charge accumulated according to charge mobility. Impedance measurement can evaluate the charge transfer characteristics of bulk or interfacial regions of ions, semiconductors, and insulators, etc., and is also an effective method for analyzing the electrical properties of materials and the interface with electrodes in OLEDs.

Specifically, the hole accumulation phenomenon can be confirmed by checking whether there is a change in capacitance according to the hole mobility from the anode to the hole transport layer. If the capacitance increases from the beginning, it can be seen that holes do not move smoothly at the hole transport layer interface and accumulate, resulting in a hole accumulation phenomenon.

According to one embodiment of the present specification, at least one of the hole transport layer, the buffer layer or the emitting-auxiliary layer may comprise a compound represented by the following Formula 1 or Formula 2.

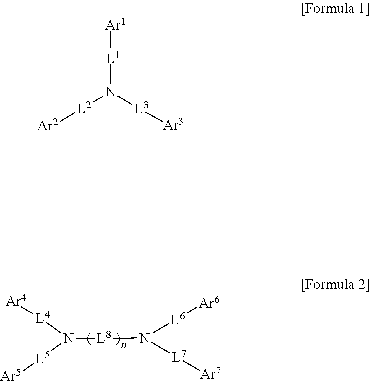

Wherein:
L¹, L², L³, L⁴, L⁵, L⁶ and L⁷ are each independently selected from the group consisting of single bond; a C₆-C₆₀ arylene group; a fluorenylene group; a C₂-C₆₀ heterocyclic group including at least one heteroatom of O, N, S, Si or P; and a fused ring group of a C₃-C₆₀ aliphatic ring and a C₆-C₆₀ aromatic ring;
L⁸ is each independently selected from the group consisting of a C₆-C₆₀ arylene group; a fluorenylene group; a C₂-C₆₀ heterocyclic group including at least one heteroatom of O, N, S, Si or P; and a fused ring group of a C₃-C₆₀ aliphatic ring and a C₆-C₆₀ aromatic ring;
Wherein when L¹, L², L³, L⁴, L⁵, L⁶, L⁷ and L⁸ are an arylene group, preferably a C₆-C₆₀ arylene group, more preferably a C₆-C₂₅ arylene group, a C₆-C₁₈ arylene group or an C₆-C₁₂ arylene group, such as phenylene, biphenylene, naphthylene, terphenylene, anthracenylene, phenanthrenylen, etc.

Wherein when L¹, L², L³, L⁴, L⁵, L⁶, L⁷ and L⁸ are a heterocyclic group, preferably a C₂-C₃₀ heterocyclic group, more preferably a C₂-C₂₅ heterocyclic group, a C₂-C₁₈ heterocyclic group, or a C₂-C₁₂ heterocyclic group, such as pyrazine, thiophene, pyridine, pyrimidine, quinoline, pyrimidoindole, 5-phenyl-5H-pyrimido[5,4-b]indole, quinazoline, quinoxaline, benzoquinazoline, carbazole, dibenzoquinazoline, benzofuran, benzothiophene, dibenzofuran, dibenzothiophene, benzothienopyrimidine, benzofuropyrimidine, phenothiazine, phenylphenothiazine, naphthobenzofuran, naphthobenzothiophene, etc.

Wherein when L¹, L², L³, L⁴, L⁵, L⁶, L⁷ and L⁸ are a fused ring group, preferably a fused ring group of an C₃-C₃₀ aliphatic ring and an C₆-C₆₀ aromatic ring, more preferably a fused ring group of an C₃-C₂₅ aliphatic ring and an C₆-C₂₅ aromatic ring. Ar¹, Ar², Ar³, Ar⁴, Ar⁵, Ar⁶ and Ar⁷ are each independently selected from the group consisting of an C₆-C₆₀ aryl group; a fluorenyl group; a C₂-C₆₀ heterocyclic group including at least one heteroatom of O, N, S, Si or P; a fused ring group of a C₃-C₆₀ aliphatic ring and a C₆-C₆₀ aromatic ring; a C₃-C₆₀ aliphatic ring; a C₁-C₆₀ alkyl group; a C₂-C₂₀ alkenyl group; a C₂-C₂₀ alkynyl group; a C₁-C₃₀ alkoxyl group; a C₆-C₆₀ aryloxy group; and -L′-N(R′)(R″); or Ar⁴ and Ar⁵ or Ar⁶ and Ar⁷ can be bonded to each other to form a ring,
Wherein when Ar¹, Ar², Ar³, Ar⁴, Ar⁵, Ar⁶ and Ar⁷ are an aryl group, preferably an C₆-C₆₀ aryl group, more preferably an C₆-C₂₅ aryl group, a C₆-C₁₈ aryl group or an C₆-C₁₂ aryl group, such as phenyl, biphenyl, terphenyl, naphthalene, phenanthrene, chryshen, etc.

Wherein when Ar¹, Ar², Ar³, Ar⁴, Ar⁵, Ar⁶ and Ar⁷ are a heterocyclic group, preferably a C₂-C₃₀ heterocyclic group, more preferably a C₂-C₂₅ heterocyclic group, a C₂-C₁₈ heterocyclic group, or a C₂-C₁₂ heterocyclic group, such as pyrazine, thiophene, pyridine, pyrimidine, quinoline, pyrimidoindole, 5-phenyl-5H-pyrimido[5,4-b]indole, quinazoline, quinoxaline, benzoquinazoline, carbazole, dibenzoquinazoline, benzofuran, benzothiophene, dibenzofuran, dibenzothiophene, benzothienopyrimidine, benzofuropyrimidine, phenothiazine, phenylphenothiazine, naphthobenzofuran, naphthobenzothiophene, etc.

Wherein when Ar¹, Ar², Ar³, Ar⁴, Ar⁵, Ar⁶ and Ar⁷ are a fused ring group, preferably a fused ring group of an C₃-C₃₀ aliphatic ring and an C₆-C₆₀ aromatic ring, more preferably a fused ring group of an C₃-C₂₅ aliphatic ring and an C₆-C₂₅ aromatic ring.

Wherein when Ar¹, Ar², Ar³, Ar⁴, Ar⁵, Ar⁶ and Ar⁷ are an aliphatic ring group, preferably a C₃-C₃₀ aliphatic ring group, more preferably a C₃-C₂₅ aliphatic ring group, a C₃-C₁₈ aliphatic ring group, and a C₃-C₁₂ aliphatic ring group, and specifically, cyclobutane, cyclopentane, cyclohexane, bicycloheptane, adamantyl, etc.

Wherein when Ar¹, Ar², Ar³, Ar⁴, Ar⁵, Ar⁶ and Ar⁷ are an alkyl group, preferably a C₁-C₃₀ alkyl group, more preferably a C₁-C₂₅ alkyl group, a C₁-C₁₈ alkyl group or a C₁-C₁₂ alkyl group, such as a methyl group, ethyl group, propyl group, isopropyl group, butyl group, t-butyl group, pentyl group, etc.

Wherein when Ar¹, Ar², Ar³, Ar⁴, Ar⁵, Ar⁶ and Ar⁷ are an alkoxyl group, preferably a C₁-C₂₅ alkoxyl group, a C₁-C₁₈ alkoxyl group or a C₁-C₁₂ alkoxyl group.

Wherein when Ar¹, Ar², Ar³, Ar⁴, Ar⁵, Ar⁶ and Ar⁷ are an aryloxy group, preferably a C₆-C₂₅ aryloxy group, a C₆-C₁₈ an aryloxy group or a C₆-C₁₂ aryloxyl group.

Wherein L′ is selected from the group consisting of a single bond; a C₆-C₆₀ arylene group; a fluorenylene group; a C₃-C₆₀ aliphatic ring; and a C₂-C₆₀ heterocyclic group including at least one heteroatom of O, N, S, Si or P;

Wherein when L′ is an arylene group, preferably a C₆-C₆₀ arylene group, more preferably an C₆-C₂₅ arylene group, an C₆-C₁₈ arylene group or an C₆-C₁₂ arylene group, such as phenylene, biphenylene, naphthylene, terphenylene, anthracenylene, phenanthrenylene, etc.

Wherein when L′ is an aliphatic ring, preferably a C₃-C₃₀ aliphatic ring; more preferably a C₃-C₂₅ aliphatic ring; a C₃-C₁₈ aliphatic ring; or a C₃-C₁₂ aliphatic ring; and specifically, cyclobutane, cyclopentane, cyclohexane, bicycloheptane, adamantyl, etc. Wherein when L′ is a heterocyclic group, preferably a C₂-C₃₀ heterocyclic group, more preferably a C₂-C₂₅ heterocyclic group, a C₂-C₁₈ heterocyclic group, or a C₂-C₁₂ heterocyclic group, such as pyrazine, thiophene, pyridine, pyrimidine, quinoline, pyrimidoindole, 5-phenyl-5H-pyrimido[5,4-b]indole, quinazoline, quinoxaline, benzoquinazoline, carbazole, dibenzoquinazoline, benzofuran, benzothiophene, dibenzofuran, dibenzothiophene, benzothienopyrimidine, benzofuropyrimidine, phenothiazine, phenylphenothiazine, naphthobenzofuran, naphthobenzothiophene, etc.

Wherein R′ and R″ are each independently selected from the group consisting of an C₆-C₆₀ aryl group; a fluorenyl group; a C₃-C₆₀ aliphatic ring; and a C₂-C₆₀ heterocyclic group including at least one heteroatom of O, N, S, Si or P; Wherein when R′ and R″ are an aryl group, preferably an C₆-C₆₀ aryl group, more preferably an C₆-C₂₅ aryl group, an C₆-C₁₈ aryl group or an C₆-C₁₂ aryl group, such as phenyl, biphenyl, terphenyl, naphthalene, phenanthrene, chryshen, etc.

Wherein when R′ and R″ are an aliphatic ring, preferably a C₃-C₃₀ aliphatic ring; more preferably a C₃-C₂₅ aliphatic ring; a C₃-C₁₈ aliphatic ring; or a C₃-C₁₂ aliphatic ring; and specifically, cyclobutane, cyclopentane, cyclohexane, bicycloheptane, adamantyl, etc.

Wherein when R′ and R″ are a heterocyclic group, preferably a C₂-C₃₀ heterocyclic group, more preferably a C₂-C₂₅ heterocyclic group, a C₂-C₁₈ heterocyclic group, or a C₂-C₁₂ heterocyclic group, such as pyrazine, thiophene, pyridine, pyrimidine, quinoline, pyrimidoindole, 5-phenyl-5H-pyrimido[5,4-b]indole, quinazoline, quinoxaline, benzoquinazoline, carbazole, dibenzoquinazoline, benzofuran, benzothiophene, dibenzofuran, dibenzothiophene, benzothienopyrimidine, benzofuropyrimidine, phenothiazine, phenylphenothiazine, naphthobenzofuran, naphthobenzothiophene, etc.

n is an integer from 1 to 3,
wherein the aryl group, arylene group, heterocyclic group, fluorenyl group, fluorenylene group, fused ring group, aliphatic ring group, alkyl group, alkenyl group, alkynyl group, alkoxy group and aryloxy group may be substituted with one or more substituents selected from the group consisting of deuterium; halogen; silane group substituted or unsubstituted with a C₁-C₂₀ alkyl group or a C₆-C₂₀ aryl group; siloxane group; boron group; germanium group; cyano group; nitro group; C₁-C₂₀ alkylthio group; C₁-C₂₀ alkoxyl group; C₆-C₂₀ aryloxy group; C₁-C₂₀ alkyl group; C₂-C₂₀ alkenyl group; C₂-C₂₀ alkynyl group; C₆-C₂₀ aryl group; C₆-C₂₀ aryl group substituted with deuterium; a fluorenyl group; C₂-C₂₀ heterocyclic group; a C₃-C₂₀ cycloalkyl ring; a C₇-C₂₀ arylalkyl group; a C₈-C₂₀ arylalkenyl group; and -L′-NR′R′; also the hydrogen of these substituents may be further substituted with one or more deuterium, and also the substituents may be bonded to each other to form a saturated or unsaturated ring, wherein the term ‘ring’ means a C₃-C₆₀ aliphatic ring or a C₆-C₆₀ aromatic ring or a C₂-C₆₀ heterocyclic group or a fused ring formed by the combination thereof.

Additionally, at least one of the Ar¹, Ar² and Ar³ and/or at least one of Ar⁴, Ar⁵, Ar⁶ and Ar⁷ is represented by any one of Formulae Ar-a to Ar-d:

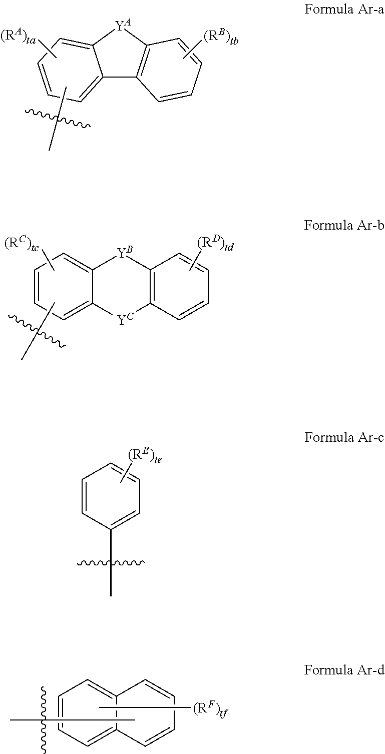

Wherein:
Y^{A}, Y^{B} and Y^{C} are each independently O, S, NR^{1A}, Si(R^{1B})(R^{1C}) or C(R^{1B})(R^{1C}),
R^{A}, R^{B}, R^{C}, R^{D}, R^{E}, R^{F}, R^{1A}, R^{1B} and R^{1C} are each the same or different, and each independently selected from the group consisting of a hydrogen; deuterium; halogen; cyano group; C₆-C₂₀ aryl group; C₆-C₂₀ aryl group substituted with deuterium; a fluorenyl group; a C₂-C₆₀ heterocyclic group including at least one heteroatom of O, N, S, Si or P; C₁-C₂₀ alkyl group; C₂-C₂₀ alkenyl group; C₂-C₂₀ alkynyl group; C₁-C₂₀ alkoxyl group; C₆-C₂₀ aryloxy group; and -L′-N(R′)(R″); or an adjacent plurality of R^{A}s or plurality of R^{B}s or plurality of R^{C}s or plurality of R^{D}s or plurality of R^{E}s or plurality of R^{F}s may be bonded to each other to form a ring, or R^{1B} and R^{1C} can be bonded to each other to form a Spiro,
ta and tc are each independently an integer of 0 to 3, tb and td are each independently an integer of 0 to 4, te is an integer of 0 to 5, tf is an integer of 0 to 7,
L′, R′ and R″ are the same as defined above,
[symbol] indicates the binding position.

Formula Ar-a is represented by any one of Formulas Ar-a-1 to Ar-a-4:

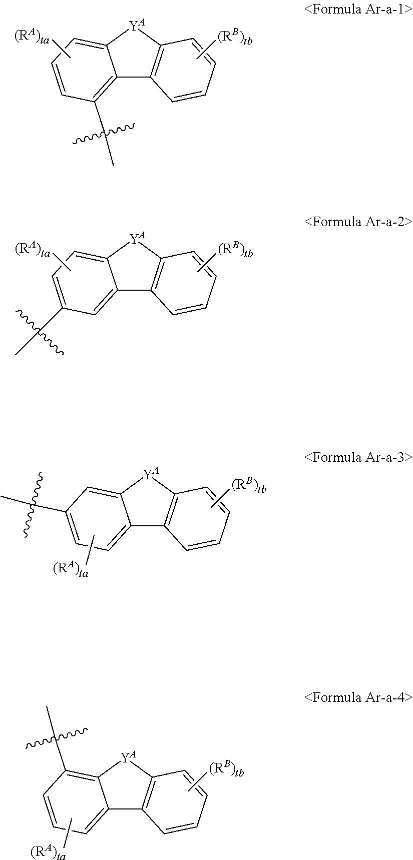

Wherein, R^{A}, R^{B}, Y^{A}, ta, tb and [symbol] are the same as defined in Formula Ar-a.

Formula Ar-b is represented by any one of Formulas Ar-b-1 to Ar-b-2:

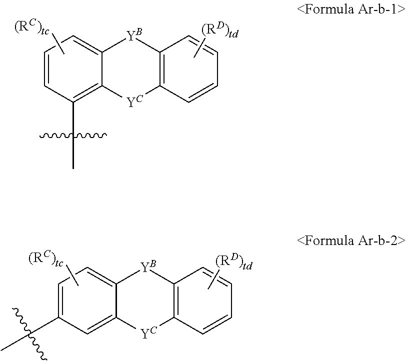

Wherein, R^{C}, R^{D}, Y^{B} Y^{C}, tc, td and [symbol] are the same as defined in Formula Ar-b.

Formula Ar-d is represented by any one of Formulas Ar-d-1 to Ar-d-2:

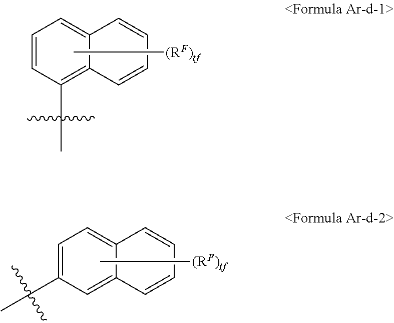

Wherein, R^{F}, tf and [symbol] are the same as defined in Formula Ar-d.

L¹, L², L³, L⁴, L⁵, L⁶ and L⁷ may be represented by a single bond or any one of Formulas b-1 to b-13, and L⁸ may be represented by any one of Formulas b-1 to b-13.

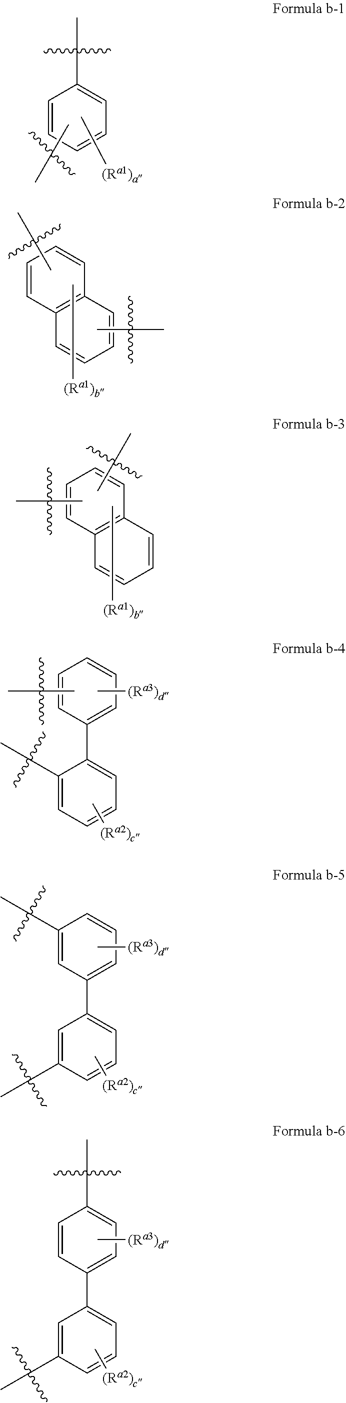

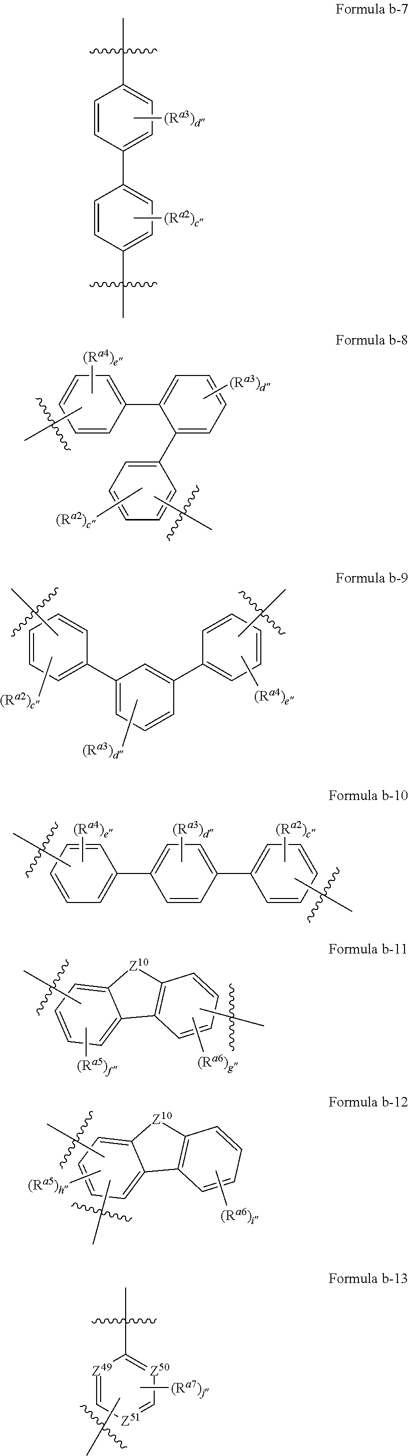

Wherein:
Z¹⁰ is O, S, NR^{1D} or C(R^{1E})(R^{1F})
a″, c″, d″, e″ and i″ are independently integers from 0 to 4, b″ is an integer from 0 to 6, f″ and g″ are independently integers from 0 to 3, h″ is an integer from 0 to 2, j″ is an integer of 0 or 1,
R^{a1}, R^{a2}, R^{a3}, R^{a4}, R^{a5}, R^{a6}, R^{a7}, R^{1D}, R^{1E} and R^{1F} are each the same or different, and each independently selected from the group consisting of a hydrogen; deuterium; an C₆-C₂₀ aryl substituted or unsubstituted with deuterium; a fluorenyl group; a C₂-C₂₀ heterocyclic group including at least one heteroatom of O, N, S, Si or P; C₁-C₅₀ alkyl group; C₂-C₂₀ alkenyl group; C₂-C₂₀ alkynyl group; C₁-C₂₀ alkoxyl group; and C₆-C₂₀ aryloxy group; or adjacent groups can be bonded together to form a ring,
Z⁴⁹, Z⁵⁰ and Z⁵¹ are each independently CR^{1G} or N,
However, at least one of Z⁴⁹, Z⁵⁰ and Z⁵¹ is N,
R^{1G} is each independently selected from the group consisting of a hydrogen; deuterium; an C₆-C₂₀ aryl; a fluorenyl group; a C₂-C₂₀ heterocyclic group including at least one heteroatom of O, N, S, Si or P; C₁-C₂₀ alkyl group; C₂-C₂₀ alkenyl group; C₂-C₂₀ alkynyl group; C₁-C₂₀ alkoxyl group; and C₆-C₂₀ aryloxy group;
[symbol] indicates the binding position.

Specifically, the compound represented by Formula 1 may be a compound represented by any one of the compounds P1-1 to P1-96, but is not limited thereto.

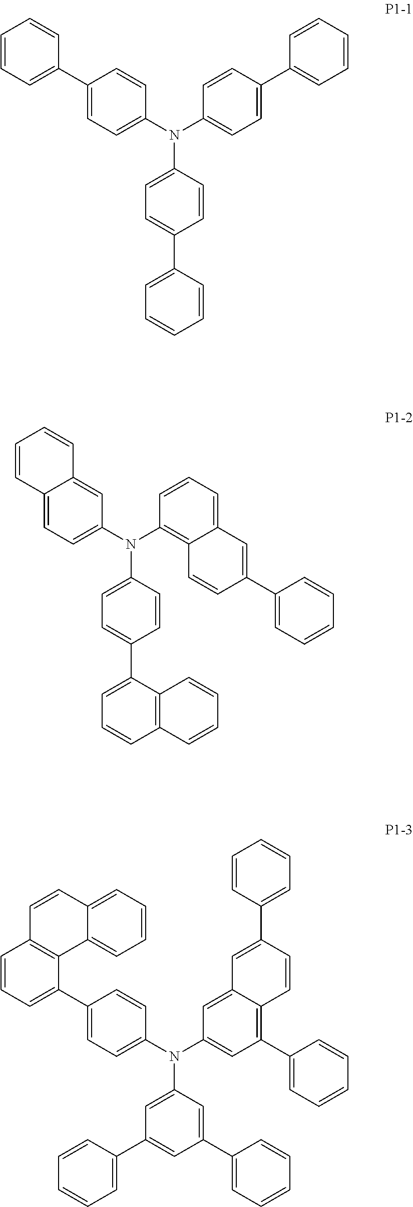 [SMILES: c1ccc(-c2ccc(N(c3ccc(-c4ccccc4)cc3)c3ccc(-c4ccccc4)cc3)cc2)cc1 ; c1ccc(-c2ccc3c(N(c4ccc(-c5cccc6ccccc56)cc4)c4ccc5ccccc5c4)cccc3c2)cc1 ; c1ccc(-c2cc(-c3ccccc3)cc(N(c3ccc(-c4cccc5ccc6ccccc6c45)cc3)c3cc(-c4ccccc4)c4ccc(-c5ccccc5)cc4c3)c2)cc1]

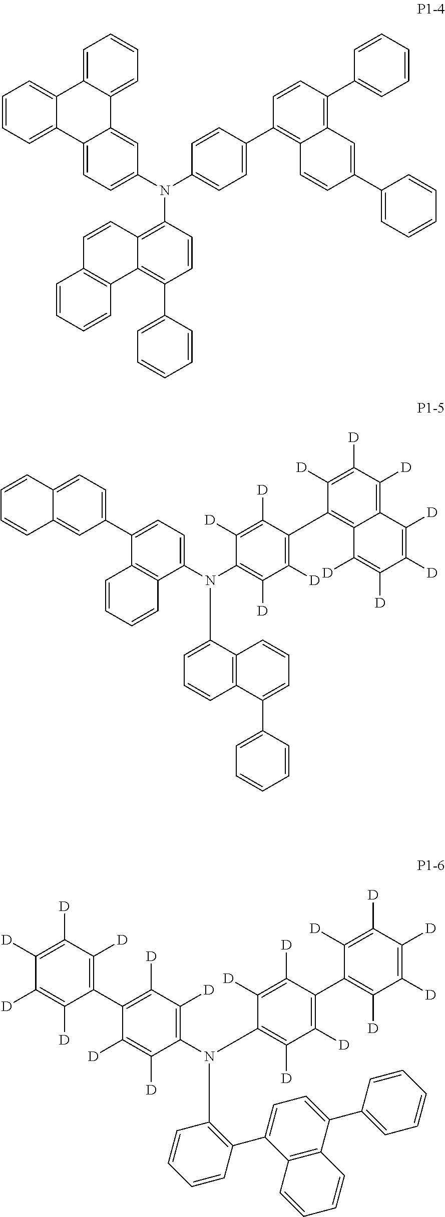 [SMILES: c1ccc(-c2ccc3c(-c4ccc(N(c5ccc6c7ccccc7c7ccccc7c6c5)c5ccc(-c6ccccc6)c6c5ccc5ccccc56)cc4)ccc(-c4ccccc4)c3c2)cc1 ; [2H]c1c([2H])c(N(c2cccc3c(-c4ccccc4)cccc23)c2ccc(-c3ccc4ccccc4c3)c3ccccc23)c([2H])c([2H])c1-c1c([2H])c([2H])c([2H])c2c([2H])c([2H])c([2H])c([2H])c12 ; [2H]c1c([2H])c([2H])c(-c2c([2H])c([2H])c(N(c3ccccc3-c3ccc(-c4ccccc4)c4ccccc34)c3c([2H])c([2H])c(-c4c([2H])c([2H])c([2H])c([2H])c4[2H])c([2H])c3[2H])c([2H])c2[2H])c([2H])c1[2H]]

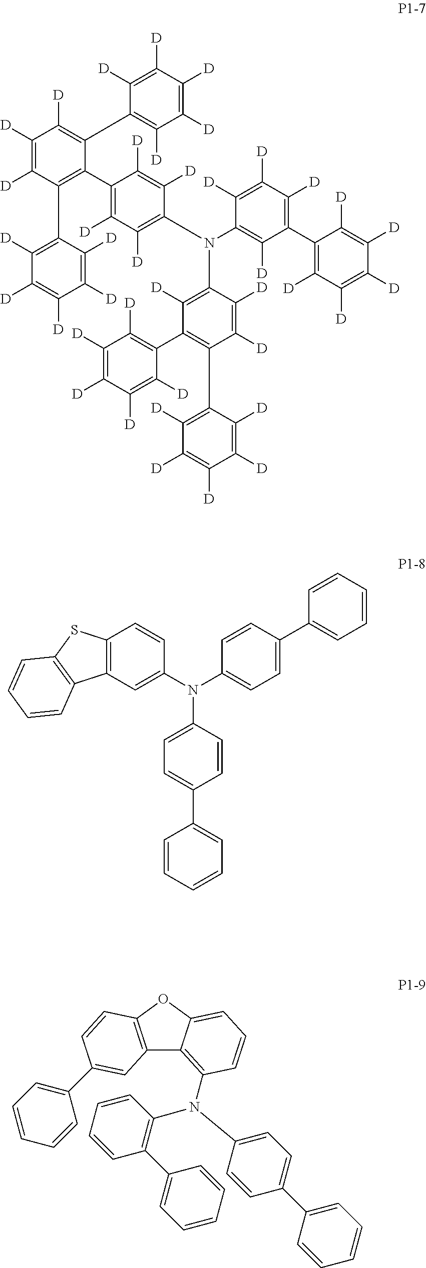 [SMILES: [2H]c1c([2H])c([2H])c(-c2c([2H])c([2H])c([2H])c(N(c3c([2H])c([2H])c(-c4c(-c5c([2H])c([2H])c([2H])c([2H])c5[2H])c([2H])c([2H])c([2H])c4-c4c([2H])c([2H])c([2H])c([2H])c4[2H])c([2H])c3[2H])c3c([2H])c([2H])c(-c4c([2H])c([2H])c([2H])c([2H])c4[2H])c(-c4c([2H])c([2H])c([2H])c([2H])c4[2H])c3[2H])c2[2H])c([2H])c1[2H] ; c1ccc(-c2ccc(N(c3ccc(-c4ccccc4)cc3)c3ccc4sc5ccccc5c4c3)cc2)cc1 ; c1ccc(-c2ccc(N(c3ccccc3-c3ccccc3)c3cccc4oc5ccc(-c6ccccc6)cc5c34)cc2)cc1]

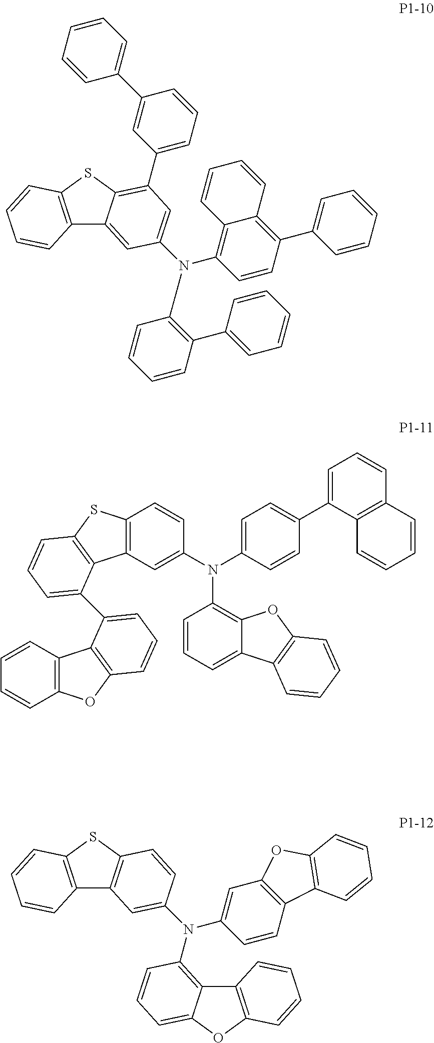 [SMILES: c1ccc(-c2cccc(-c3cc(N(c4ccccc4-c4ccccc4)c4ccc(-c5ccccc5)c5ccccc45)cc4c3sc3ccccc34)c2)cc1 ; c1ccc2c(-c3ccc(N(c4ccc5sc6cccc(-c7cccc8oc9ccccc9c78)c6c5c4)c4cccc5c4oc4ccccc45)cc3)cccc2c1 ; c1ccc2c(c1)oc1cc(N(c3ccc4sc5ccccc5c4c3)c3cccc4oc5ccccc5c34)ccc12]

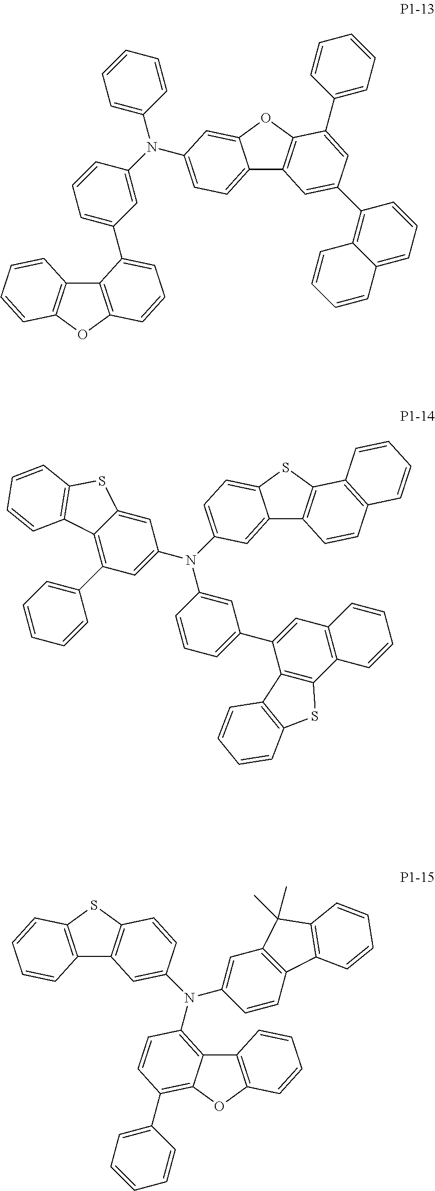 [SMILES: c1ccc(-c2cc(-c3cccc4ccccc34)cc3c2oc2cc(N(c4ccccc4)c4cccc(-c5cccc6oc7ccccc7c56)c4)ccc23)cc1 ; c1ccc(-c2cc(N(c3cccc(-c4cc5ccccc5c5sc6ccccc6c45)c3)c3ccc4sc5c6ccccc6ccc5c4c3)cc3sc4ccccc4c23)cc1 ; CC1(C)c2ccccc2-c2ccc(N(c3ccc4sc5ccccc5c4c3)c3ccc(-c4ccccc4)c4oc5ccccc5c34)cc21]

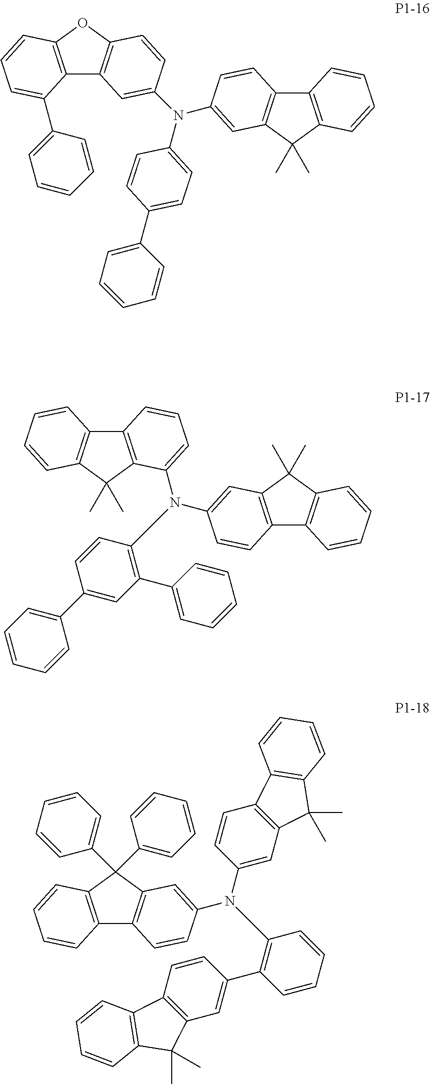 [SMILES: CC1(C)c2ccccc2-c2ccc(N(c3ccc(-c4ccccc4)cc3)c3ccc4oc5cccc(-c6ccccc6)c5c4c3)cc21 ; CC1(C)c2ccccc2-c2ccc(N(c3ccc(-c4ccccc4)cc3-c3ccccc3)c3cccc4c3C(C)(C)c3ccccc3-4)cc21 ; CC1(C)c2ccccc2-c2ccc(-c3ccccc3N(c3ccc4c(c3)C(C)(C)c3ccccc3-4)c3ccc4c(c3)C(c3ccccc3)(c3ccccc3)c3ccccc3-4)cc21]

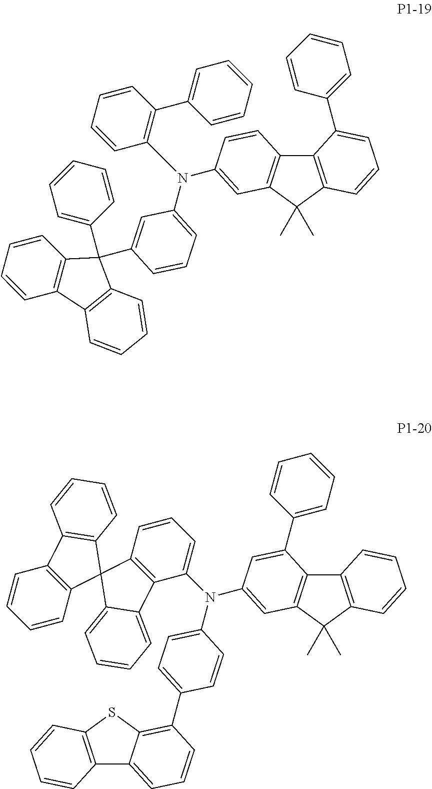 [SMILES: CC1(C)c2cc(N(c3cccc(C4(c5ccccc5)c5ccccc5-c5ccccc54)c3)c3ccccc3-c3ccccc3)ccc2-c2c(-c3ccccc3)cccc21 ; CC1(C)c2ccccc2-c2c(-c3ccccc3)cc(N(c3ccc(-c4cccc5c4sc4ccccc45)cc3)c3cccc4c3-c3ccccc3C43c4ccccc4-c4ccccc43)cc21]

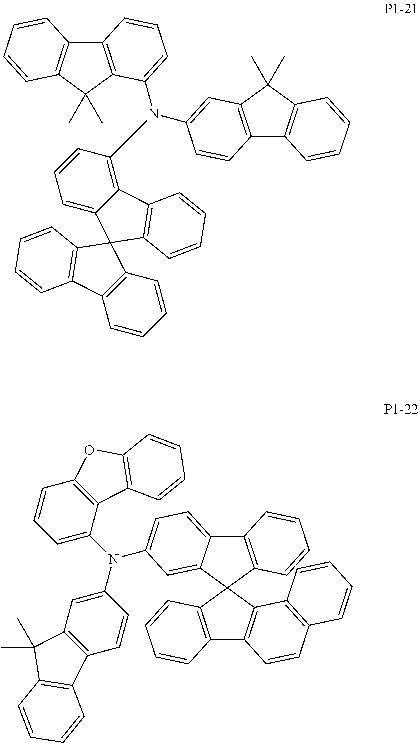 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2ccc(N(c3ccc4c(c3)C3(c5ccccc5-4)c4ccccc4-c4ccc5ccccc5c43)c3cccc4oc5ccccc5c34)cc21]

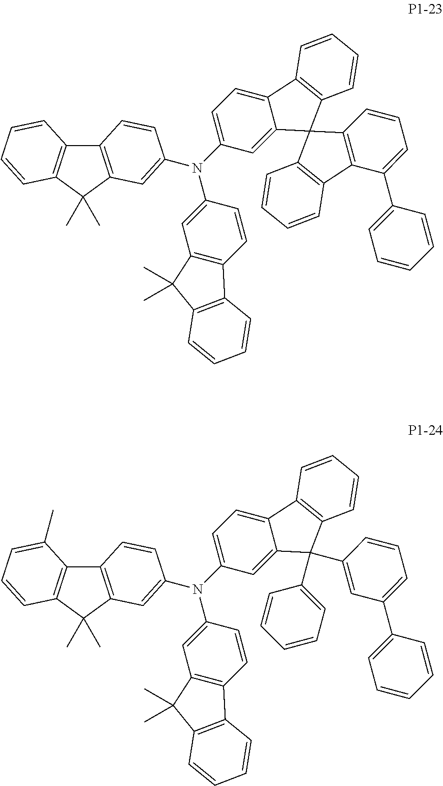 [SMILES: CC1(C)c2ccccc2-c2ccc(N(c3ccc4c(c3)C(C)(C)c3ccccc3-4)c3ccc4c(c3)C3(c5ccccc5-4)c4ccccc4-c4c(-c5ccccc5)cccc43)cc21 ; Cc1cccc2c1-c1ccc(N(c3ccc4c(c3)C(C)(C)c3ccccc3-4)c3ccc4c(c3)C(c3ccccc3)(c3cccc(-c5ccccc5)c3)c3ccccc3-4)cc1C2(C)C]

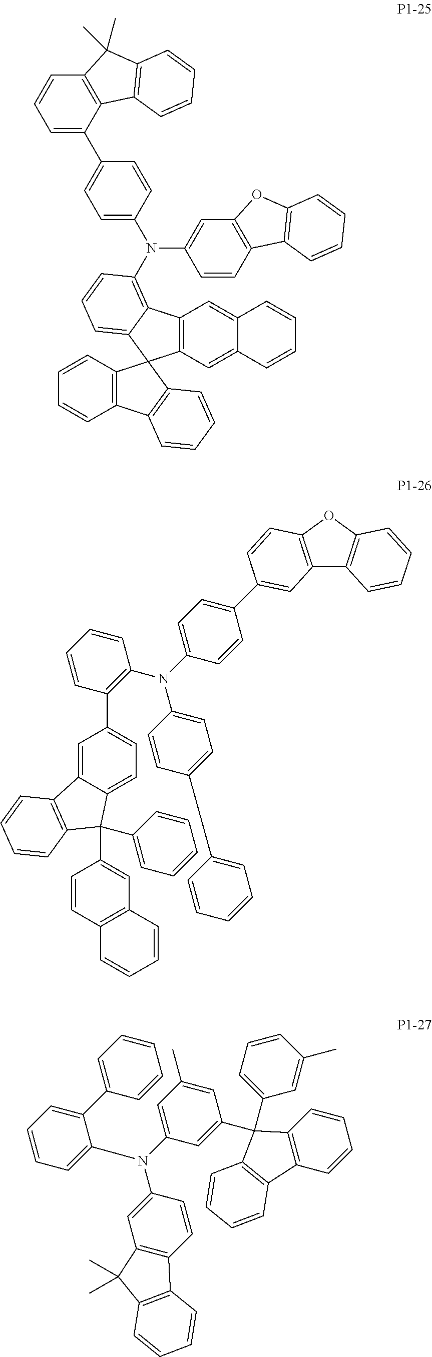 [SMILES: CC1(C)c2ccccc2-c2c(-c3ccc(N(c4ccc5c(c4)oc4ccccc45)c4cccc5c4-c4cc6ccccc6cc4C54c5ccccc5-c5ccccc54)cc3)cccc21 ; c1ccc(-c2ccc(N(c3ccc(-c4ccc5oc6ccccc6c5c4)cc3)c3ccccc3-c3ccc4c(c3)-c3ccccc3C4(c3ccccc3)c3ccc4ccccc4c3)cc2)cc1 ; Cc1cccc(C2(c3cc(C)cc(N(c4ccc5c(c4)C(C)(C)c4ccccc4-5)c4ccccc4-c4ccccc4)c3)c3ccccc3-c3ccccc32)c1]

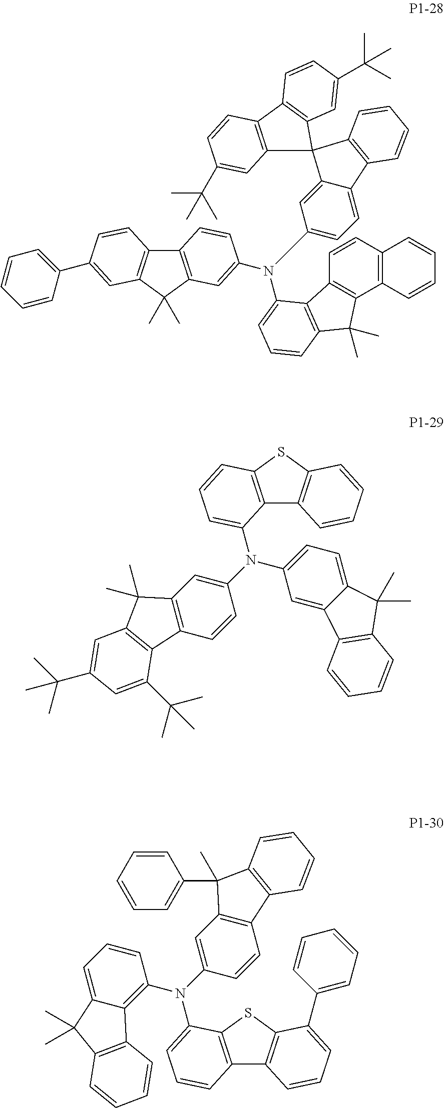

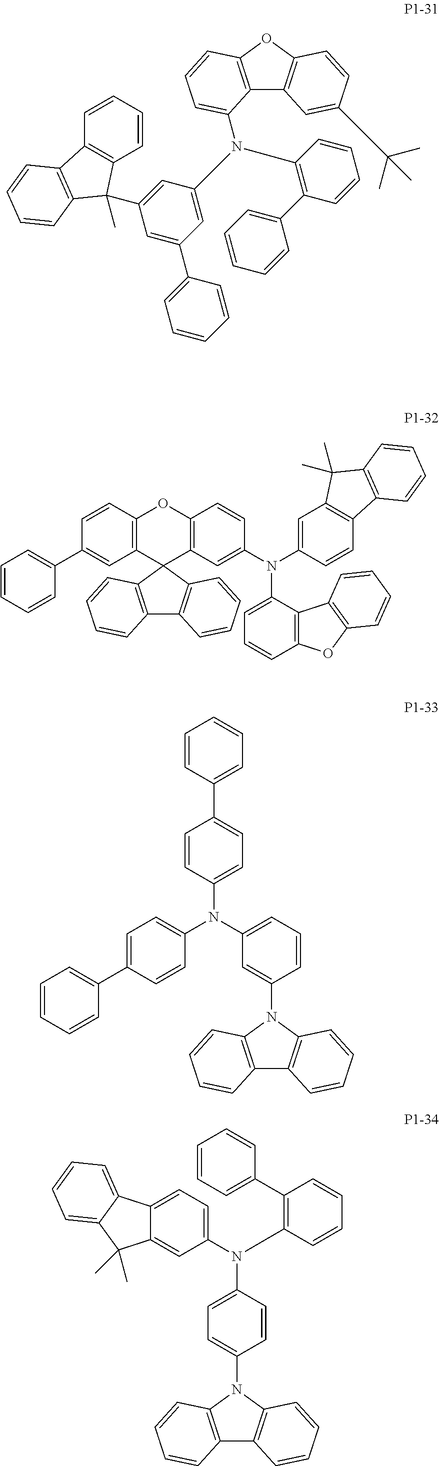

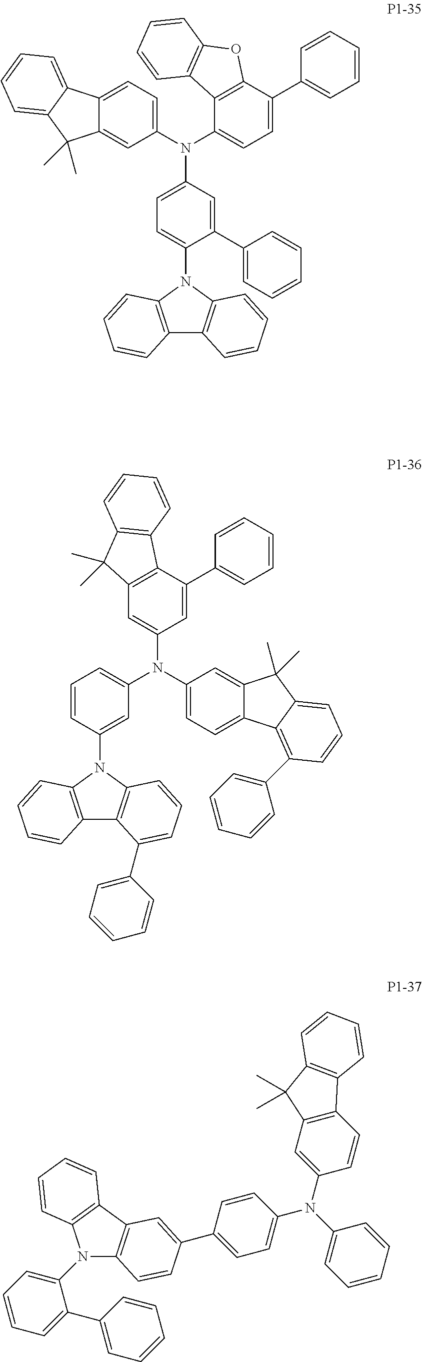 [SMILES: CC1(C)c2ccccc2-c2ccc(N(c3ccc(-n4c5ccccc5c5ccccc54)c(-c4ccccc4)c3)c3ccc(-c4ccccc4)c4oc5ccccc5c34)cc21 ; CC1(C)c2cc(N(c3cccc(-n4c5ccccc5c5c(-c6ccccc6)cccc54)c3)c3cc(-c4ccccc4)c4c(c3)C(C)(C)c3ccccc3-4)ccc2-c2c(-c3ccccc3)cccc21 ; CC1(C)c2ccccc2-c2ccc(N(c3ccccc3)c3ccc(-c4ccc5c(c4)c4ccccc4n5-c4ccccc4-c4ccccc4)cc3)cc21]

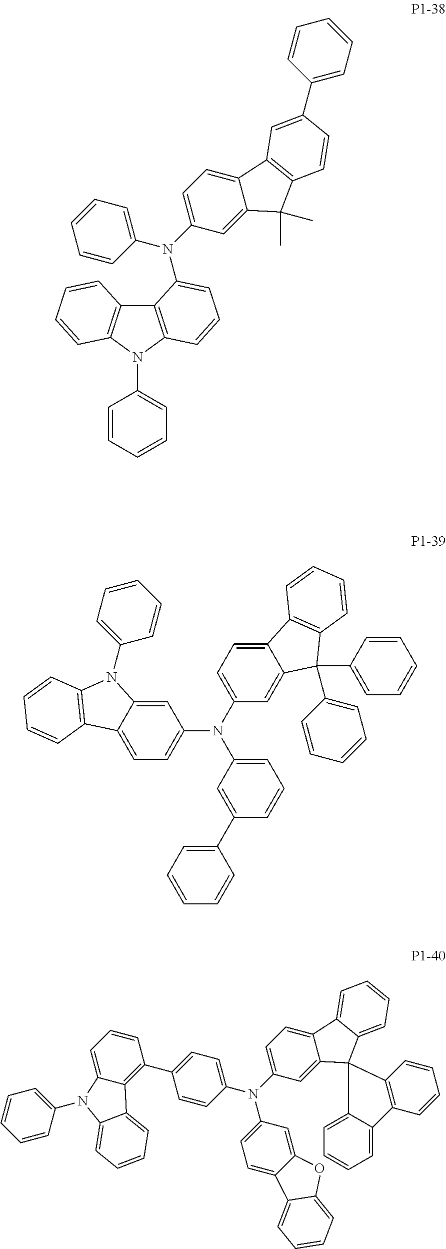 [SMILES: CC1(C)c2ccc(-c3ccccc3)cc2-c2ccc(N(c3ccccc3)c3cccc4c3c3ccccc3n4-c3ccccc3)cc21 ; c1ccc(-c2cccc(N(c3ccc4c(c3)C(c3ccccc3)(c3ccccc3)c3ccccc3-4)c3ccc4c5ccccc5n(-c5ccccc5)c4c3)c2)cc1 ; c1ccc(-n2c3ccccc3c3c(-c4ccc(N(c5ccc6c(c5)C5(c7ccccc7-c7ccccc75)c5ccccc5-6)c5ccc6c(c5)oc5ccccc56)cc4)cccc32)cc1]

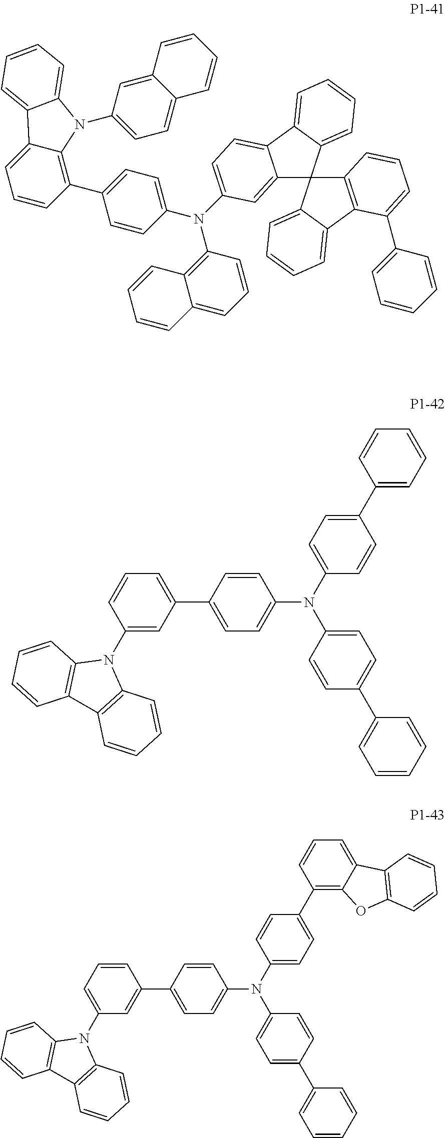 [SMILES: c1ccc(-c2cccc3c2-c2ccccc2C32c3ccccc3-c3ccc(N(c4ccc(-c5cccc6c7ccccc7n(-c7ccc8ccccc8c7)c56)cc4)c4cccc5ccccc45)cc32)cc1 ; c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

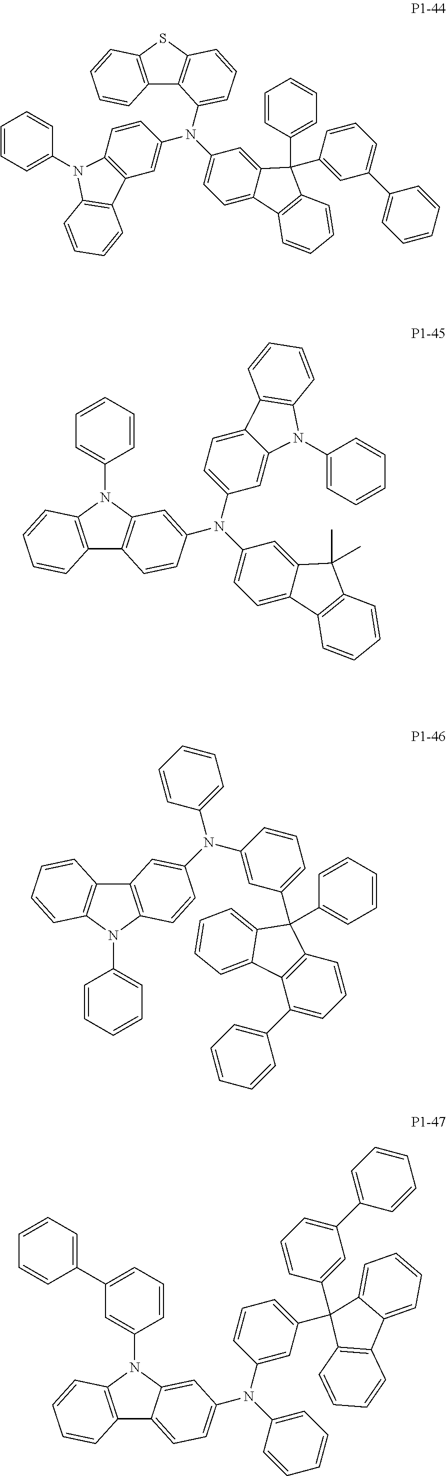 [SMILES: c1ccc(-c2cccc(C3(c4ccccc4)c4ccccc4-c4ccc(N(c5ccc6c(c5)c5ccccc5n6-c5ccccc5)c5cccc6sc7ccccc7c56)cc43)c2)cc1 ; CC1(C)c2ccccc2-c2ccc(N(c3ccc4c5ccccc5n(-c5ccccc5)c4c3)c3ccc4c5ccccc5n(-c5ccccc5)c4c3)cc21 ; c1ccc(-c2cccc3c2-c2ccccc2C3(c2ccccc2)c2cccc(N(c3ccccc3)c3ccc4c(c3)c3ccccc3n4-c3ccccc3)c2)cc1 ; c1ccc(-c2cccc(-n3c4ccccc4c4ccc(N(c5ccccc5)c5cccc(C6(c7cccc(-c8ccccc8)c7)c7ccccc7-c7ccccc76)c5)cc43)c2)cc1]

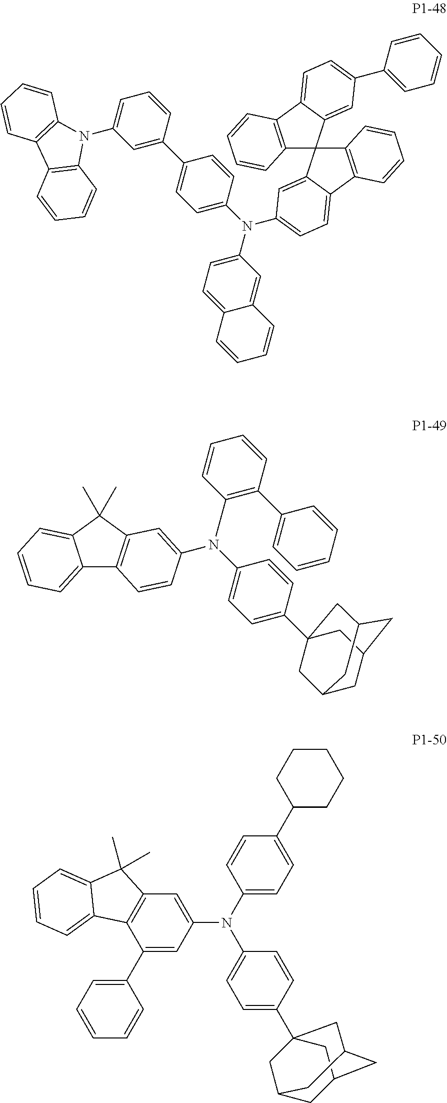 [SMILES: c1ccc(-c2ccc3c(c2)C2(c4ccccc4-3)c3ccccc3-c3ccc(N(c4ccc(-c5cccc(-n6c7ccccc7c7ccccc76)c5)cc4)c4ccc5ccccc5c4)cc32)cc1 ; CC1(C)c2ccccc2-c2ccc(N(c3ccc(C45CC6CC(CC(C6)C4)C5)cc3)c3ccccc3-c3ccccc3)cc21 ; CC1(C)c2ccccc2-c2c(-c3ccccc3)cc(N(c3ccc(C4CCCCC4)cc3)c3ccc(C45CC6CC(CC(C6)C4)C5)cc3)cc21]

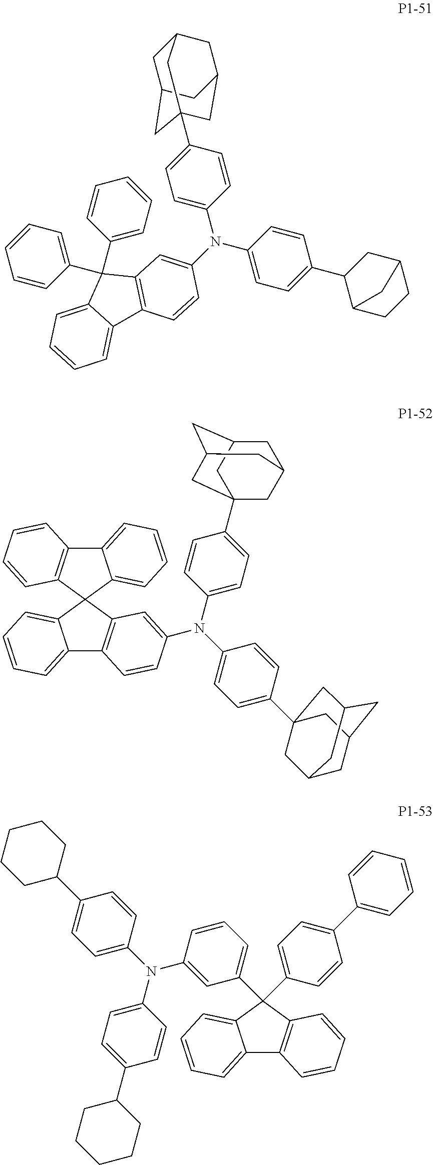 [SMILES: c1ccc(C2(c3ccccc3)c3ccccc3-c3ccc(N(c4ccc(C5CC6CCC5C6)cc4)c4ccc(C56CC7CC(CC(C7)C5)C6)cc4)cc32)cc1 ; c1ccc2c(c1)-c1ccccc1C21c2ccccc2-c2ccc(N(c3ccc(C45CC6CC(CC(C6)C4)C5)cc3)c3ccc(C45CC6CC(CC(C6)C4)C5)cc3)cc21 ; c1ccc(-c2ccc(C3(c4cccc(N(c5ccc(C6CCCCC6)cc5)c5ccc(C6CCCCC6)cc5)c4)c4ccccc4-c4ccccc43)cc2)cc1]

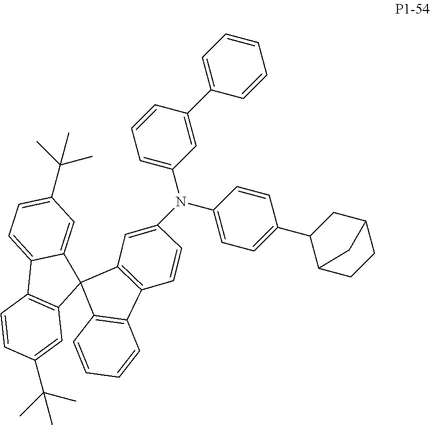 [SMILES: CC(C)(C)c1ccc2c(c1)C1(c3ccccc3-c3ccc(N(c4ccc(C5CC6CCC5C6)cc4)c4cccc(-c5ccccc5)c4)cc31)c1cc(C(C)(C)C)ccc1-2]

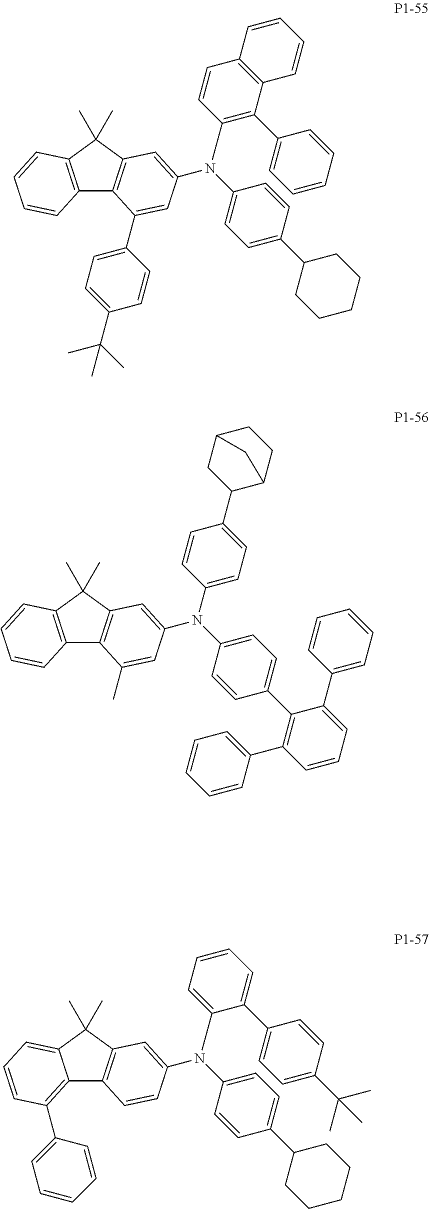 [SMILES: CC(C)(C)c1ccc(-c2cc(N(c3ccc(C4CCCCC4)cc3)c3ccc4ccccc4c3-c3ccccc3)cc3c2-c2ccccc2C3(C)C)cc1 ; Cc1cc(N(c2ccc(-c3c(-c4ccccc4)cccc3-c3ccccc3)cc2)c2ccc(C3CC4CCC3C4)cc2)cc2c1-c1ccccc1C2(C)C ; CC(C)(C)c1ccc(-c2ccccc2N(c2ccc(C3CCCCC3)cc2)c2ccc3c(c2)C(C)(C)c2cccc(-c4ccccc4)c2-3)cc1]

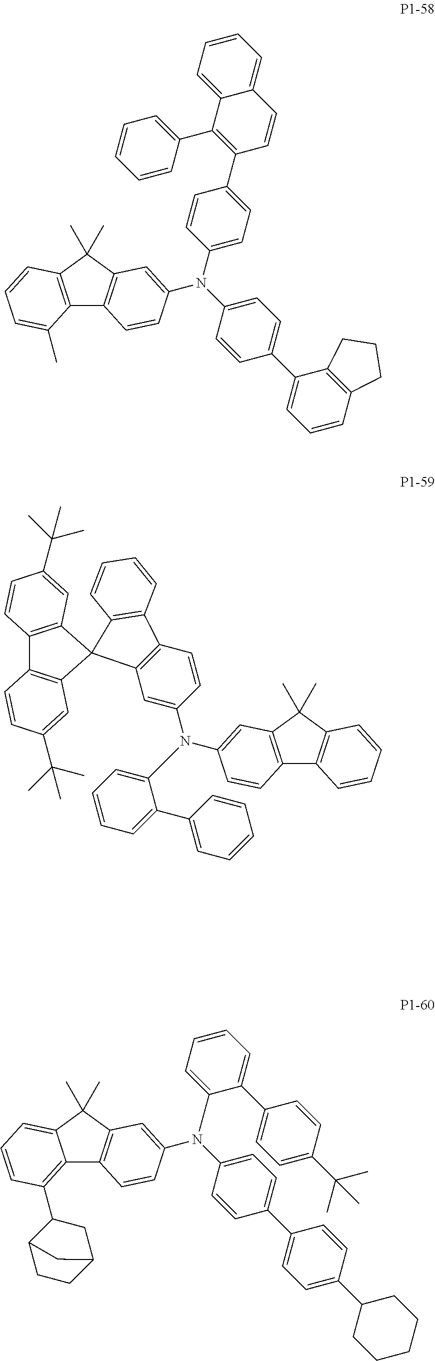 [SMILES: Cc1cccc2c1-c1ccc(N(c3ccc(-c4cccc5c4CCC5)cc3)c3ccc(-c4ccc5ccccc5c4-c4ccccc4)cc3)cc1C2(C)C ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC(C)(C)c1ccc(-c2ccccc2N(c2ccc(-c3ccc(C4CCCCC4)cc3)cc2)c2ccc3c(c2)C(C)(C)c2cccc(C4CC5CCC4C5)c2-3)cc1]

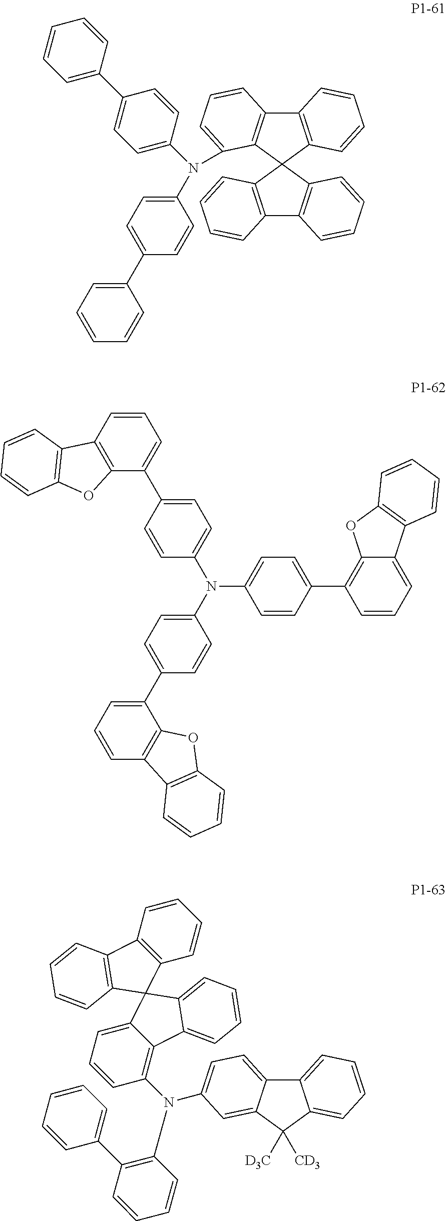 [SMILES: c1ccc(-c2ccc(N(c3ccc(-c4ccccc4)cc3)c3cccc4c3C3(c5ccccc5-c5ccccc53)c3ccccc3-4)cc2)cc1 ; c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; [2H]C([2H])([2H])C1(C([2H])([2H])[2H])c2ccccc2-c2ccc(N(c3ccccc3-c3ccccc3)c3cccc4c3-c3ccccc3C43c4ccccc4-c4ccccc43)cc21]

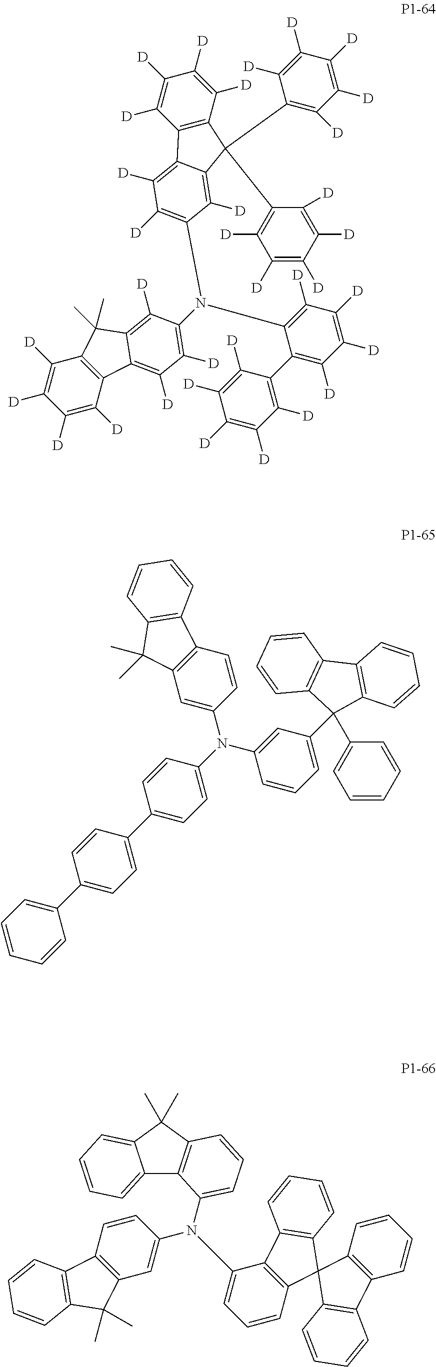 [SMILES: [2H]c1c([2H])c([2H])c(-c2c([2H])c([2H])c([2H])c([2H])c2N(c2c([2H])c([2H])c3c(c2[2H])C(C)(C)c2c([2H])c([2H])c([2H])c([2H])c2-3)c2c([2H])c([2H])c3c(c2[2H])C(c2c([2H])c([2H])c([2H])c([2H])c2[2H])(c2c([2H])c([2H])c([2H])c([2H])c2[2H])c2c([2H])c([2H])c([2H])c([2H])c2-3)c([2H])c1[2H] ; CC1(C)c2ccccc2-c2ccc(N(c3ccc(-c4ccc(-c5ccccc5)cc4)cc3)c3cccc(C4(c5ccccc5)c5ccccc5-c5ccccc54)c3)cc21 ; CC1(C)c2ccccc2-c2ccc(N(c3cccc4c3-c3ccccc3C4(C)C)c3cccc4c3-c3ccccc3C43c4ccccc4-c4ccccc43)cc21]

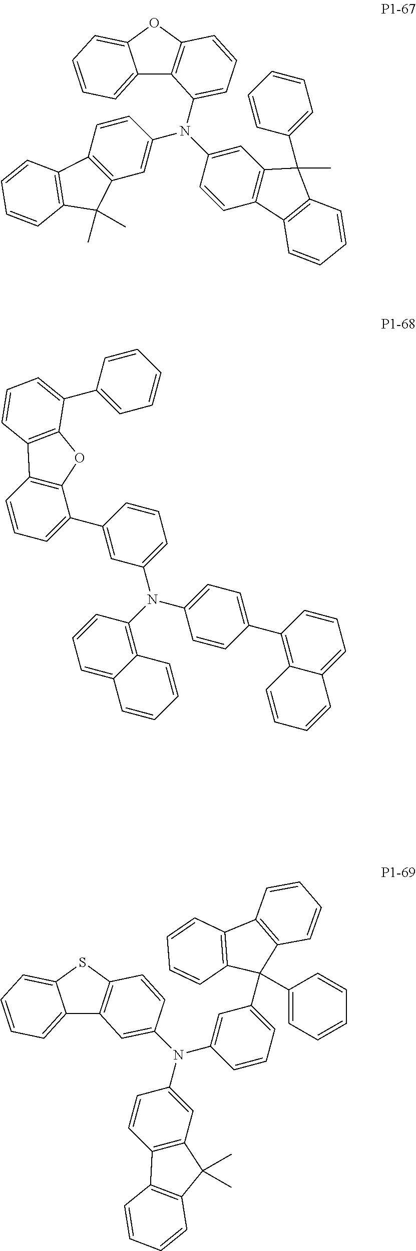 [SMILES: CC1(C)c2ccccc2-c2ccc(N(c3ccc4c(c3)C(C)(c3ccccc3)c3ccccc3-4)c3cccc4oc5ccccc5c34)cc21 ; c1ccc(-c2cccc3c2oc2c(-c4cccc(N(c5ccc(-c6cccc7ccccc67)cc5)c5cccc6ccccc56)c4)cccc23)cc1 ; CC1(C)c2ccccc2-c2ccc(N(c3cccc(C4(c5ccccc5)c5ccccc5-c5ccccc54)c3)c3ccc4sc5ccccc5c4c3)cc21]

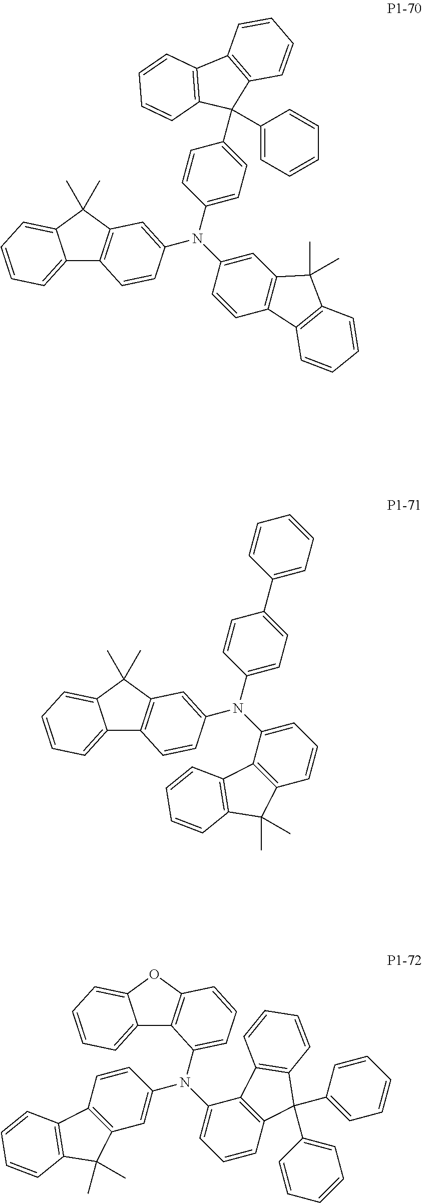 [SMILES: CC1(C)c2ccccc2-c2ccc(N(c3ccc(C4(c5ccccc5)c5ccccc5-c5ccccc54)cc3)c3ccc4c(c3)C(C)(C)c3ccccc3-4)cc21 ; CC1(C)c2ccccc2-c2ccc(N(c3ccc(-c4ccccc4)cc3)c3cccc4c3-c3ccccc3C4(C)C)cc21 ; CC1(C)c2ccccc2-c2ccc(N(c3cccc4c3-c3ccccc3C4(c3ccccc3)c3ccccc3)c3cccc4oc5ccccc5c34)cc21]

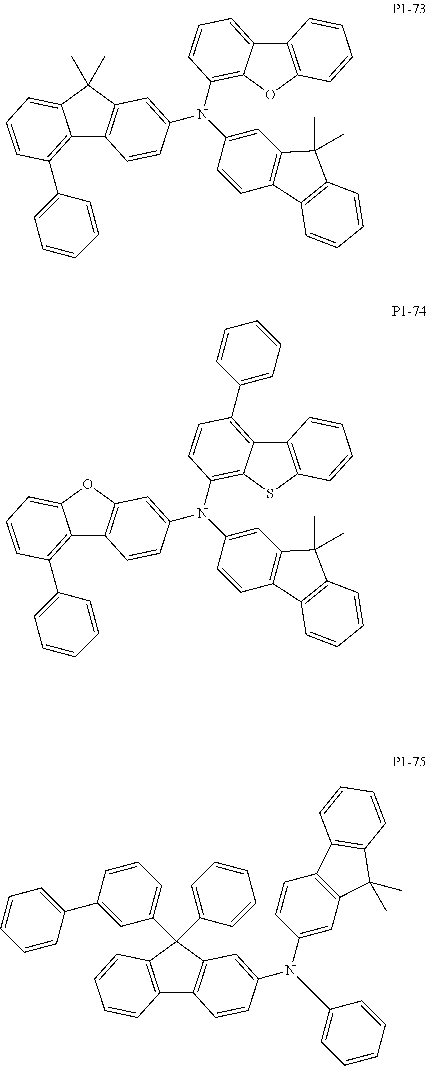 [SMILES: CC1(C)c2ccccc2-c2ccc(N(c3ccc4c(c3)C(C)(C)c3cccc(-c5ccccc5)c3-4)c3cccc4c3oc3ccccc34)cc21 ; CC1(C)c2ccccc2-c2ccc(N(c3ccc4c(c3)oc3cccc(-c5ccccc5)c34)c3ccc(-c4ccccc4)c4c3sc3ccccc34)cc21 ; CC1(C)c2ccccc2-c2ccc(N(c3ccccc3)c3ccc4c(c3)C(c3ccccc3)(c3cccc(-c5ccccc5)c3)c3ccccc3-4)cc21]

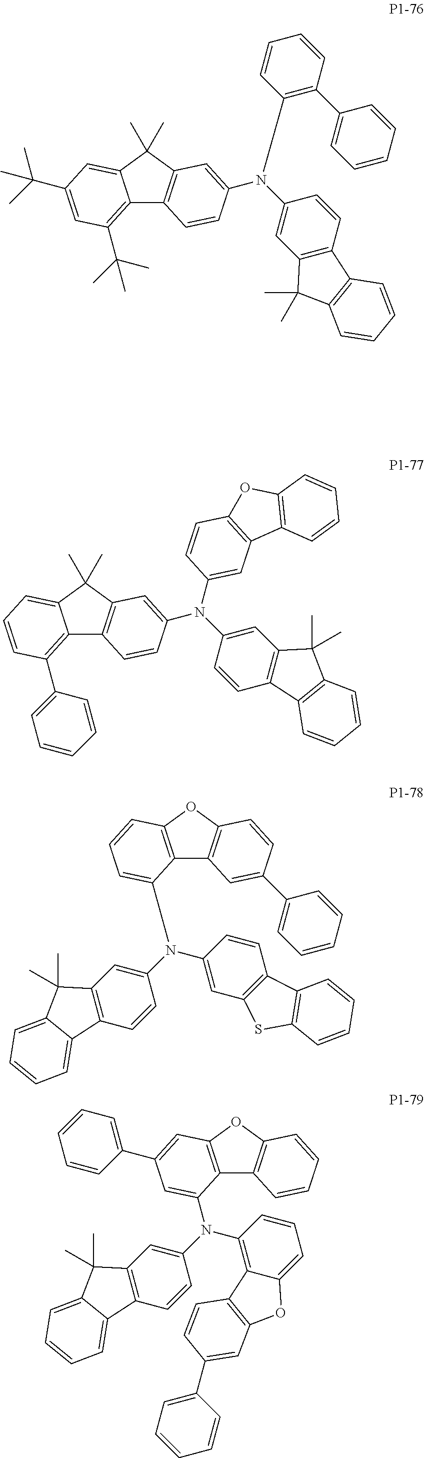

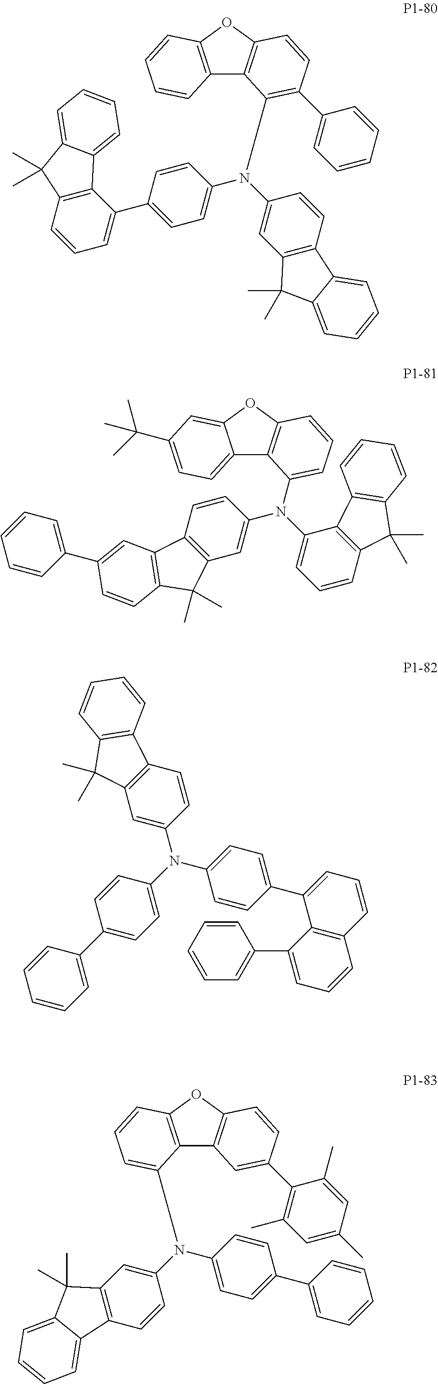 [SMILES: CC1(C)c2ccccc2-c2ccc(N(c3ccc(-c4cccc5c4-c4ccccc4C5(C)C)cc3)c3c(-c4ccccc4)ccc4oc5ccccc5c34)cc21 ; CC(C)(C)c1ccc2c(c1)oc1cccc(N(c3ccc4c(c3)C(C)(C)c3ccc(-c5ccccc5)cc3-4)c3cccc4c3-c3ccccc3C4(C)C)c12 ; CC1(C)c2ccccc2-c2ccc(N(c3ccc(-c4ccccc4)cc3)c3ccc(-c4cccc5cccc(-c6ccccc6)c45)cc3)cc21 ; Cc1cc(C)c(-c2ccc3oc4cccc(N(c5ccc(-c6ccccc6)cc5)c5ccc6c(c5)C(C)(C)c5ccccc5-6)c4c3c2)c(C)c1]

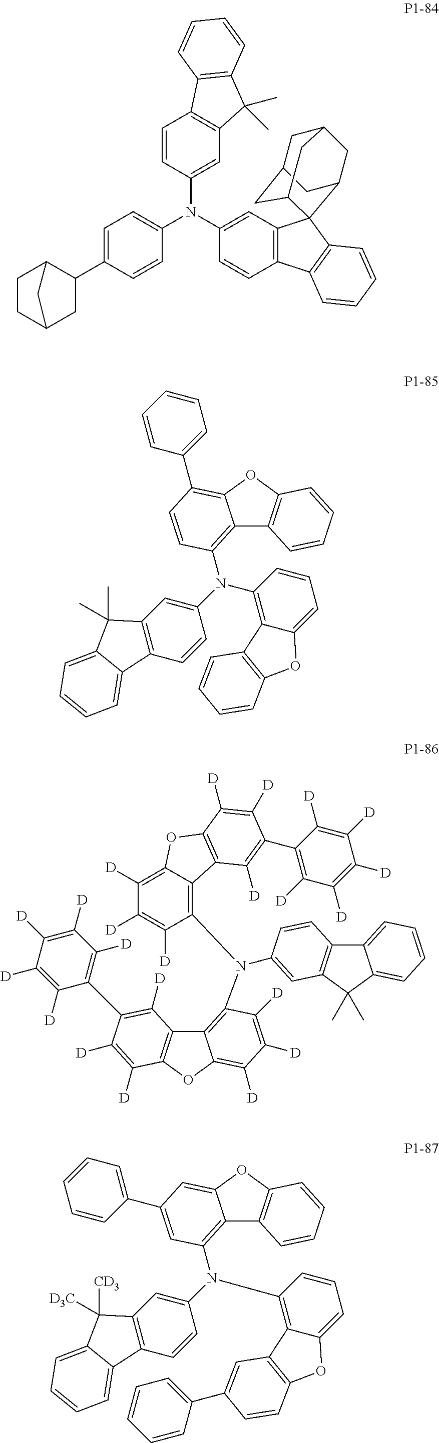

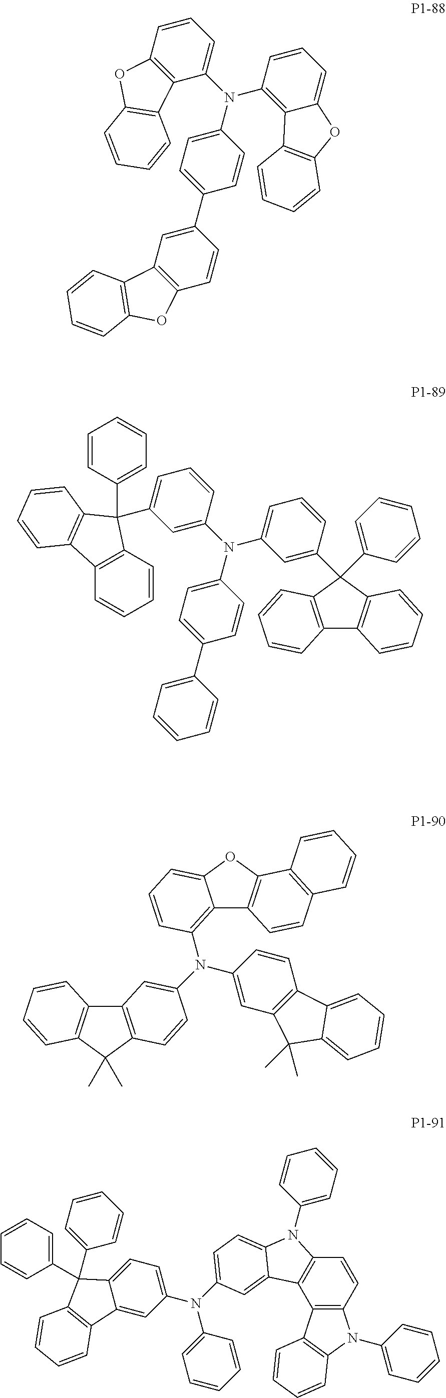 [SMILES: c1ccc2c(c1)oc1ccc(-c3ccc(N(c4cccc5oc6ccccc6c45)c4cccc5oc6ccccc6c45)cc3)cc12 ; c1ccc(-c2ccc(N(c3cccc(C4(c5ccccc5)c5ccccc5-c5ccccc54)c3)c3cccc(C4(c5ccccc5)c5ccccc5-c5ccccc54)c3)cc2)cc1 ; CC1(C)c2ccccc2-c2cc(N(c3ccc4c(c3)C(C)(C)c3ccccc3-4)c3cccc4oc5c6ccccc6ccc5c34)ccc21 ; c1ccc(N(c2ccc3c(c2)-c2ccccc2C3(c2ccccc2)c2ccccc2)c2ccc3c(c2)c2c4c5ccccc5n(-c5ccccc5)c4ccc2n3-c2ccccc2)cc1]

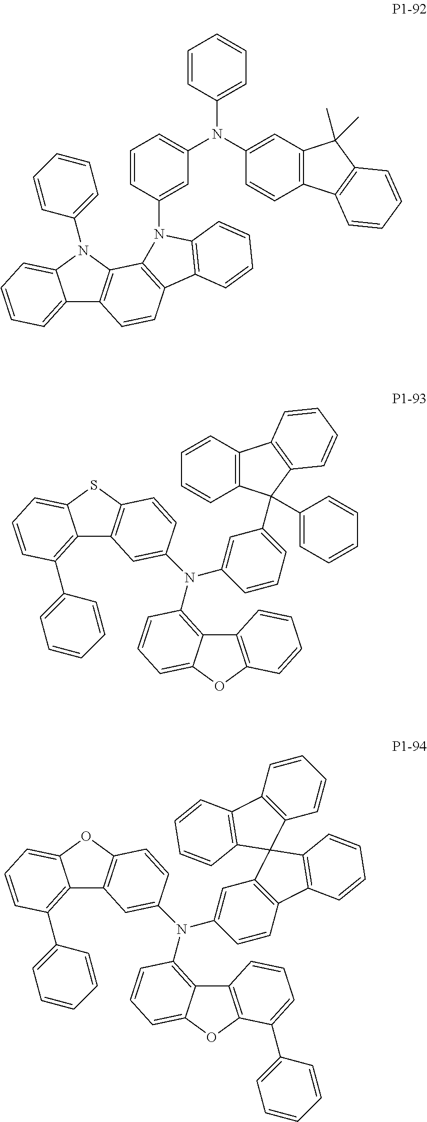 [SMILES: CC1(C)c2ccccc2-c2ccc(N(c3ccccc3)c3cccc(-n4c5ccccc5c5ccc6c7ccccc7n(-c7ccccc7)c6c54)c3)cc21 ; c1ccc(-c2cccc3sc4ccc(N(c5cccc(C6(c7ccccc7)c7ccccc7-c7ccccc76)c5)c5cccc6oc7ccccc7c56)cc4c23)cc1 ; c1ccc(-c2cccc3c2oc2cccc(N(c4ccc5c(c4)C4(c6ccccc6-c6ccccc64)c4ccccc4-5)c4ccc5oc6cccc(-c7ccccc7)c6c5c4)c23)cc1]

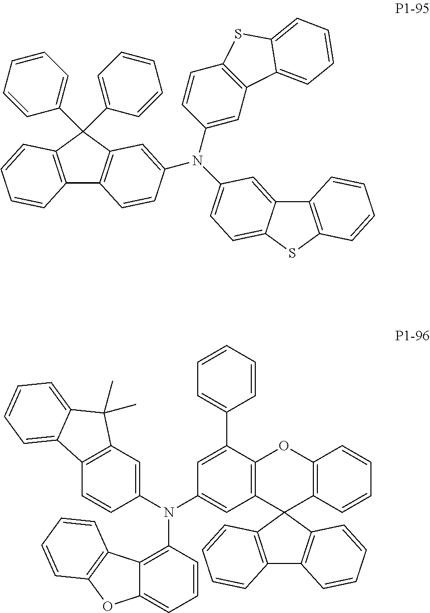 [SMILES: c1ccc(C2(c3ccccc3)c3ccccc3-c3ccc(N(c4ccc5sc6ccccc6c5c4)c4ccc5sc6ccccc6c5c4)cc32)cc1 ; CC1(C)c2ccccc2-c2ccc(N(c3cc(-c4ccccc4)c4c(c3)C3(c5ccccc5O4)c4ccccc4-c4ccccc43)c3cccc4oc5ccccc5c34)cc21]

Specifically, the compound represented by Formula 2 may be any one of the following compounds P2-1 to P2-76, but is not limited thereto.

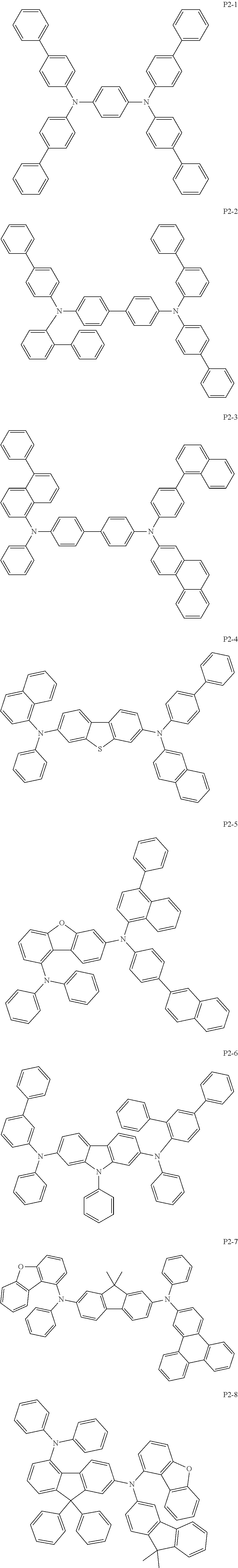

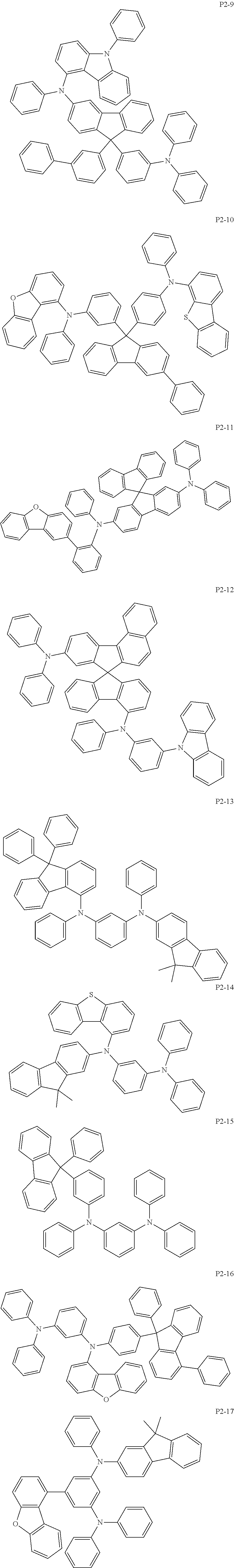

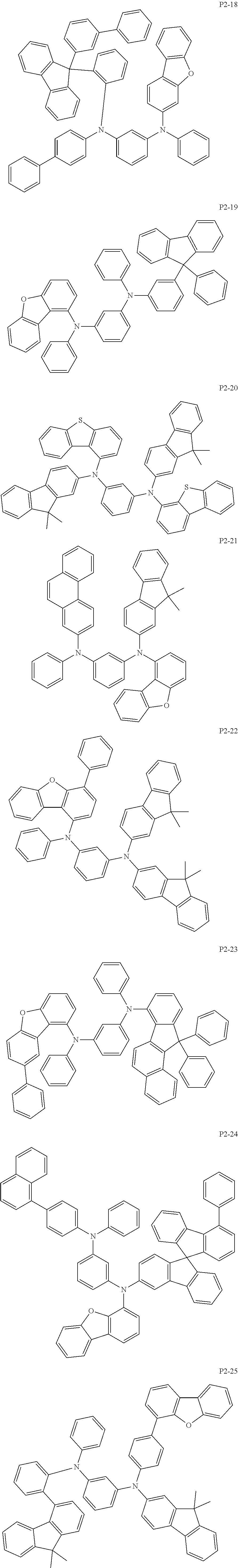

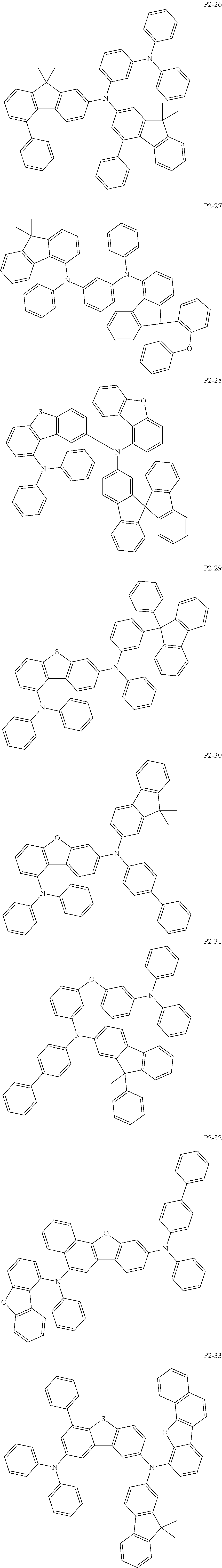

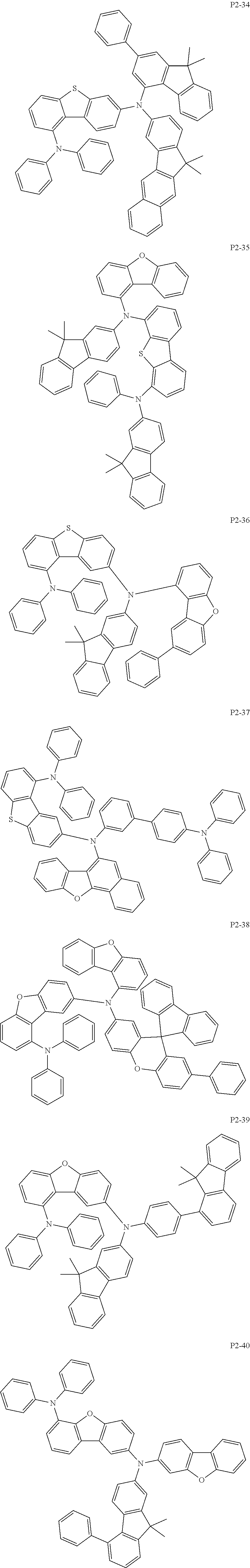

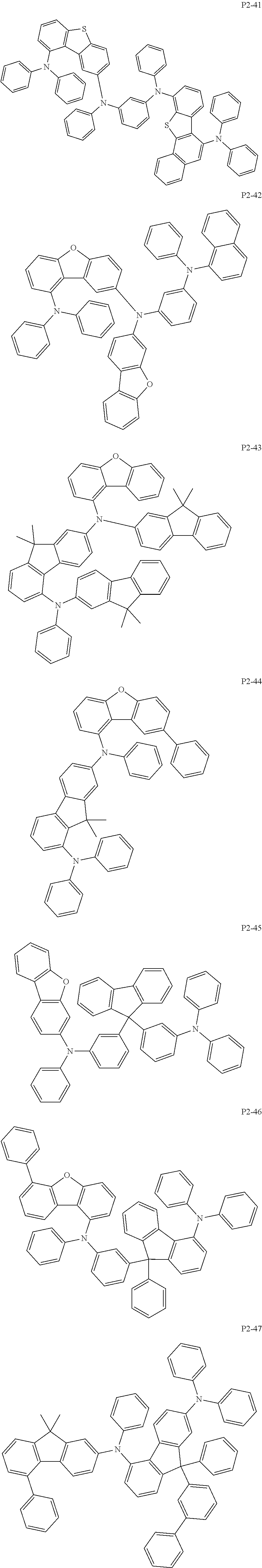

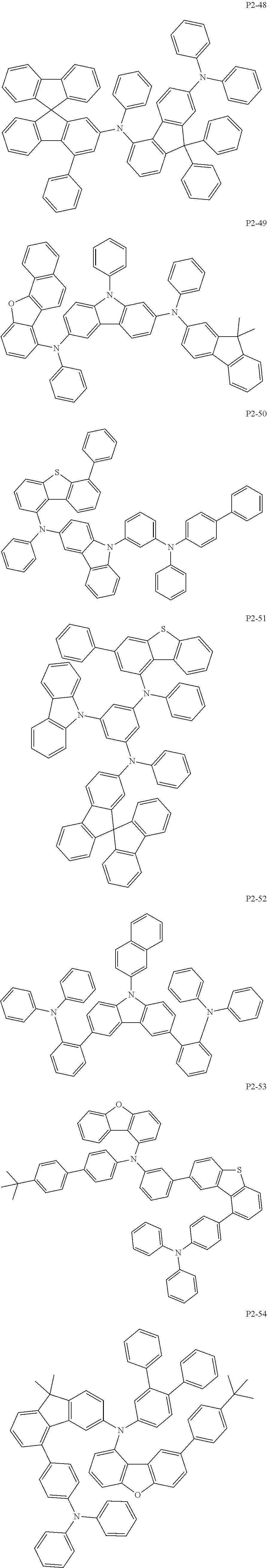

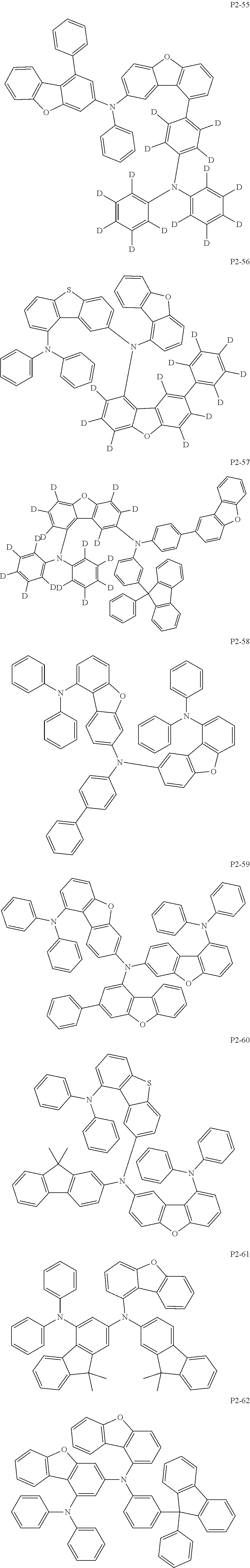

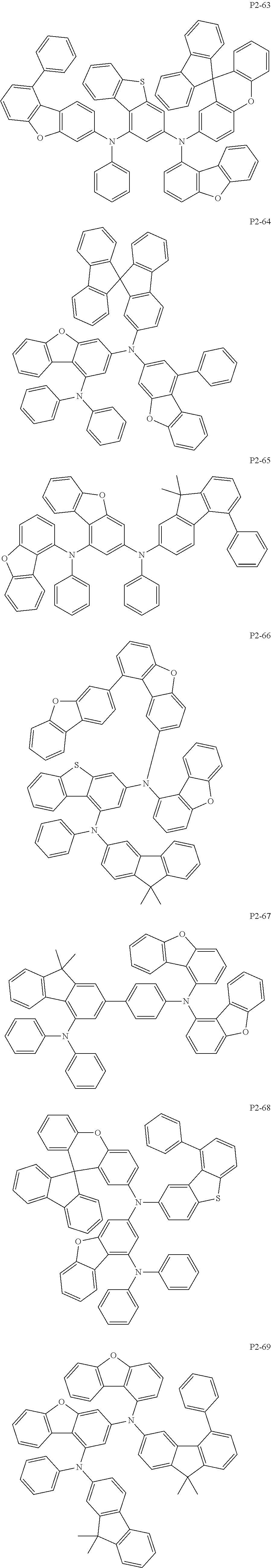

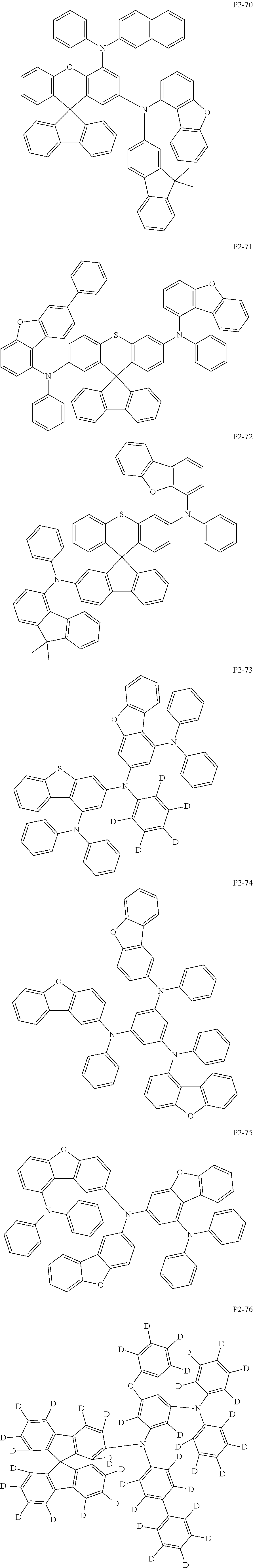

The emitting-auxiliary layer plays a role in transporting and injecting holes from the hole transport layer to the emitting layer and in blocking electrons from the emitting layer to the hole transport layer. At this time, by controlling the injection of holes between the hole transport layer and the emitting-auxiliary layer, the amount of holes and electrons in the emitting layer can be controlled to be balanced. Here, the balance between the amount of holes and the amount of electrons means that the holes and electrons injected into the emitting layer recombine within the emitting layer to effectively form excitons for light emission. For example, if the amount of holes in the emitting layer becomes greater than the amount of electrons, non-radiative decay of holes are generated in addition to the holes involved in recombination, resulting in a loss of quantum efficiency of the element.

Therefore, by achieving a quantitative balance of injected holes and electrons, the amount of holes and electrons that are extinguished without contributing to light emission can be reduced, thereby affecting the element characteristics.

When there is an excess of holes in the emitting layer, the amount of holes injected in the hole transport band, such as the hole transport layer, buffer layer, and emitting-auxiliary layer, can be reduced to achieve a balance between holes and electrons in the emitting layer. In general, the hole mobility of the hole transport band, such as the hole transport layer, buffer layer, and emitting-auxiliary layer provided between the anode side terminal and the emitting layer, exhibits a faster characteristic than the electron mobility of the electron transport band, such as the electron transport-auxiliary layer and electron transport layer provided between the cathode and the emitting layer.

Therefore, it is important to control the amount of holes injected into the emitting layer in order to increase the luminescence efficiency of the element, and it may be more effective to control the injection of holes between the hole transport layer and the emitting-auxiliary layer than to control the injection of holes from the emitting-auxiliary layer to the emitting layer. Additionally, a buffer layer may be further included between the hole transport layer and the emitting-auxiliary layer.

The amount of holes injected into the emitting layer can be controlled depending on the emitting-auxiliary layer. When the hole trapping between the emitting-auxiliary layer and the emitting layer becomes stronger, V_{Cmax}-V_{C(0.8 nF)} exceeds 1.3 V, which means that hole accumulation between the emitting-auxiliary layer and the emitting layer continues to occur. This can cause efficiency reduction and lifetime reduction due to the inability to form exciton and the unbalance of the amount of holes and electrons within the emitting layer due to the accumulation of carriers. If the hole accumulation between the emitting-auxiliary layer and the emitting layer is alleviated and the balance according to the hole injection control is improved, V_{Cmax}-V_{C(0.8 nF)} shows a characteristic of less than 1.3 V, which can be said to be a characteristic of an organic electronic element in which not only hole accumulation is minimized but exciton formation is smooth. Therefore, the element characteristics of V_{Cmax}-V_{C(0.8 nF)} are less than 1.3 V, and the efficiency of the organic electronic element can be improved and the operating time can be extended through the element design with the minimized value of V_{Cmax}.

In an OLED display, each pixel is made up of different colored subpixels to emit the desired color. Subpixels are fabricated by depositing a white-emitting OLED stack covering the entire surface of the matrix and positioning RGB (red, green, and blue) or RGBW (red, green, blue, and white) color filters on top of the OLED stack. Alternatively, different primary color OLED layers are configured within the subpixels. In this case, it is desirable to structure only the emitting layer after depositing common layers (layers prior to the emitting layer, hole injection layer, hole transport layer, emitting-auxiliary layer, etc.). However, it is observed that in the above 2 cases, they can interact through parasitic currents passing through the common layer of the OLED stack. Undesirable interaction between adjacent pixels or subpixels is known as “crosstalk”. Crosstalk leads to undesirable color shifts, especially in the case of color screens. (See Korean Patent No. 10-1647160)

In the case of an OLED device such as FIG. 1, parasitic currents are observed in adjacent pixels or subpixels, not only in common layers but also in layers formed by overlapping layers of each color without being deposited perfectly separately during the process.

In this case, it is thought that the stability of the OLED device will be improved by limiting the parasitic current by controlling the lateral resistance change rate.

Preferably, the emitting layer according to the present invention is a red emitting layer or a green emitting layer, and preferably includes a phosphorescent emitter.

According to another embodiment of the present invention, the organic material layer may be formed in a form in which a plurality of stacks including a hole transport layer, an emitting-auxiliary layer, an emitting layer, and an electron transport layer are formed.

In general, organic light-emitting devices can be divided into single-light-emitting structure devices (Single OLED) and multilayer light-emitting structure devices (Tandem OLED) depending on the number of light-emitting parts. A multilayer light-emitting structure device (Tandem OLED) is an OLED device composed of 2 or more light-emitting parts (stack), and can easily improve efficiency and lifetime compared to existing single OLEDs.

Specifically, an organic electronic element according to one embodiment of the present invention may comprise a first electrode, a first stack formed on the first electrode, a second stack formed on the first stack, and a second electrode. Wherein, the stack may correspond to an organic material layer including an emitting layer, and a light efficiency enhancing layer may be further formed on a surface of the first electrode and/or the second electrode that is not in contact with the organic material layer.

The first stack and the second stack are organic material layers comprising a hole transport layer, an emitting layer, and an electron transport layer, respectively, and the first stack and the second stack can be formed with the same or different laminated structures.

At least one of the first stack and the second stack may comprise an emitting-auxiliary layer between the hole transport layer and the emitting layer, wherein the emitting-auxiliary layer may be a mixture containing the third compound. Wherein, the third compound may be an organic compound, an organometallic compound, or a metal compound. Additionally, a buffer layer may be comprised between the hole transport layer and the emitting-auxiliary layer, wherein the buffer layer may be comprised in the first stack and/or the second stack.

Additionally, a charge generation layer (CGL) can be formed between the first stack and the second stack. The charge generation layer (CGL) may comprise a first charge generation layer and a second charge generation layer. These charge generation layers (CGLs) are formed between the emitting layers of the first stack and the emitting layers of the second stack to increase the current efficiency generated in each emitting layer and to smoothly distribute charges.

2 or more stacks of these organic material layers can be formed. For example, when 3 stacks are formed, a charge generation layer (CGL) and a third stack can be additionally laminated on the second stack.

In this manner, when a plurality of emitting layers is formed by a multilayer stack structure, it is possible to manufacture an organic light-emitting device that emits white light through the mixing effect of the light emitted from each emitting layer, and it is also possible to manufacture an organic light-emitting device that emits light of various colors.

The present invention may further comprise a light efficiency enhancing layer formed on at least one surface of the first electrode and the second electrode, which is opposite to the organic material layer.

Additionally, the organic material layer may comprise 2 or more stacks comprising a hole transport layer, an emitting layer, and an electron transport layer sequentially formed on the anode, and the organic material layer may further comprise a charge generation layer formed between the 2 or more stacks.

The organic material layer according to the present invention can be manufactured with a smaller number of layers by using various polymer materials, and not by a deposition method, but by a solution process or a solvent process, such as a spin coating process, a nozzle printing process, an inkjet printing process, a slot coating process, a dip coating process, a roll-to-roll process, a doctor blading process, a screen printing process, or a thermal transfer method. Since the organic material layer according to the present invention can be formed by various methods, the scope of the present invention is not limited by the formation method.

An organic electronic element according to one embodiment of the present invention may be a front-emitting, back-emitting, or both-sided emitting type depending on the material used.

Additionally, the organic electronic element according to one embodiment of the present invention may be selected from the group consisting of an organic light-emitting device, an organic solar cell, an organic photoconductor, an organic transistor, a monochrome lighting device, and a quantum dot display device.

Another embodiment of the present invention may include a display device comprising the organic electronic element of the present invention described above, and an electronic device comprising a control unit for driving the display device. Wherein the electronic device may be a current or future wired or wireless communication terminal, and includes all electronic devices such as mobile communication terminals such as mobile phones, PDAs, electronic dictionaries, PMPs, remote controls, navigation systems, game consoles, various TVs, and various computers.

Hereinafter, Synthesis examples of the compound represented by Formula 1 and Formula 2 according to the present invention and preparation examples of the organic electronic element will be described in detail by way of example, but are not limited to the following examples.

### [Synthesis Example 1] Synthesis Example of Formula 1

The compound (final products) represented by Formula 1 according to the present invention can be synthesized according to the reaction path of Reaction Scheme 1, but is not limited thereto.

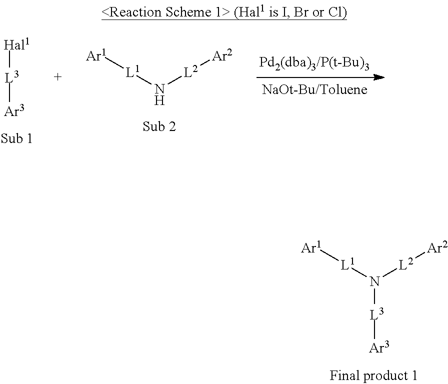

### I. Synthesis Example of Sub 1

Compounds belonging to Sub 1 of Reaction scheme 1 may be, but are not limited to, the compounds below, and Table 1 shows the FD-MS (Field Desorption Mass Spectrometry) values of the compounds below.

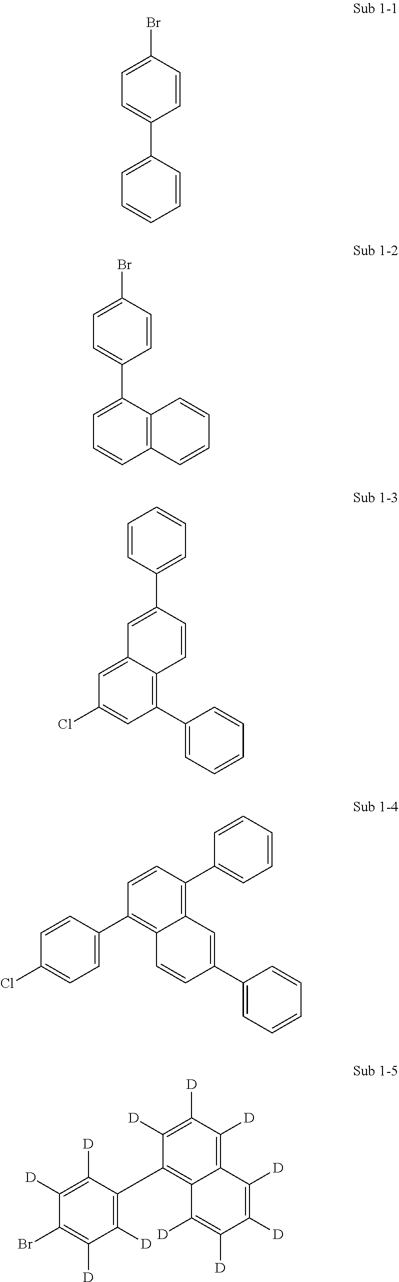 [SMILES: Brc1ccc(-c2ccccc2)cc1 ; Brc1ccc(-c2cccc3ccccc23)cc1 ; Clc1cc(-c2ccccc2)c2ccc(-c3ccccc3)cc2c1 ; Clc1ccc(-c2ccc(-c3ccccc3)c3cc(-c4ccccc4)ccc23)cc1 ; [2H]c1c([2H])c(-c2c([2H])c([2H])c([2H])c3c([2H])c([2H])c([2H])c([2H])c23)c([2H])c([2H])c1Br]

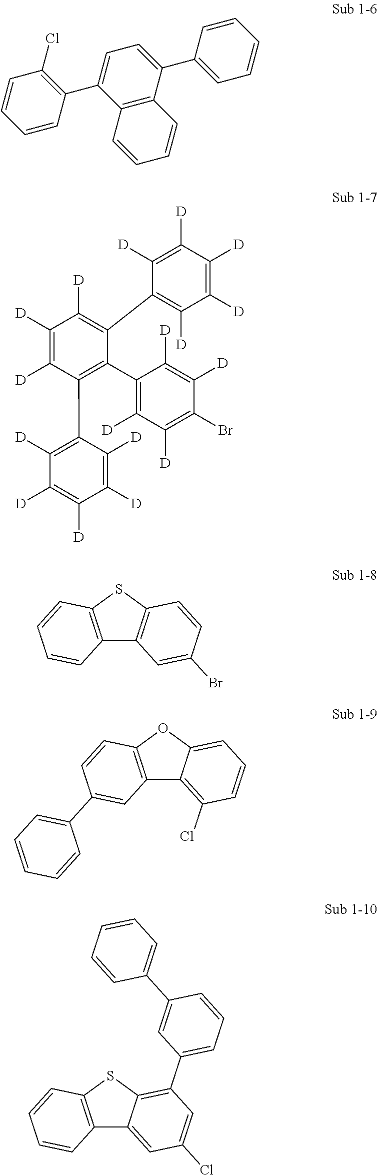 [SMILES: Clc1ccccc1-c1ccc(-c2ccccc2)c2ccccc12 ; [2H]c1c([2H])c([2H])c(-c2c([2H])c([2H])c([2H])c(-c3c([2H])c([2H])c([2H])c([2H])c3[2H])c2-c2c([2H])c([2H])c(Br)c([2H])c2[2H])c([2H])c1[2H] ; Brc1ccc2sc3ccccc3c2c1 ; Clc1cccc2oc3ccc(-c4ccccc4)cc3c12 ; Clc1cc(-c2cccc(-c3ccccc3)c2)c2sc3ccccc3c2c1]

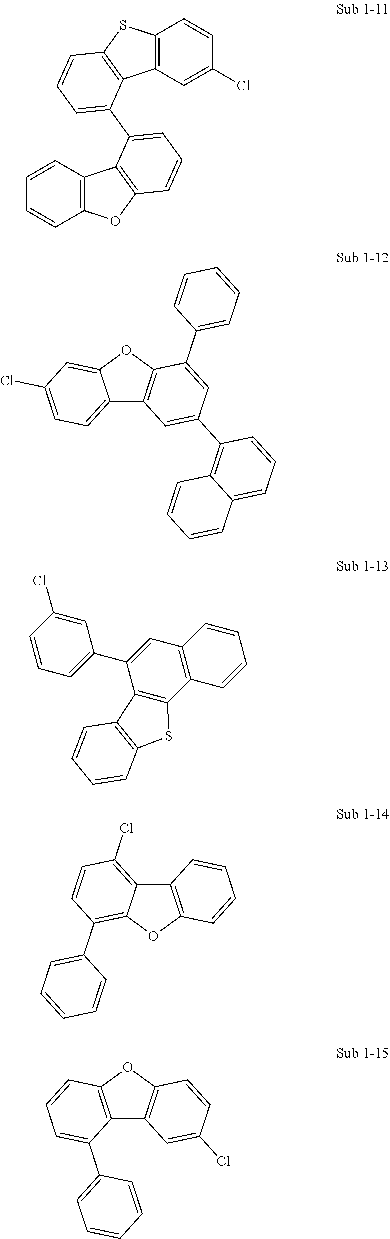 [SMILES: Clc1ccc2sc3cccc(-c4cccc5oc6ccccc6c45)c3c2c1 ; Clc1ccc2c(c1)oc1c(-c3ccccc3)cc(-c3cccc4ccccc34)cc12 ; Clc1cccc(-c2cc3ccccc3c3sc4ccccc4c23)c1 ; Clc1ccc(-c2ccccc2)c2oc3ccccc3c12 ; Clc1ccc2oc3cccc(-c4ccccc4)c3c2c1]

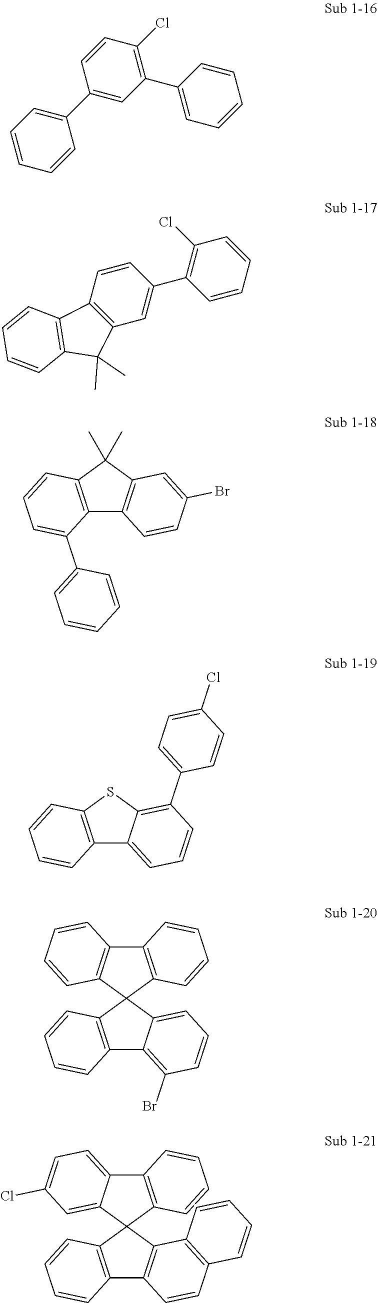

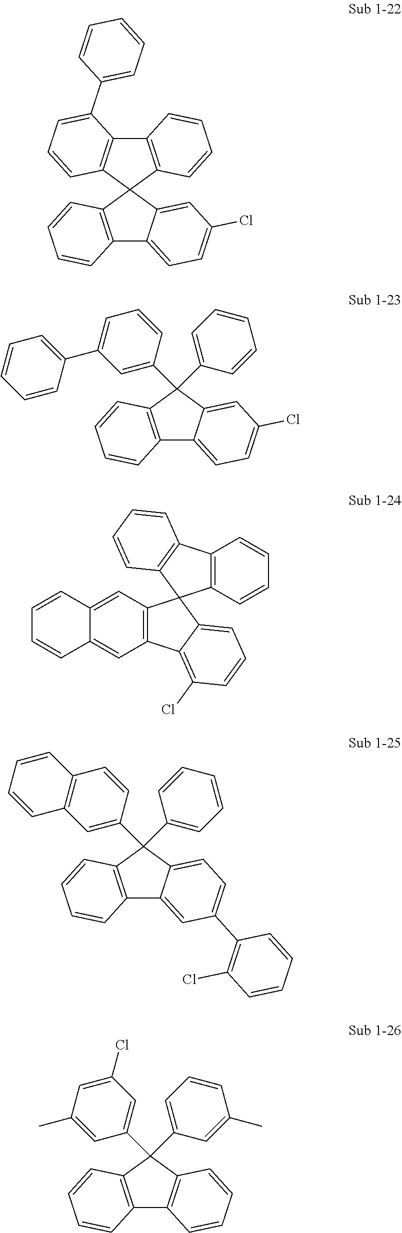

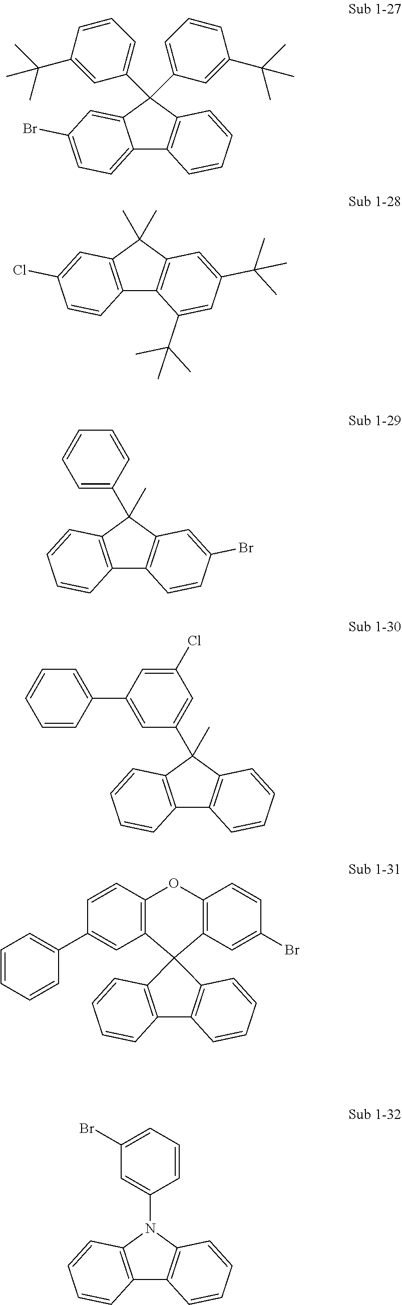

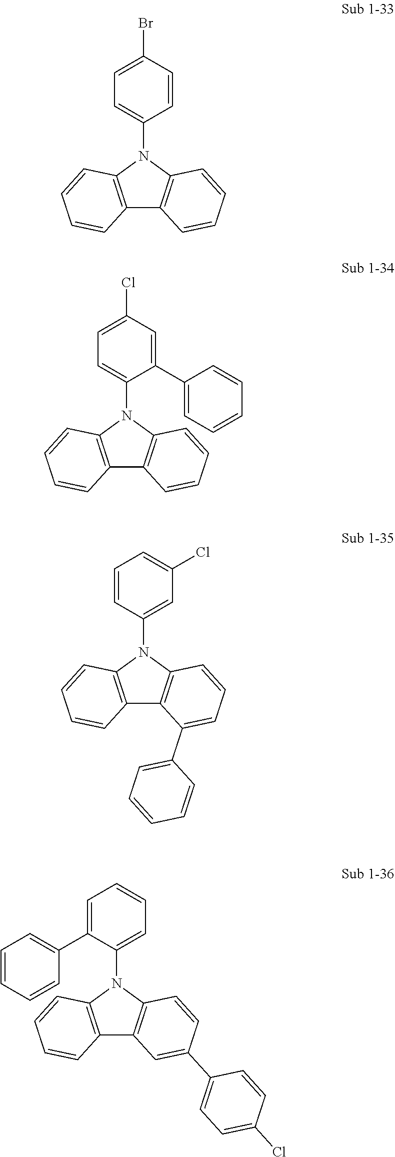 [SMILES: Brc1ccc(-n2c3ccccc3c3ccccc32)cc1 ; Clc1ccc(-n2c3ccccc3c3ccccc32)c(-c2ccccc2)c1 ; Clc1cccc(-n2c3ccccc3c3c(-c4ccccc4)cccc32)c1 ; Clc1ccc(-c2ccc3c(c2)c2ccccc2n3-c2ccccc2-c2ccccc2)cc1]

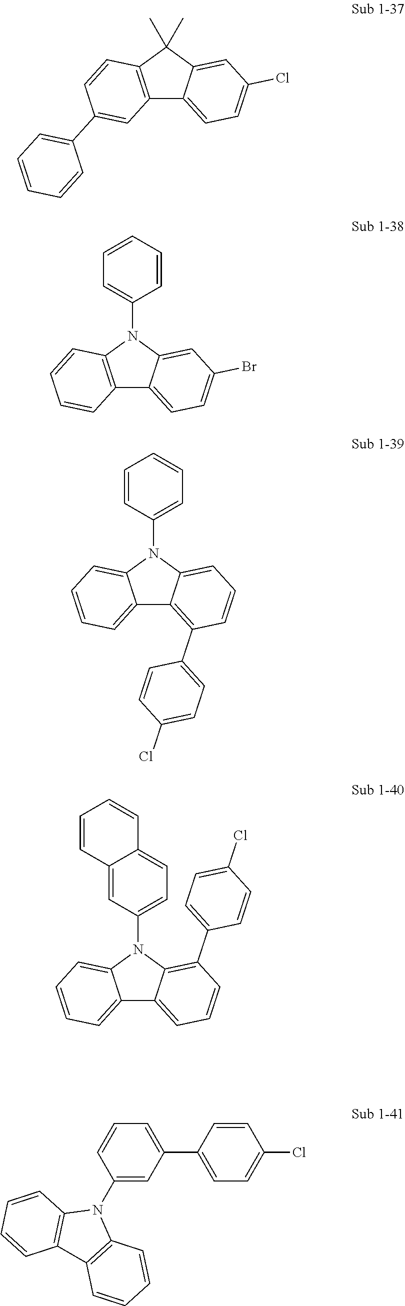

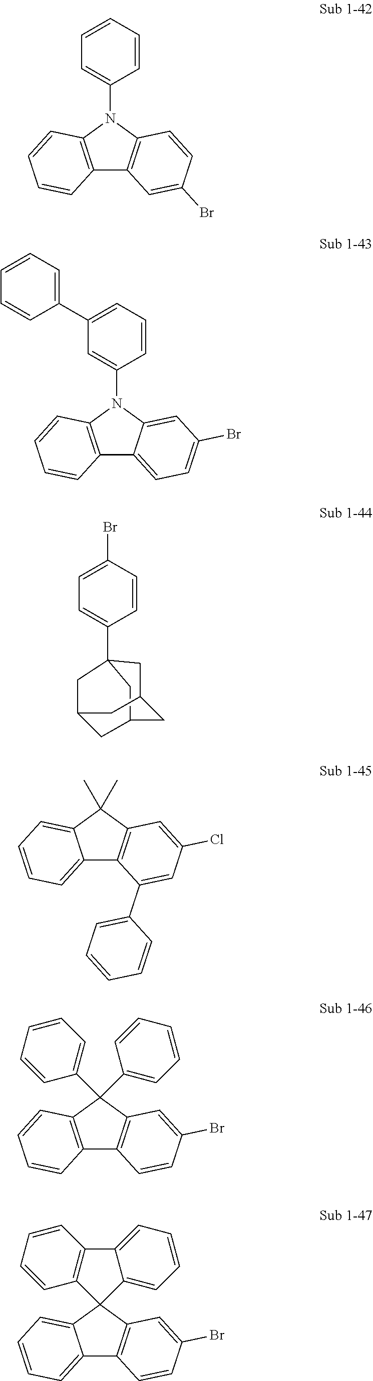

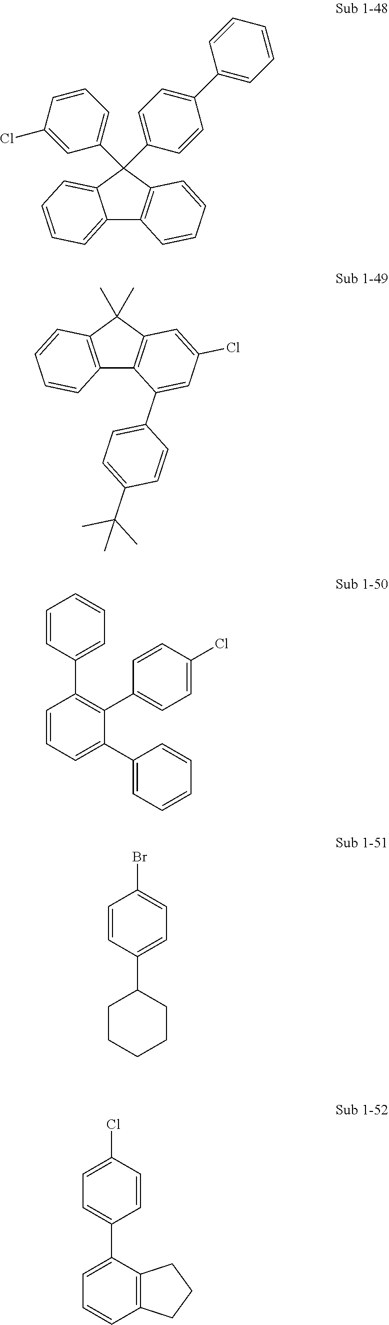

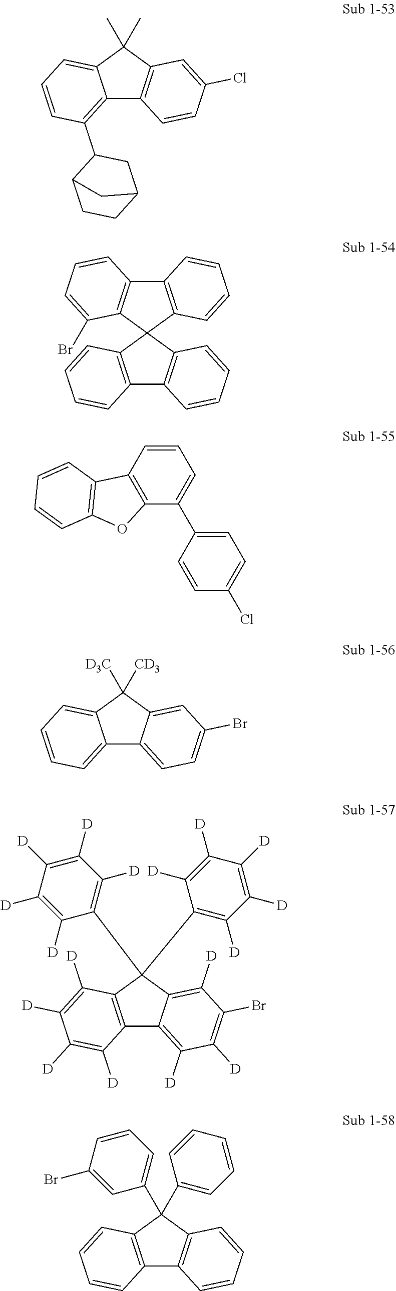

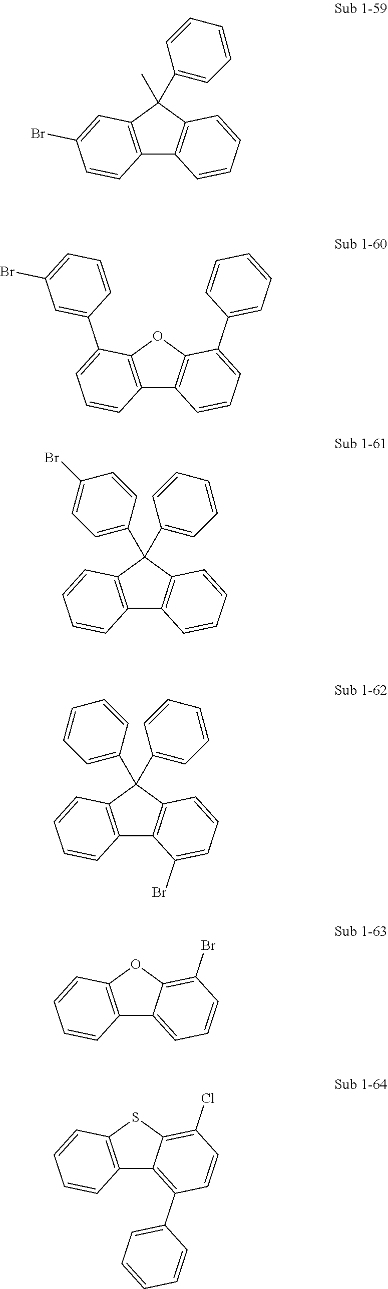 [SMILES: CC1(c2ccccc2)c2ccccc2-c2ccc(Br)cc21 ; Brc1cccc(-c2cccc3c2oc2c(-c4ccccc4)cccc23)c1 ; Brc1ccc(C2(c3ccccc3)c3ccccc3-c3ccccc32)cc1 ; Brc1cccc2c1-c1ccccc1C2(c1ccccc1)c1ccccc1 ; Brc1cccc2c1oc1ccccc12 ; Clc1ccc(-c2ccccc2)c2c1sc1ccccc12]

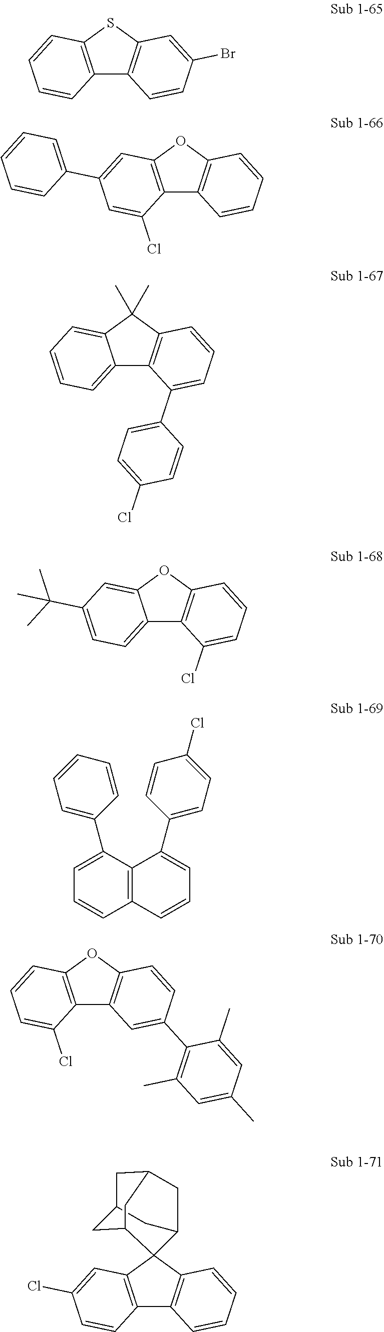

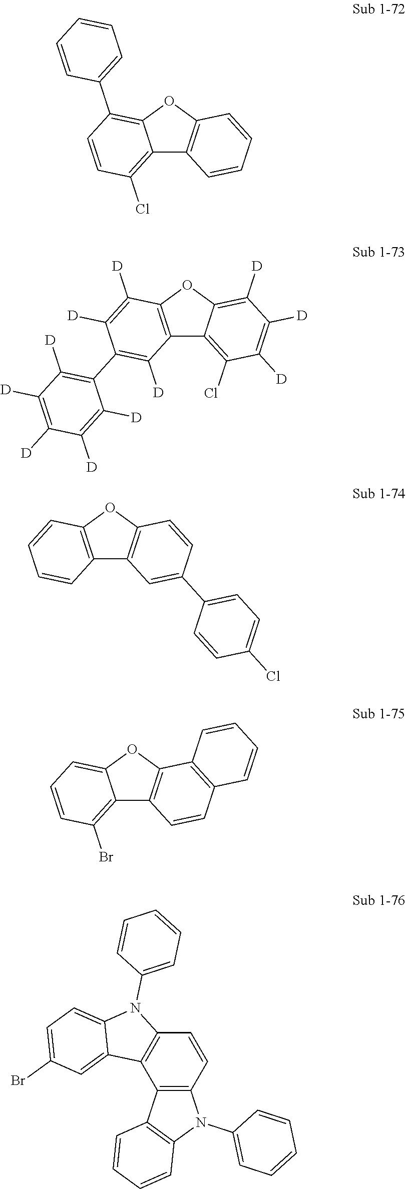

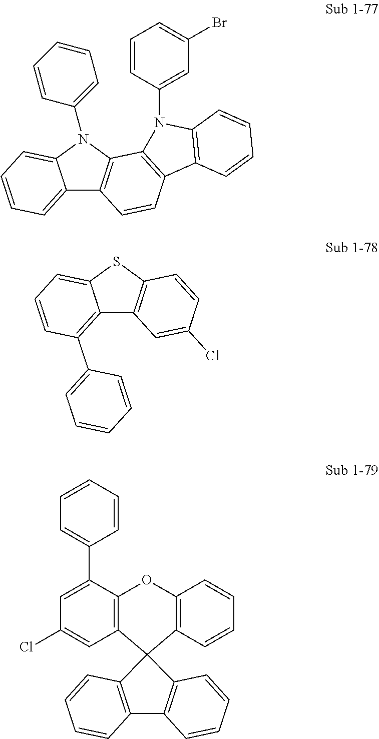 [SMILES: Brc1cccc(-n2c3ccccc3c3ccc4c5ccccc5n(-c5ccccc5)c4c32)c1 ; Clc1ccc2sc3cccc(-c4ccccc4)c3c2c1 ; Clc1cc(-c2ccccc2)c2c(c1)C1(c3ccccc3O2)c2ccccc2-c2ccccc21]

TABLE 1

| compound | FD-MS | compound | FD-MS |
|---|---|---|---|
| Sub 1-1 | m/z = 231.99(C12H9Br = 233.11) | Sub 1-2 | m/z = 282(C16H11Br = 283.17) |
| Sub 1-3 | m/z = 314.09(C22H15Cl = 314.81) | Sub 1-4 | m/z = 390.12(C28H19Cl = 390.91) |
| Sub 1-5 | m/z = 293.07(C16D11Br = 294.24) | Sub 1-6 | m/z = 314.09(C22H15Cl = 314.81) |
| Sub 1-7 | m/z = 401.16(C24D17Br = 402.41) | Sub 1-8 | m/z = 261.95(C12H7BrS = 263.15) |
| Sub 1-9 | m/z = 278.05(C18H11ClO = 278.74) | Sub 1-10 | m/z = 370.06(C24H15ClS = 370.89) |
| Sub 1-11 | m/z = 384.04(C24H13ClOS = 384.88) | Sub 1-12 | m/z = 404.1(C28H17ClO = 404.89) |
| Sub 1-13 | m/z = 344.04(C22H13ClS = 344.86) | Sub 1-14 | m/z = 278.05(C18H11ClO = 278.74) |
| Sub 1-15 | m/z = 278.05(C18H11ClO = 278.74) | Sub 1-16 | m/z = 264.07(C18H13Cl = 264.75) |
| Sub 1-17 | m/z = 304.1(C21H17Cl = 304.82) | Sub 1-18 | m/z = 348.05(C21H17Br = 349.27) |
| Sub 1-19 | m/z = 294.03(C18H11ClS = 294.8) | Sub 1-20 | m/z = 394.04(C25H15Br = 395.3) |
| Sub 1-21 | m/z = 400.1(C29H17Cl = 400.9) | Sub 1-22 | m/z = 426.12(C31H19Cl = 426.94) |
| Sub 1-23 | m/z = 428.13(C31H21Cl = 428.96) | Sub 1-24 | m/z = 400.1(C29H17Cl = 400.9) |
| Sub 1-25 | m/z = 478.15(C35H23Cl = 479.02) | Sub 1-26 | m/z = 380.13(C27H21Cl = 380.91) |
| Sub 1-27 | m/z = 506.16(C33H31Br = 507.51) | Sub 1-28 | m/z = 340.2(C23H29Cl = 340.93) |
| Sub 1-29 | m/z = 334.04(C20H15Br = 335.24) | Sub 1-30 | m/z = 366.12(C26H19Cl = 366.89) |
| Sub 1-31 | m/z = 486.06(C31H19BrO = 487.4) | Sub 1-32 | m/z = 321.02(C18H12BrN = 322.2) |
| Sub 1-33 | m/z = 321.02(C18H12BrN = 322.2) | Sub 1-34 | m/z = 353.1(C24H16ClN = 353.85) |
| Sub 1-35 | m/z = 353.1(C24H16ClN = 353.85) | Sub 1-36 | m/z = 429.13(C30H20ClN = 429.95) |
| Sub 1-37 | m/z = 304.1(C21H17Cl = 304.82) | Sub 1-38 | m/z = 321.02(C18H12BrN = 322.2) |
| Sub 1-39 | m/z = 353.1(C24H16ClN = 353.85) | Sub 1-40 | m/z = 403.11(C28H18ClN = 403.91) |
| Sub 1-41 | m/z = 353.1(C24H16ClN = 353.85) | Sub 1-42 | m/z = 321.02(C18H12BrN = 322.2) |
| Sub 1-43 | m/z = 397.05(C24H16BrN = 398.3) | Sub 1-44 | m/z = 290.07(C16H19Br = 291.23) |
| Sub 1-45 | m/z = 304.1(C21H17Cl = 304.82) | Sub 1-46 | m/z = 396.05(C25H17Br = 397.31) |
| Sub 1-47 | m/z = 394.04(C25H15Br = 395.3) | Sub 1-48 | m/z = 428.13(C31H21Cl = 428.96) |
| Sub 1-49 | m/z = 360.16(C25H25Cl = 360.92) | Sub 1-50 | m/z = 340.1(C24H17Cl = 340.85) |
| Sub 1-51 | m/z = 238.04(C12H15Br = 239.16) | Sub 1-52 | m/z = 228.07(C15H13Cl = 228.72) |
| Sub 1-53 | m/z = 322.15(C22H23Cl = 322.88) | Sub 1-54 | m/z = 394.04(C25H15Br = 395.3) |
| Sub 1-55 | m/z = 278.05(C18H11ClO = 278.74) | Sub 1-56 | m/z = 278.06(C15H7D6Br = 279.21) |
| Sub 1-57 | m/z = 413.16(C25D17Br = 414.42) | Sub 1-58 | m/z = 396.05(C25H17Br = 397.31) |
| Sub 1-59 | m/z = 334.04(C20H15Br = 335.24) | Sub 1-60 | m/z = 398.03(C24H15BrO = 399.29) |
| Sub 1-61 | m/z = 396.05(C25H17Br = 397.31) | Sub 1-62 | m/z = 396.05(C25H17Br = 397.31) |
| Sub 1-63 | m/z = 245.97(C12H7BrO = 247.09) | Sub 1-64 | m/z = 294.03(C18H11ClS = 294.8) |
| Sub 1-65 | m/z = 261.95(C12H7BrS = 263.15) | Sub 1-66 | m/z = 278.05(C18H11ClO = 278.74) |
| Sub 1-67 | m/z = 304.1(C21H17Cl = 304.82) | Sub 1-68 | m/z = 258.08(C16H15ClO = 258.75) |
| Sub 1-69 | m/z = 314.09(C22H15Cl = 314.81) | Sub 1-70 | m/z = 320.1(C21H17ClO = 320.82) |
| Sub 1-71 | m/z = 320.13(C22H21Cl = 320.86) | Sub 1-72 | m/z = 278.05(C18H11ClO = 278.74) |
| Sub 1-73 | m/z = 289.12(C18D11ClO = 289.8) | Sub 1-74 | m/z = 278.05(C18H11ClO = 278.74) |
| Sub 1-75 | m/z = 295.98(C16H9BrO = 297.15) | Sub 1-76 | m/z = 486.07(C30H19BrN2 = 487.4) |
| Sub 1-77 | m/z = 486.07(C30H19BrN2 = 487.4) | Sub 1-78 | m/z = 294.03(C18H11ClS = 294.8) |
| Sub 1-79 | m/z = 442.11(C31H19ClO = 442.94) | | |

### II. Synthesis Example of Sub 2

Compounds belonging to Sub 2 of Reaction scheme 1 may be, but are not limited to, the compounds below, and Table 2 shows the FD-MS (Field Desorption Mass Spectrometry) values of the compounds below.

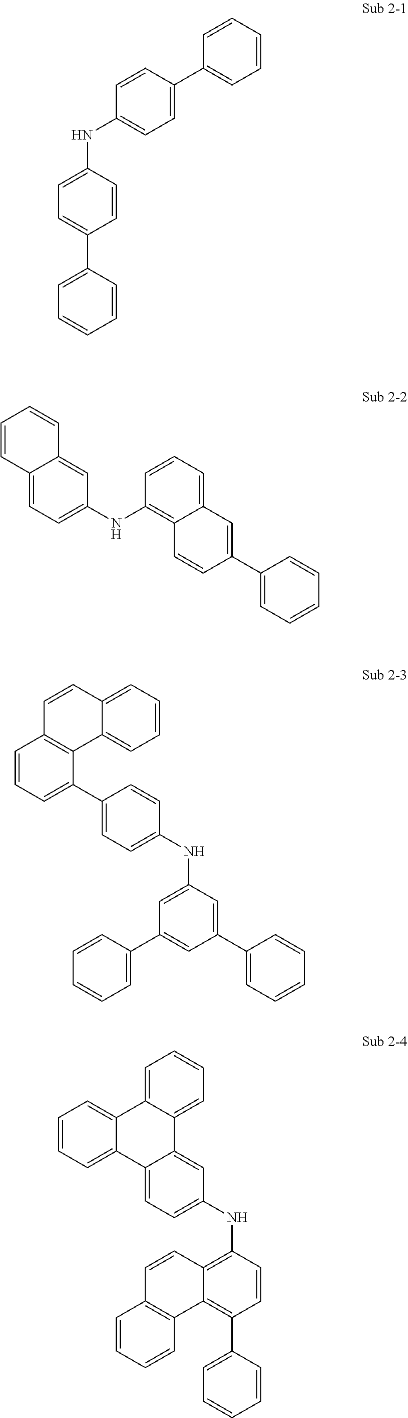 [SMILES: c1ccc(-c2ccc(Nc3ccc(-c4ccccc4)cc3)cc2)cc1 ; c1ccc(-c2ccc3c(Nc4ccc5ccccc5c4)cccc3c2)cc1 ; c1ccc(-c2cc(Nc3ccc(-c4cccc5ccc6ccccc6c45)cc3)cc(-c3ccccc3)c2)cc1 ; c1ccc(-c2ccc(Nc3ccc4c5ccccc5c5ccccc5c4c3)c3ccc4ccccc4c23)cc1]

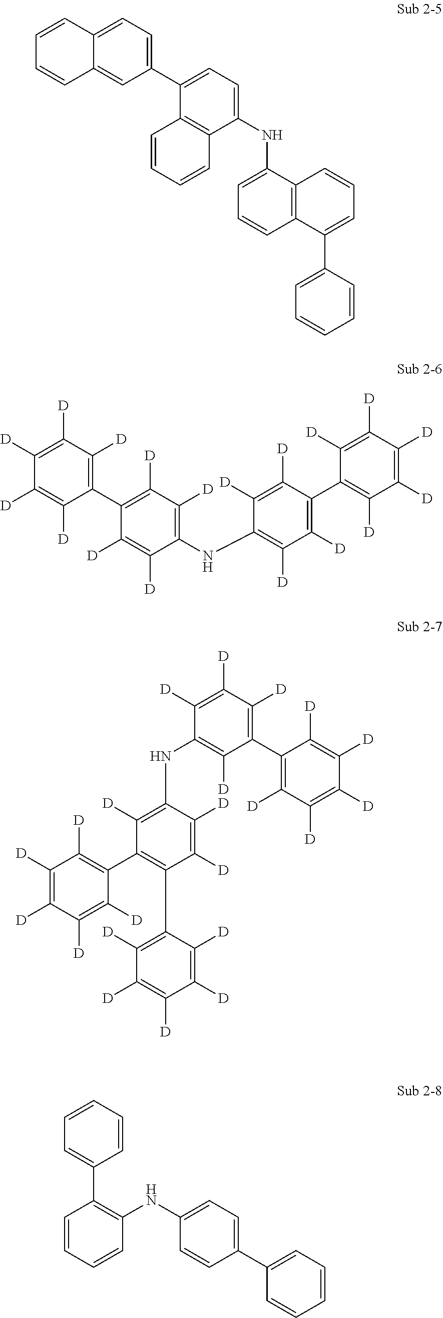 [SMILES: c1ccc(-c2cccc3c(Nc4ccc(-c5ccc6ccccc6c5)c5ccccc45)cccc23)cc1 ; [2H]c1c([2H])c([2H])c(-c2c([2H])c([2H])c(Nc3c([2H])c([2H])c(-c4c([2H])c([2H])c([2H])c([2H])c4[2H])c([2H])c3[2H])c([2H])c2[2H])c([2H])c1[2H] ; [2H]c1c([2H])c([2H])c(-c2c([2H])c([2H])c([2H])c(Nc3c([2H])c([2H])c(-c4c([2H])c([2H])c([2H])c([2H])c4[2H])c(-c4c([2H])c([2H])c([2H])c([2H])c4[2H])c3[2H])c2[2H])c([2H])c1[2H] ; c1ccc(-c2ccc(Nc3ccccc3-c3ccccc3)cc2)cc1]

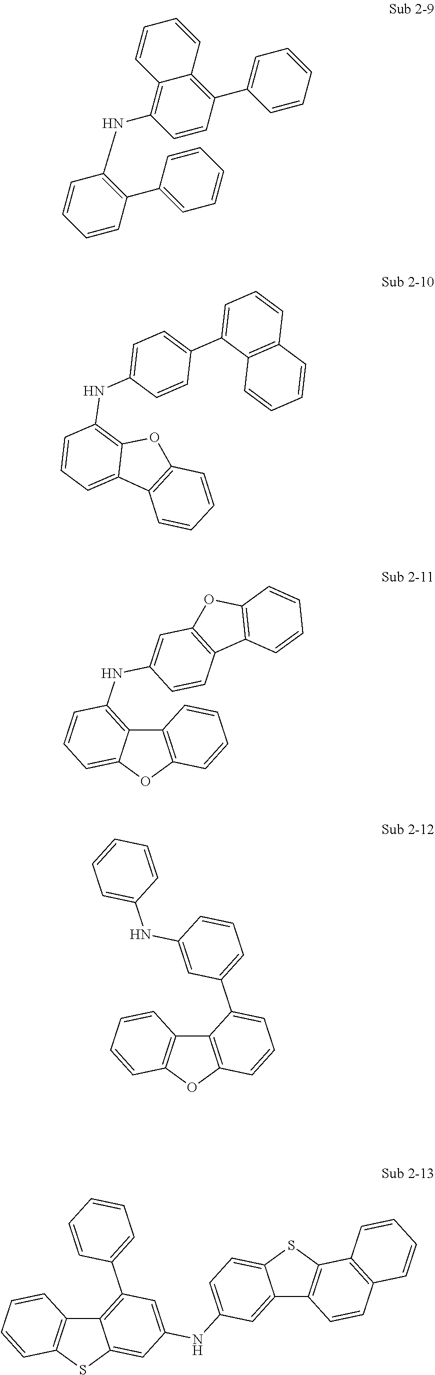 [SMILES: c1ccc(-c2ccccc2Nc2ccc(-c3ccccc3)c3ccccc23)cc1 ; c1ccc2c(-c3ccc(Nc4cccc5c4oc4ccccc45)cc3)cccc2c1 ; c1ccc2c(c1)oc1cc(Nc3cccc4oc5ccccc5c34)ccc12 ; c1ccc(Nc2cccc(-c3cccc4oc5ccccc5c34)c2)cc1 ; c1ccc(-c2cc(Nc3ccc4sc5c6ccccc6ccc5c4c3)cc3sc4ccccc4c23)cc1]

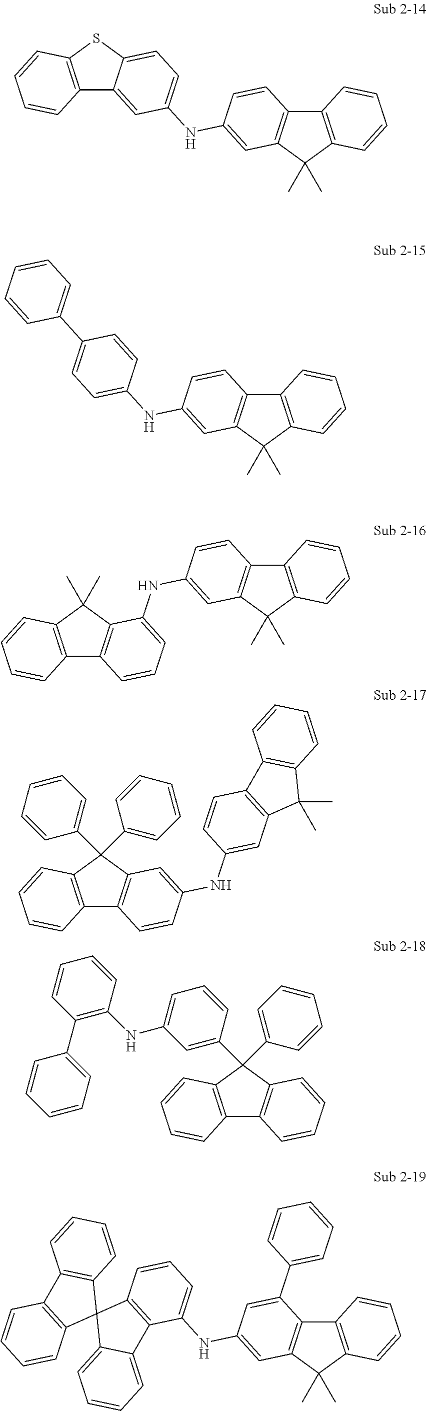

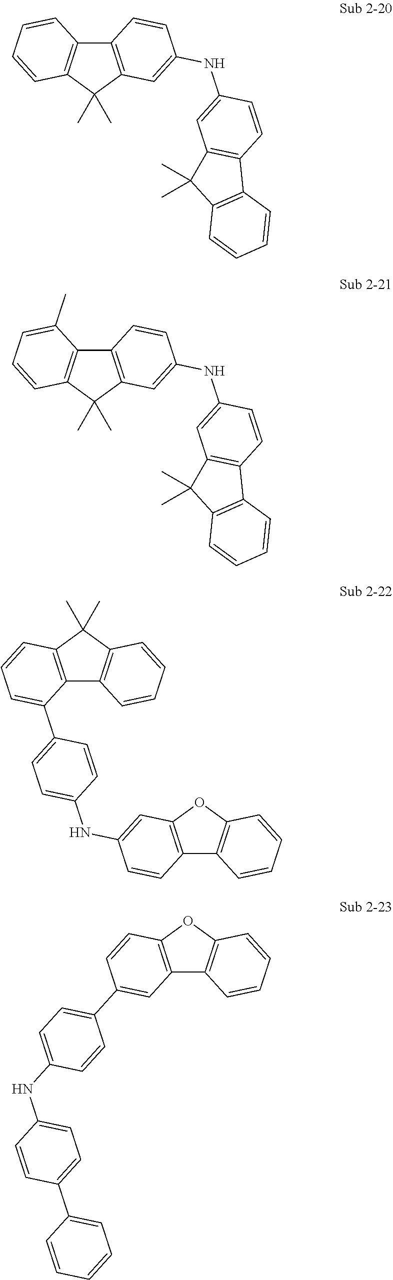 [SMILES: CC1(C)c2ccccc2-c2ccc(Nc3ccc4c(c3)C(C)(C)c3ccccc3-4)cc21 ; Cc1cccc2c1-c1ccc(Nc3ccc4c(c3)C(C)(C)c3ccccc3-4)cc1C2(C)C ; CC1(C)c2ccccc2-c2c(-c3ccc(Nc4ccc5c(c4)oc4ccccc45)cc3)cccc21 ; c1ccc(-c2ccc(Nc3ccc(-c4ccc5oc6ccccc6c5c4)cc3)cc2)cc1]

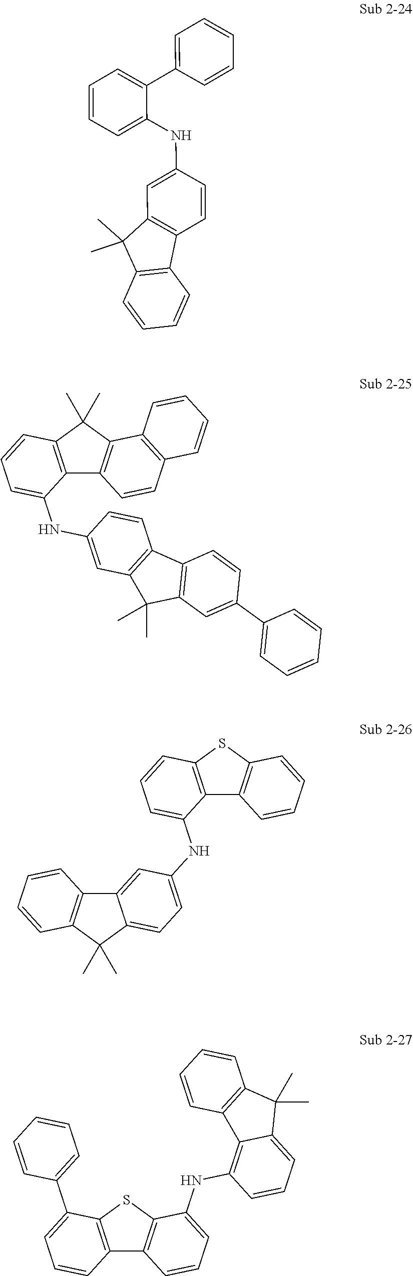 [SMILES: CC1(C)c2ccccc2-c2ccc(Nc3ccccc3-c3ccccc3)cc21 ; CC1(C)c2cc(Nc3cccc4c3-c3ccc5ccccc5c3C4(C)C)ccc2-c2ccc(-c3ccccc3)cc21 ; CC1(C)c2ccccc2-c2cc(Nc3cccc4sc5ccccc5c34)ccc21 ; CC1(C)c2ccccc2-c2c(Nc3cccc4c3sc3c(-c5ccccc5)cccc34)cccc21]

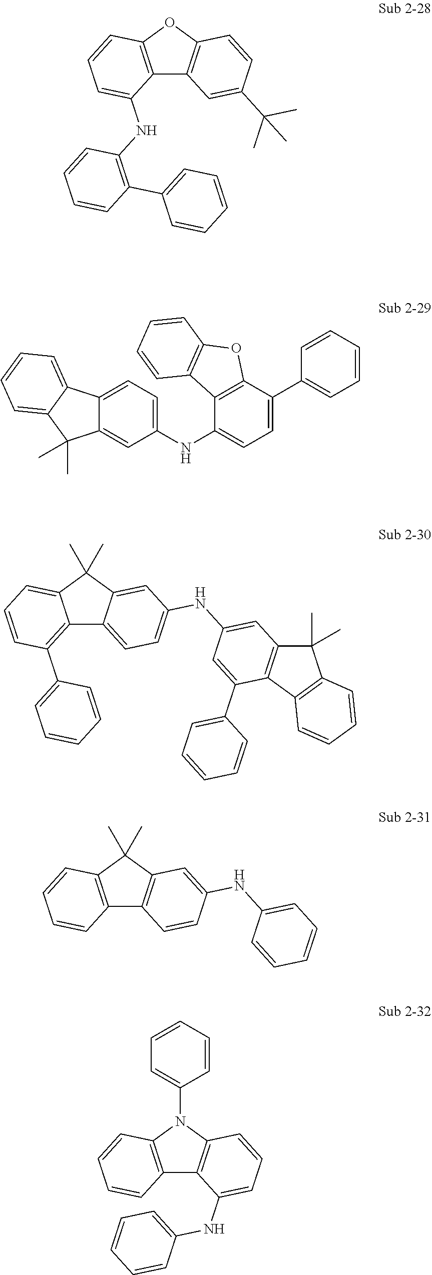 [SMILES: CC(C)(C)c1ccc2oc3cccc(Nc4ccccc4-c4ccccc4)c3c2c1 ; CC1(C)c2ccccc2-c2ccc(Nc3ccc(-c4ccccc4)c4oc5ccccc5c34)cc21 ; CC1(C)c2cc(Nc3cc(-c4ccccc4)c4c(c3)C(C)(C)c3ccccc3-4)ccc2-c2c(-c3ccccc3)cccc21 ; CC1(C)c2ccccc2-c2ccc(Nc3ccccc3)cc21 ; c1ccc(Nc2cccc3c2c2ccccc2n3-c2ccccc2)cc1]

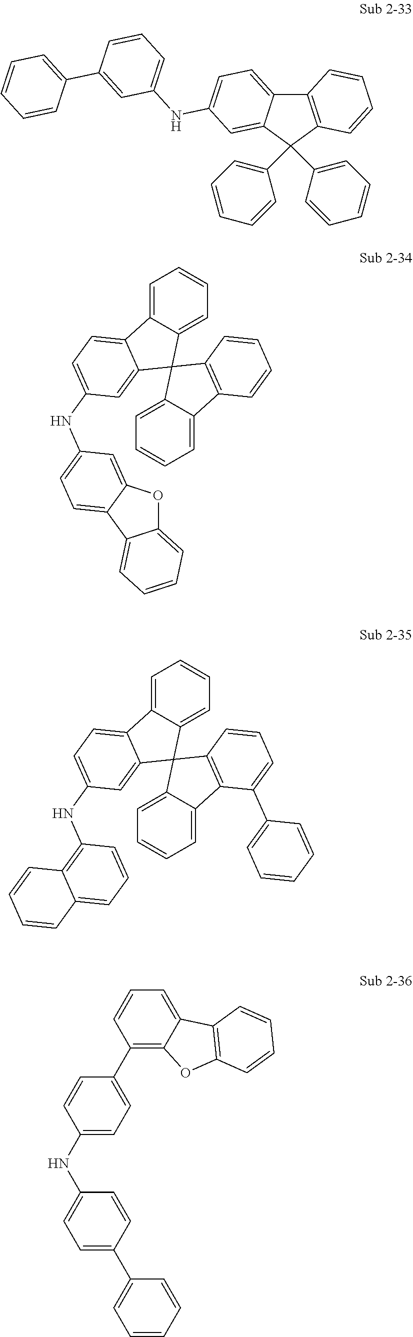 [SMILES: c1ccc(-c2cccc(Nc3ccc4c(c3)C(c3ccccc3)(c3ccccc3)c3ccccc3-4)c2)cc1 ; c1ccc2c(c1)-c1ccccc1C21c2ccccc2-c2ccc(Nc3ccc4c(c3)oc3ccccc34)cc21 ; c1ccc(-c2cccc3c2-c2ccccc2C32c3ccccc3-c3ccc(Nc4cccc5ccccc45)cc32)cc1 ; c1ccc(-c2ccc(Nc3ccc(-c4cccc5c4oc4ccccc45)cc3)cc2)cc1]

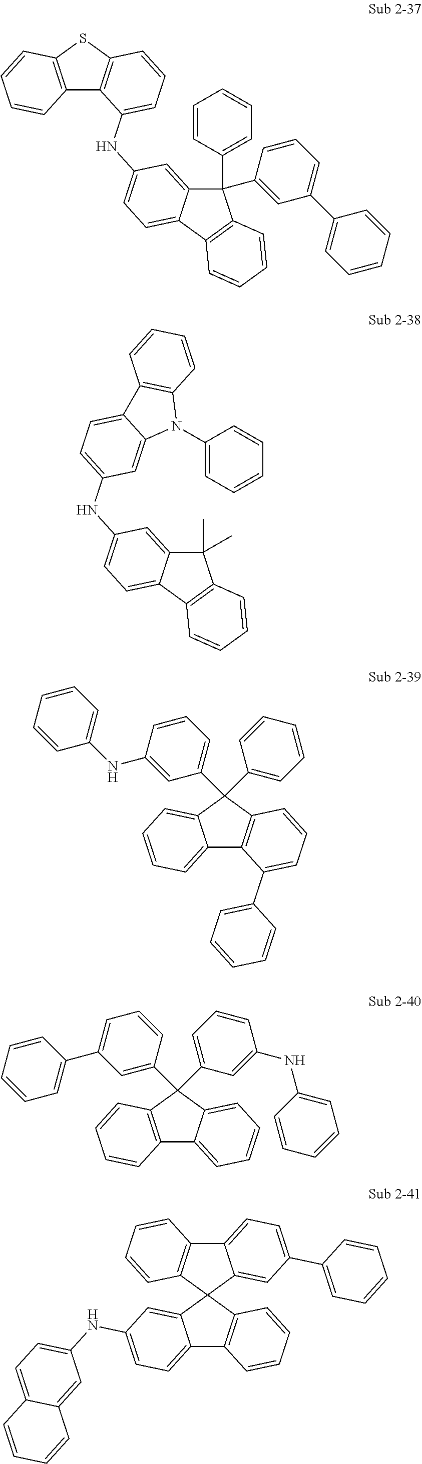 [SMILES: c1ccc(-c2cccc(C3(c4ccccc4)c4ccccc4-c4ccc(Nc5cccc6sc7ccccc7c56)cc43)c2)cc1 ; CC1(C)c2ccccc2-c2ccc(Nc3ccc4c5ccccc5n(-c5ccccc5)c4c3)cc21 ; c1ccc(Nc2cccc(C3(c4ccccc4)c4ccccc4-c4c(-c5ccccc5)cccc43)c2)cc1 ; c1ccc(Nc2cccc(C3(c4cccc(-c5ccccc5)c4)c4ccccc4-c4ccccc43)c2)cc1 ; c1ccc(-c2ccc3c(c2)C2(c4ccccc4-c4ccc(Nc5ccc6ccccc6c5)cc42)c2ccccc2-3)cc1]

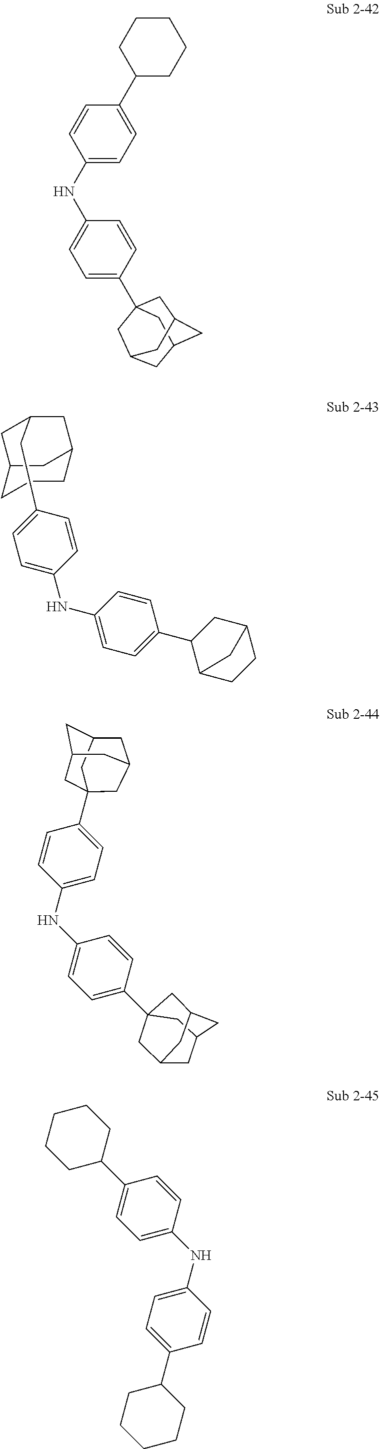 [SMILES: c1cc(C2CCCCC2)ccc1Nc1ccc(C23CC4CC(CC(C4)C2)C3)cc1 ; c1cc(Nc2ccc(C3CC4CCC3C4)cc2)ccc1CC1CC2CCCC(C2)C1 ; c1cc(C23CC4CC(CC(C4)C2)C3)ccc1Nc1ccc(C23CC4CC(CC(C4)C2)C3)cc1 ; c1cc(C2CCCCC2)ccc1Nc1ccc(C2CCCCC2)cc1]

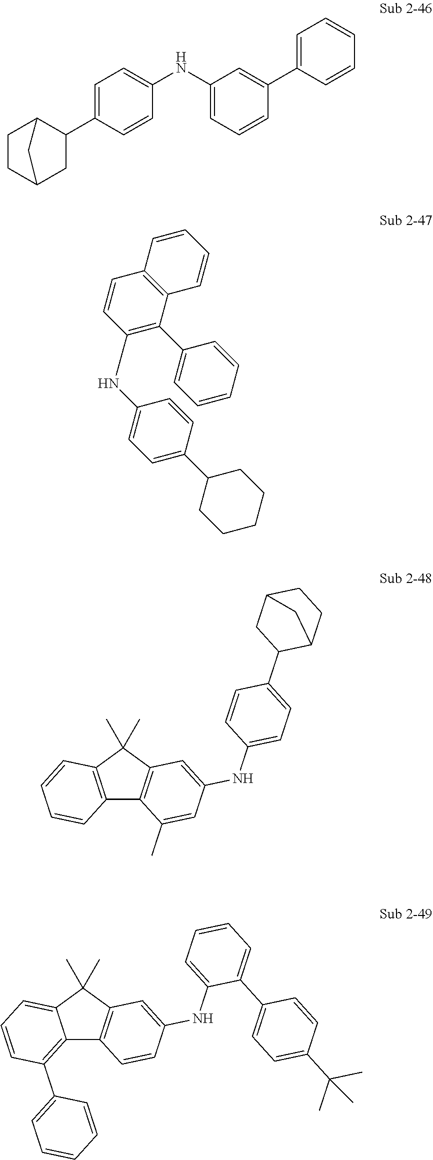 [SMILES: c1ccc(-c2cccc(Nc3ccc(C4CC5CCC4C5)cc3)c2)cc1 ; c1ccc(-c2c(Nc3ccc(C4CCCCC4)cc3)ccc3ccccc23)cc1 ; Cc1cc(Nc2ccc(C3CC4CCC3C4)cc2)cc2c1-c1ccccc1C2(C)C ; CC(C)(C)c1ccc(-c2ccccc2Nc2ccc3c(c2)C(C)(C)c2cccc(-c4ccccc4)c2-3)cc1]

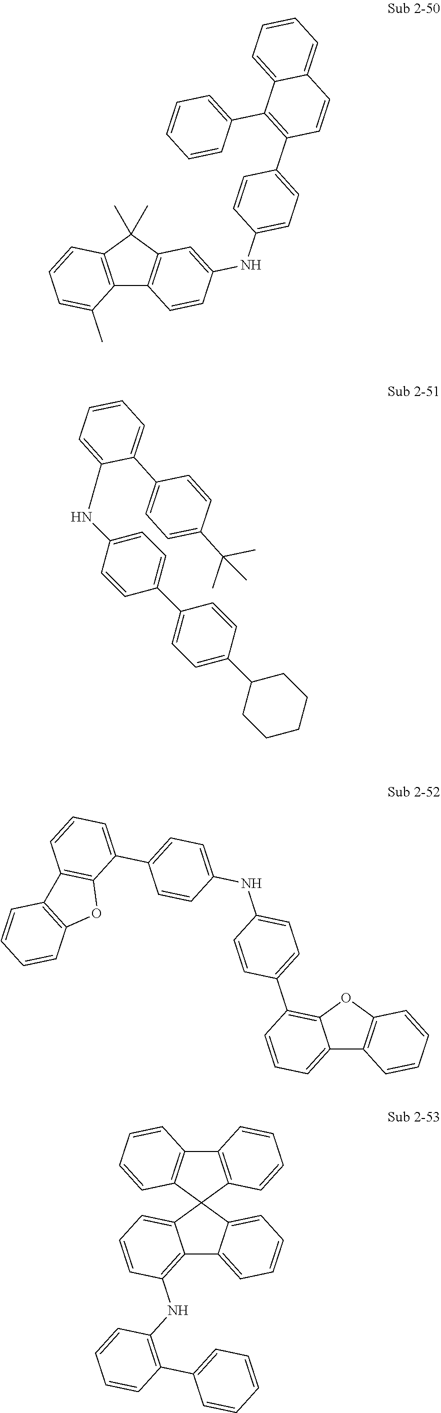 [SMILES: Cc1cccc2c1-c1ccc(Nc3ccc(-c4ccc5ccccc5c4-c4ccccc4)cc3)cc1C2(C)C ; CC(C)(C)c1ccc(-c2ccccc2Nc2ccc(-c3ccc(C4CCCCC4)cc3)cc2)cc1 ; c1ccc2c(c1)oc1c(-c3ccc(Nc4ccc(-c5cccc6c5oc5ccccc56)cc4)cc3)cccc12 ; c1ccc(-c2ccccc2Nc2cccc3c2-c2ccccc2C32c3ccccc3-c3ccccc32)cc1]

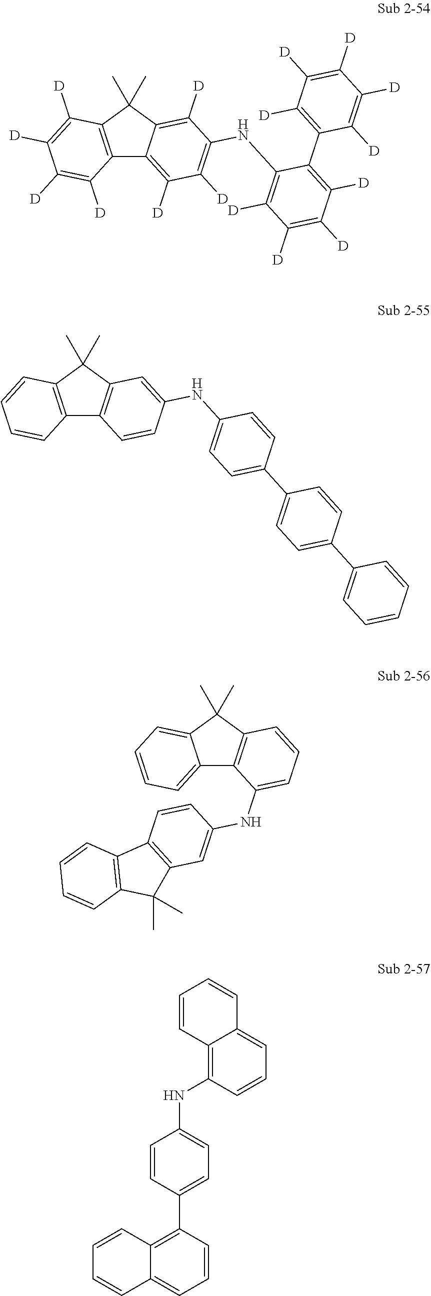 [SMILES: [2H]c1c([2H])c([2H])c(-c2c([2H])c([2H])c([2H])c([2H])c2Nc2c([2H])c([2H])c3c(c2[2H])C(C)(C)c2c([2H])c([2H])c([2H])c([2H])c2-3)c([2H])c1[2H] ; CC1(C)c2ccccc2-c2ccc(Nc3ccc(-c4ccc(-c5ccccc5)cc4)cc3)cc21 ; CC1(C)c2ccccc2-c2ccc(Nc3cccc4c3-c3ccccc3C4(C)C)cc21 ; c1ccc2c(Nc3ccc(-c4cccc5ccccc45)cc3)cccc2c1]

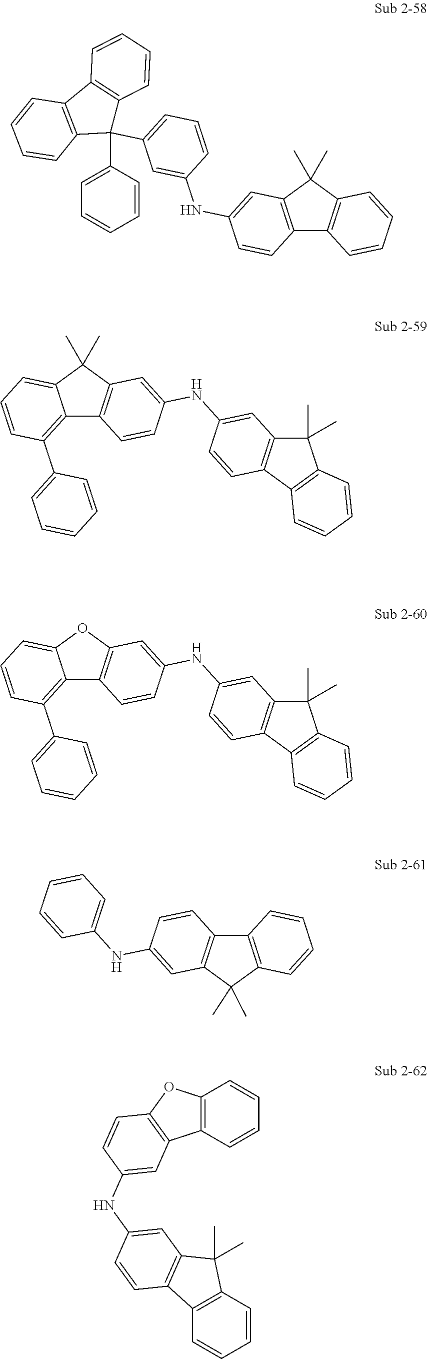 [SMILES: CC1(C)c2ccccc2-c2ccc(Nc3cccc(C4(c5ccccc5)c5ccccc5-c5ccccc54)c3)cc21 ; CC1(C)c2ccccc2-c2ccc(Nc3ccc4c(c3)C(C)(C)c3cccc(-c5ccccc5)c3-4)cc21 ; CC1(C)c2ccccc2-c2ccc(Nc3ccc4c(c3)oc3cccc(-c5ccccc5)c34)cc21 ; CC1(C)c2ccccc2-c2ccc(Nc3ccccc3)cc21 ; CC1(C)c2ccccc2-c2ccc(Nc3ccc4oc5ccccc5c4c3)cc21]

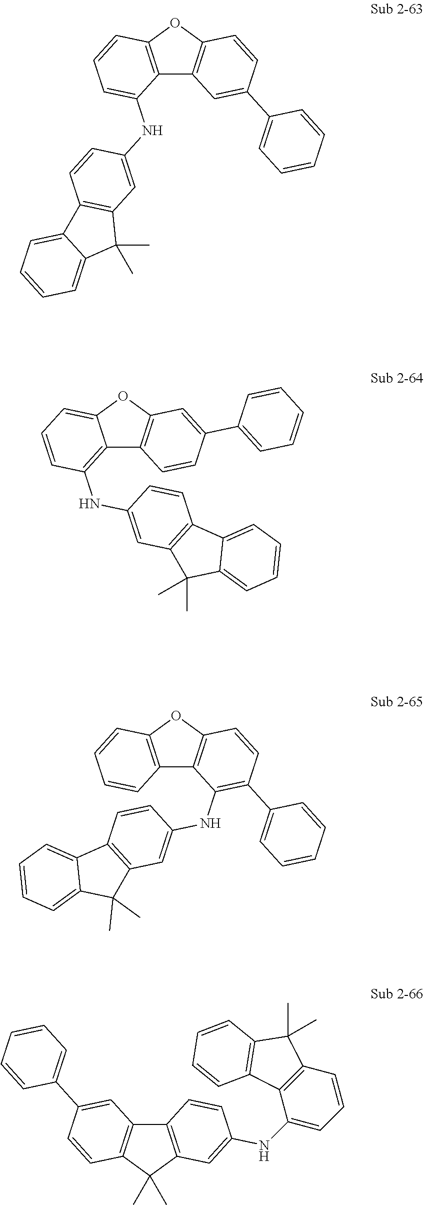 [SMILES: CC1(C)c2ccccc2-c2ccc(Nc3cccc4oc5ccc(-c6ccccc6)cc5c34)cc21 ; CC1(C)c2ccccc2-c2ccc(Nc3cccc4oc5cc(-c6ccccc6)ccc5c34)cc21 ; CC1(C)c2ccccc2-c2ccc(Nc3c(-c4ccccc4)ccc4oc5ccccc5c34)cc21 ; CC1(C)c2ccc(-c3ccccc3)cc2-c2ccc(Nc3cccc4c3-c3ccccc3C4(C)C)cc21]

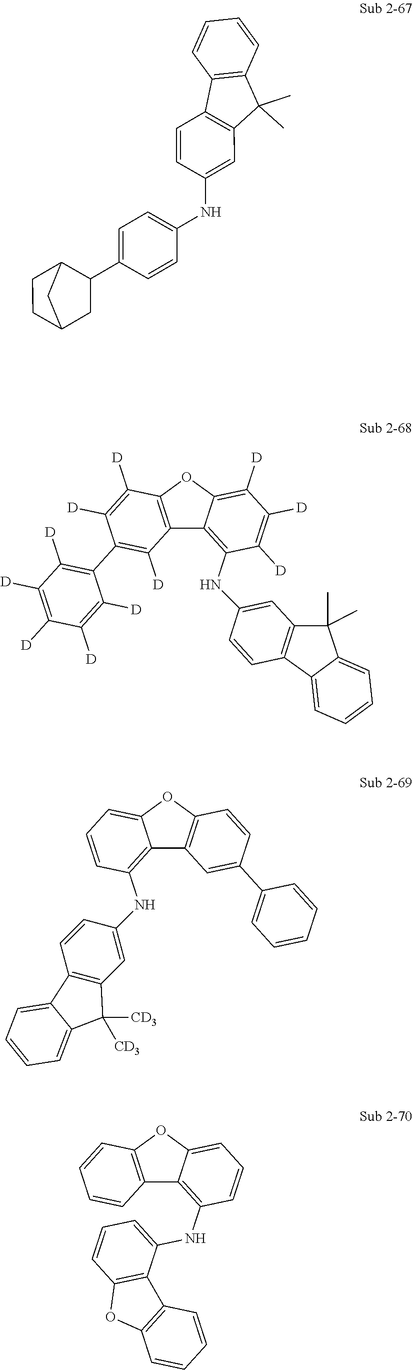 [SMILES: CC1(C)c2ccccc2-c2ccc(Nc3ccc(C4CC5CCC4C5)cc3)cc21 ; [2H]c1c([2H])c([2H])c(-c2c([2H])c([2H])c3oc4c([2H])c([2H])c([2H])c(Nc5ccc6c(c5)C(C)(C)c5ccccc5-6)c4c3c2[2H])c([2H])c1[2H] ; [2H]C([2H])([2H])C1(C([2H])([2H])[2H])c2ccccc2-c2ccc(Nc3cccc4oc5ccc(-c6ccccc6)cc5c34)cc21 ; c1ccc2c(c1)oc1cccc(Nc3cccc4oc5ccccc5c34)c12]

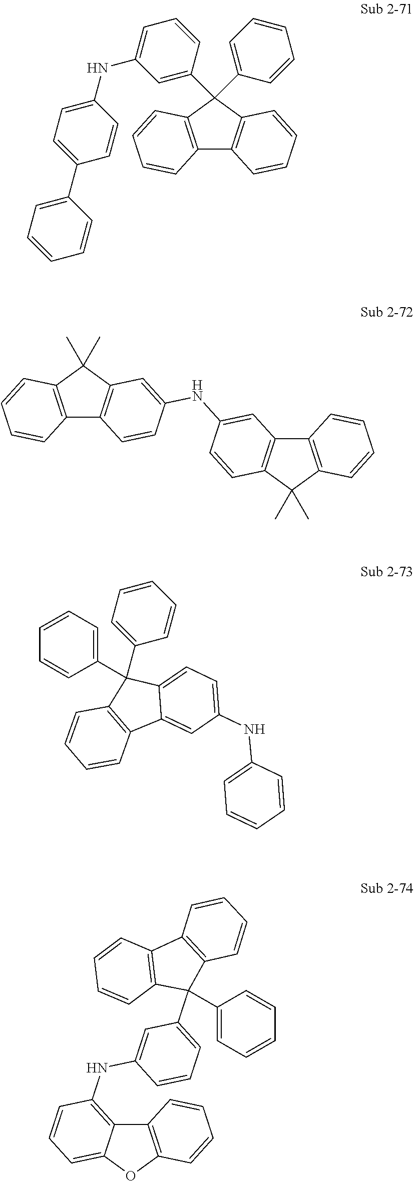 [SMILES: c1ccc(-c2ccc(Nc3cccc(C4(c5ccccc5)c5ccccc5-c5ccccc54)c3)cc2)cc1 ; CC1(C)c2ccccc2-c2cc(Nc3ccc4c(c3)C(C)(C)c3ccccc3-4)ccc21 ; c1ccc(Nc2ccc3c(c2)-c2ccccc2C3(c2ccccc2)c2ccccc2)cc1 ; c1ccc(C2(c3cccc(Nc4cccc5oc6ccccc6c45)c3)c3ccccc3-c3ccccc32)cc1]

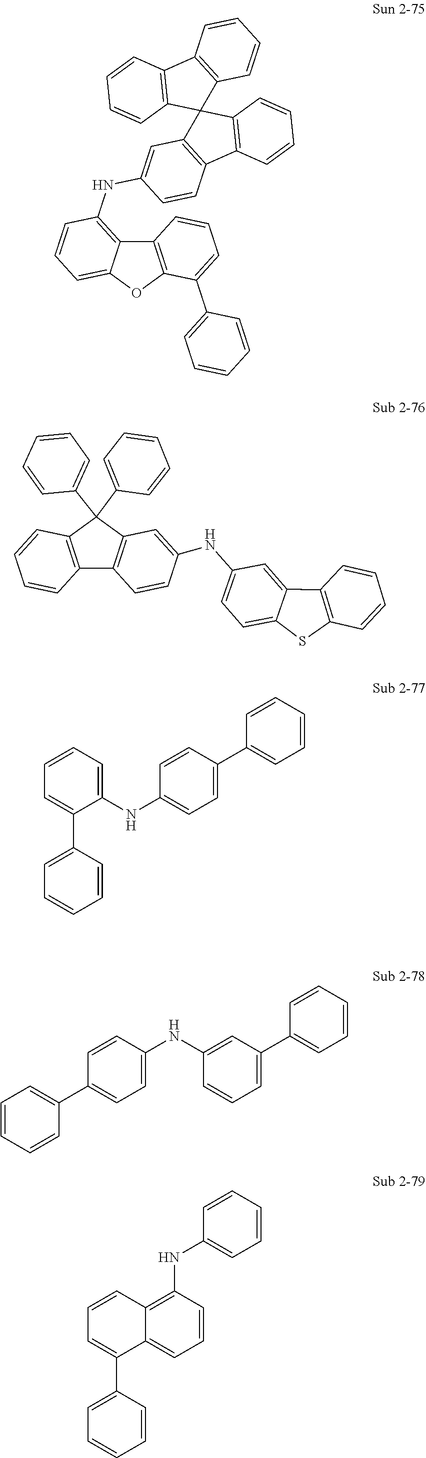 [SMILES: c1ccc(-c2cccc3c2oc2cccc(Nc4ccc5c(c4)C4(c6ccccc6-c6ccccc64)c4ccccc4-5)c23)cc1 ; c1ccc(C2(c3ccccc3)c3ccccc3-c3ccc(Nc4ccc5sc6ccccc6c5c4)cc32)cc1 ; c1ccc(-c2ccc(Nc3ccccc3-c3ccccc3)cc2)cc1 ; c1ccc(-c2ccc(Nc3cccc(-c4ccccc4)c3)cc2)cc1 ; c1ccc(Nc2cccc3c(-c4ccccc4)cccc23)cc1]

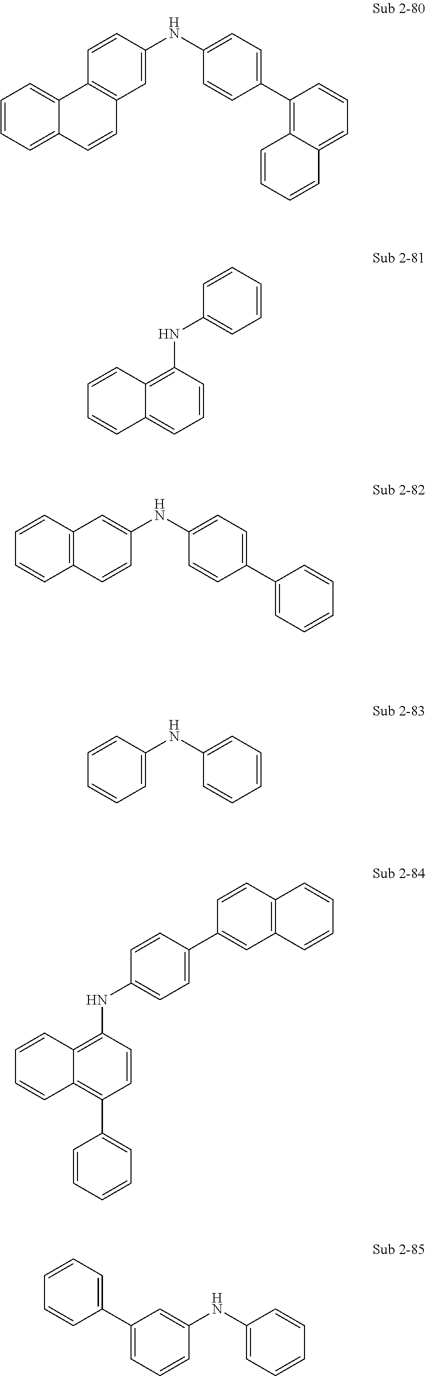 [SMILES: c1ccc2c(-c3ccc(Nc4ccc5c(ccc6ccccc65)c4)cc3)cccc2c1 ; c1ccc(Nc2cccc3ccccc23)cc1 ; c1ccc(-c2ccc(Nc3ccc4ccccc4c3)cc2)cc1 ; c1ccc(Nc2ccccc2)cc1 ; c1ccc(-c2ccc(Nc3ccc(-c4ccc5ccccc5c4)cc3)c3ccccc23)cc1 ; c1ccc(Nc2cccc(-c3ccccc3)c2)cc1]

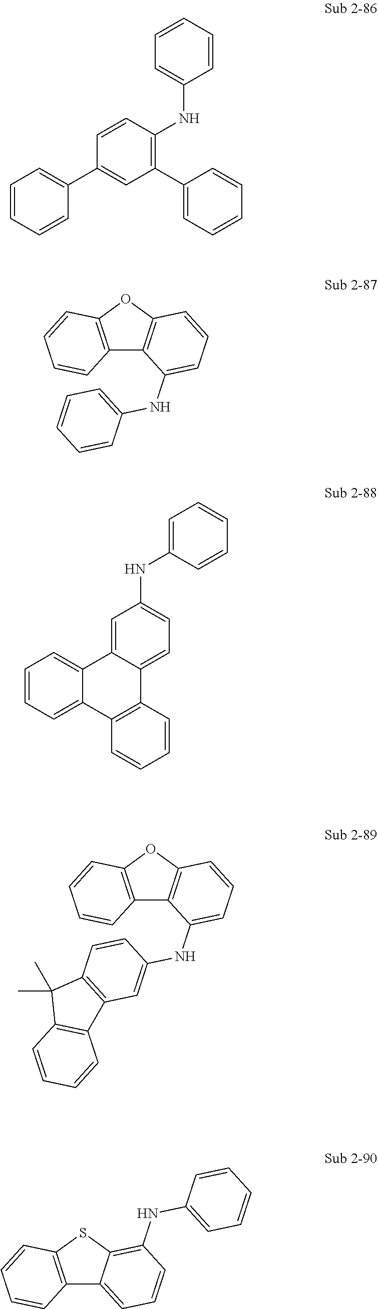 [SMILES: c1ccc(Nc2ccc(-c3ccccc3)cc2-c2ccccc2)cc1 ; c1ccc(Nc2cccc3oc4ccccc4c23)cc1 ; c1ccc(Nc2ccc3c4ccccc4c4ccccc4c3c2)cc1 ; CC1(C)c2ccccc2-c2cc(Nc3cccc4oc5ccccc5c34)ccc21 ; c1ccc(Nc2cccc3c2sc2ccccc23)cc1]

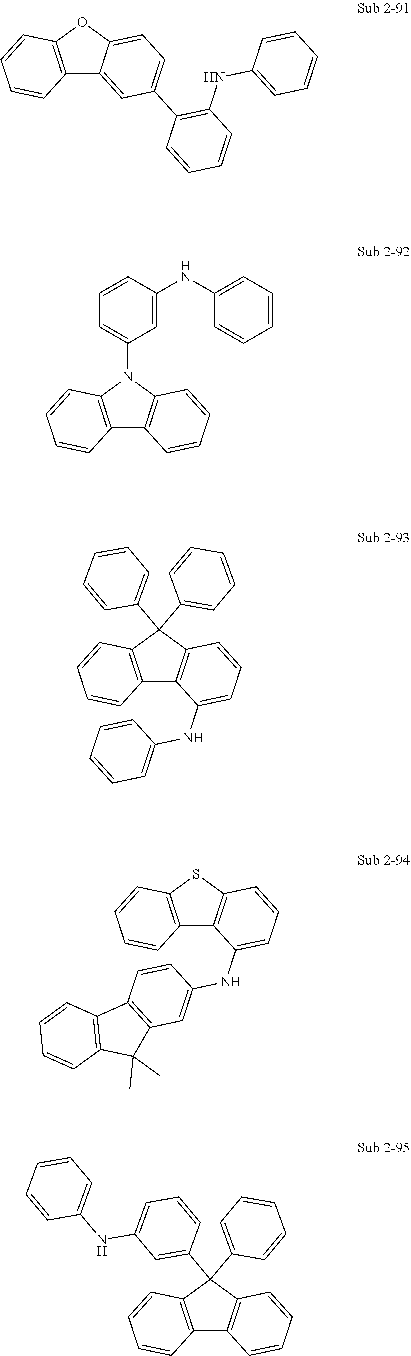 [SMILES: c1ccc(Nc2ccccc2-c2ccc3oc4ccccc4c3c2)cc1 ; c1ccc(Nc2cccc(-n3c4ccccc4c4ccccc43)c2)cc1 ; c1ccc(Nc2cccc3c2-c2ccccc2C3(c2ccccc2)c2ccccc2)cc1 ; CC1(C)c2ccccc2-c2ccc(Nc3cccc4sc5ccccc5c34)cc21 ; c1ccc(Nc2cccc(C3(c4ccccc4)c4ccccc4-c4ccccc43)c2)cc1]

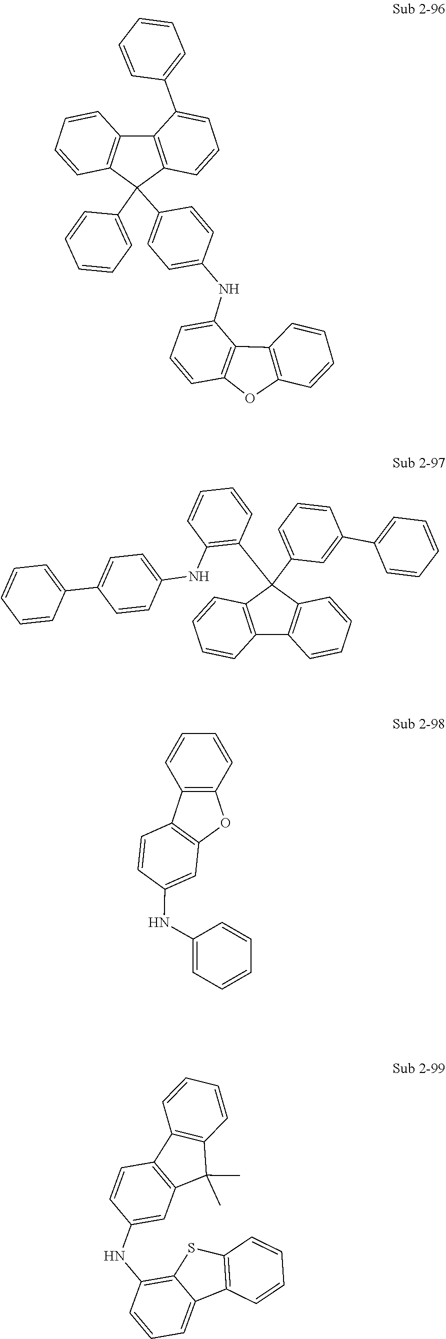 [SMILES: c1ccc(-c2cccc3c2-c2ccccc2C3(c2ccccc2)c2ccc(Nc3cccc4oc5ccccc5c34)cc2)cc1 ; c1ccc(-c2ccc(Nc3ccccc3C3(c4cccc(-c5ccccc5)c4)c4ccccc4-c4ccccc43)cc2)cc1 ; c1ccc(Nc2ccc3c(c2)oc2ccccc23)cc1 ; CC1(C)c2ccccc2-c2ccc(Nc3cccc4c3sc3ccccc34)cc21]

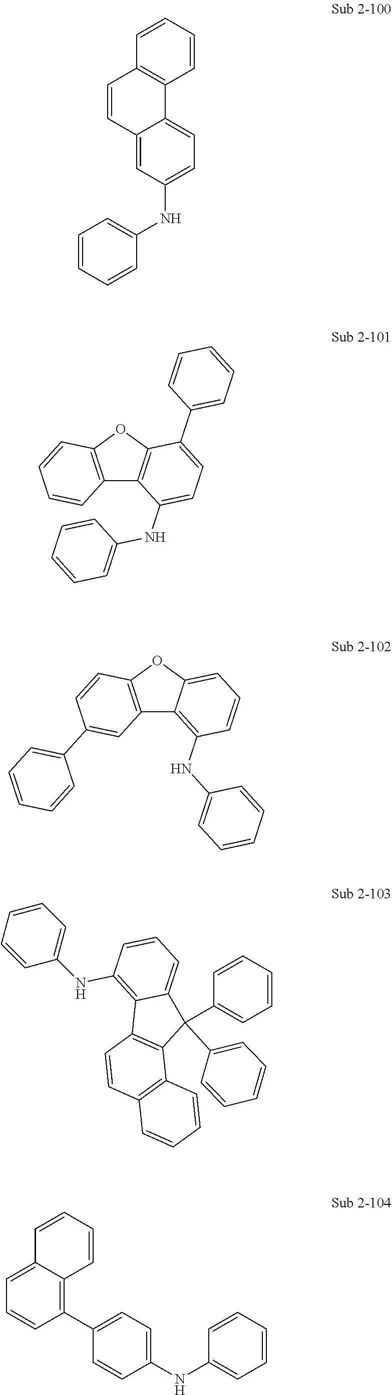 [SMILES: c1ccc(Nc2ccc3c(ccc4ccccc43)c2)cc1 ; c1ccc(Nc2ccc(-c3ccccc3)c3oc4ccccc4c23)cc1 ; c1ccc(Nc2cccc3oc4ccc(-c5ccccc5)cc4c23)cc1 ; c1ccc(Nc2cccc3c2-c2ccc4ccccc4c2C3(c2ccccc2)c2ccccc2)cc1 ; c1ccc(Nc2ccc(-c3cccc4ccccc34)cc2)cc1]

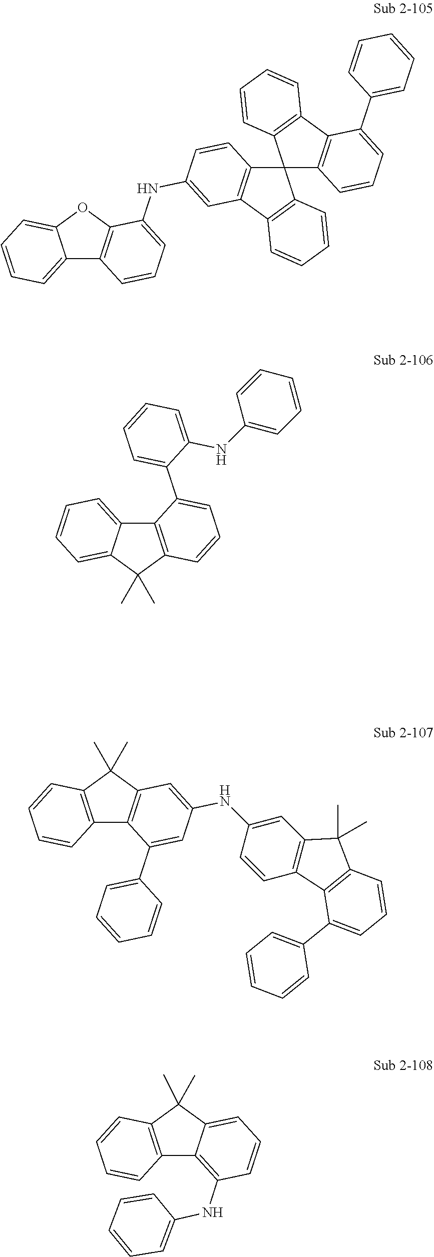 [SMILES: c1ccc(-c2cccc3c2-c2ccccc2C32c3ccccc3-c3cc(Nc4cccc5c4oc4ccccc45)ccc32)cc1 ; CC1(C)c2ccccc2-c2c(-c3ccccc3Nc3ccccc3)cccc21 ; CC1(C)c2cc(Nc3cc(-c4ccccc4)c4c(c3)C(C)(C)c3ccccc3-4)ccc2-c2c(-c3ccccc3)cccc21 ; CC1(C)c2ccccc2-c2c(Nc3ccccc3)cccc21]

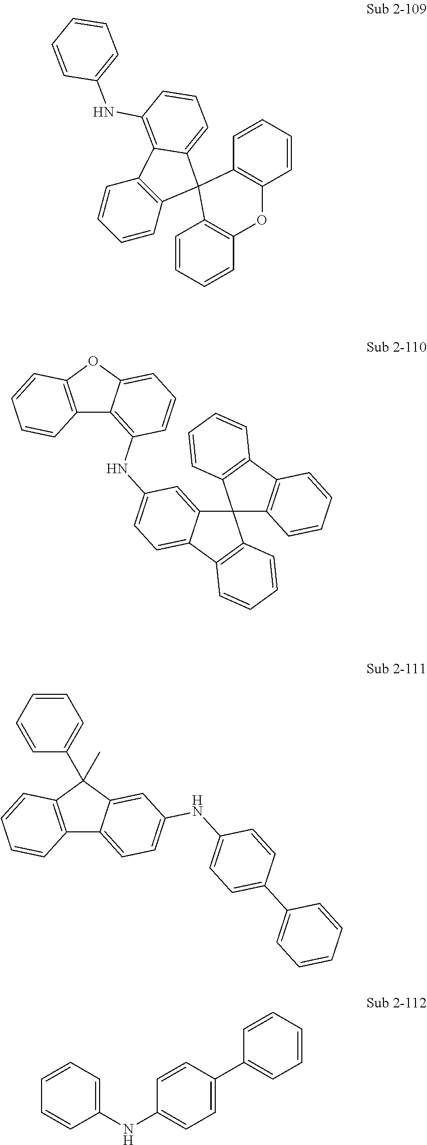 [SMILES: c1ccc(Nc2cccc3c2-c2ccccc2C32c3ccccc3Oc3ccccc32)cc1 ; c1ccc2c(c1)-c1ccccc1C21c2ccccc2-c2ccc(Nc3cccc4oc5ccccc5c34)cc21 ; CC1(c2ccccc2)c2ccccc2-c2ccc(Nc3ccc(-c4ccccc4)cc3)cc21 ; c1ccc(Nc2ccc(-c3ccccc3)cc2)cc1]

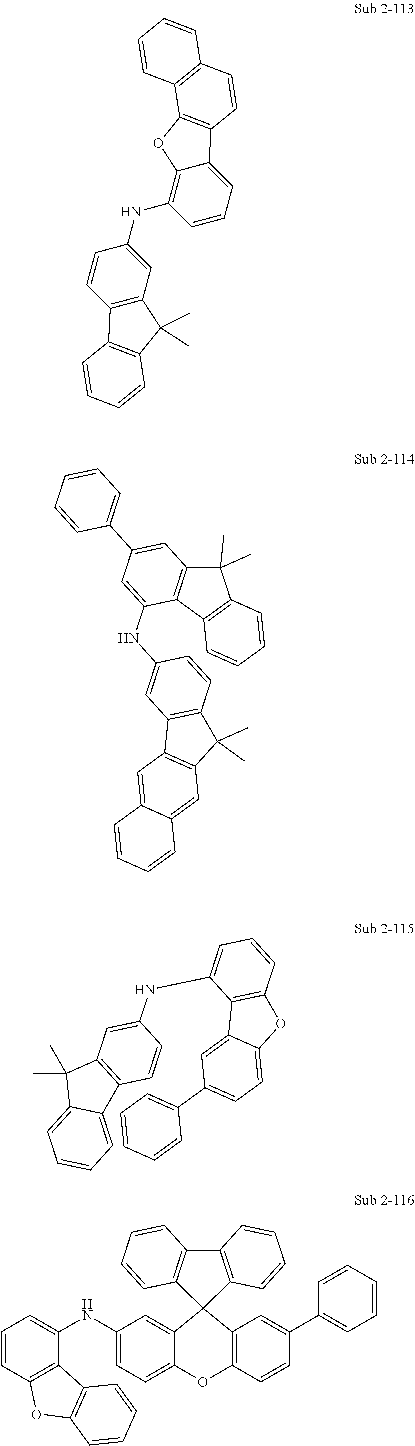 [SMILES: CC1(C)c2ccccc2-c2ccc(Nc3cccc4c3oc3c5ccccc5ccc43)cc21 ; CC1(C)c2ccc(Nc3cc(-c4ccccc4)cc4c3-c3ccccc3C4(C)C)cc2-c2cc3ccccc3cc21 ; CC1(C)c2ccccc2-c2ccc(Nc3cccc4oc5ccc(-c6ccccc6)cc5c34)cc21 ; c1ccc(-c2ccc3c(c2)C2(c4cc(Nc5cccc6oc7ccccc7c56)ccc4O3)c3ccccc3-c3ccccc32)cc1]

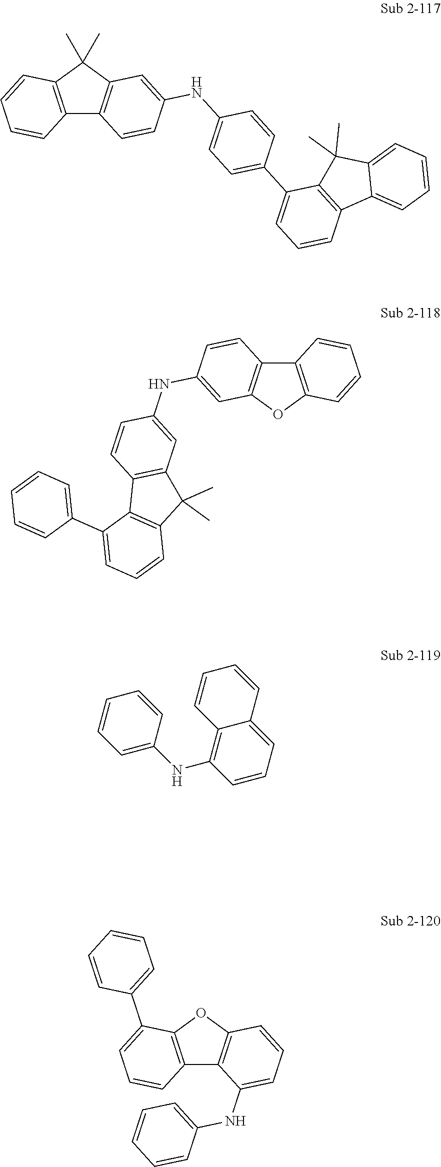 [SMILES: CC1(C)c2ccccc2-c2ccc(Nc3ccc(-c4cccc5c4C(C)(C)c4ccccc4-5)cc3)cc21 ; CC1(C)c2cc(Nc3ccc4c(c3)oc3ccccc34)ccc2-c2c(-c3ccccc3)cccc21 ; c1ccc(Nc2cccc3ccccc23)cc1 ; c1ccc(Nc2cccc3oc4c(-c5ccccc5)cccc4c23)cc1]

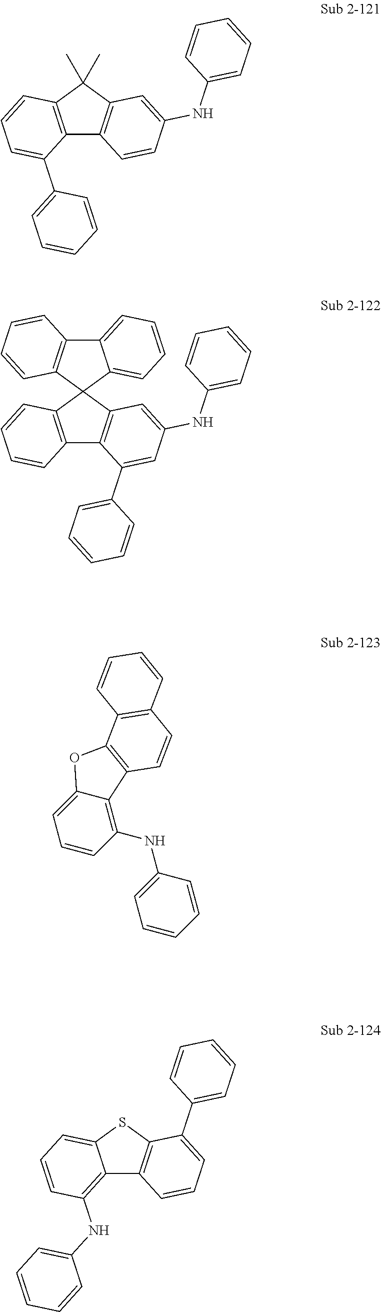 [SMILES: CC1(C)c2cc(Nc3ccccc3)ccc2-c2c(-c3ccccc3)cccc21 ; c1ccc(Nc2cc(-c3ccccc3)c3c(c2)C2(c4ccccc4-c4ccccc42)c2ccccc2-3)cc1 ; c1ccc(Nc2cccc3oc4c5ccccc5ccc4c23)cc1 ; c1ccc(Nc2cccc3sc4c(-c5ccccc5)cccc4c23)cc1]

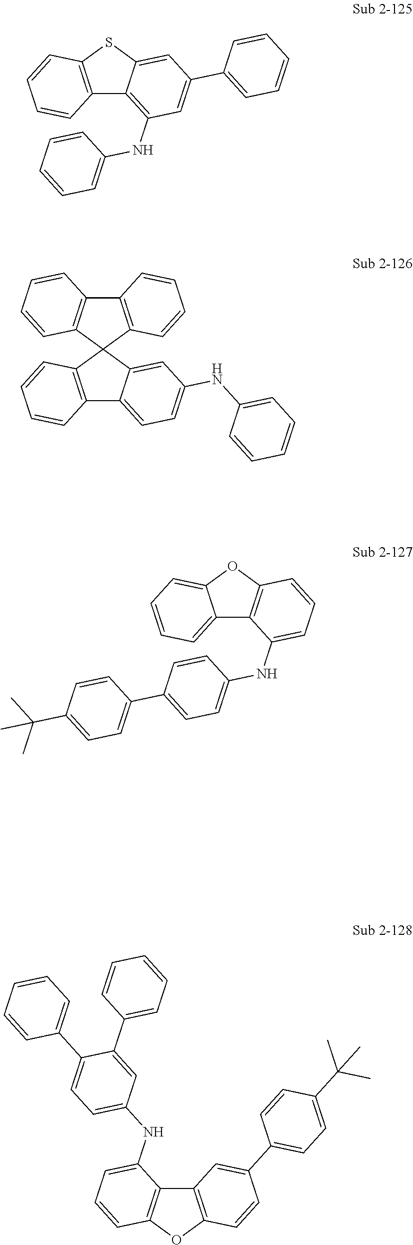 [SMILES: c1ccc(Nc2cc(-c3ccccc3)cc3sc4ccccc4c23)cc1 ; c1ccc(Nc2ccc3c(c2)C2(c4ccccc4-c4ccccc42)c2ccccc2-3)cc1 ; CC(C)(C)c1ccc(-c2ccc(Nc3cccc4oc5ccccc5c34)cc2)cc1 ; CC(C)(C)c1ccc(-c2ccc3oc4cccc(Nc5ccc(-c6ccccc6)c(-c6ccccc6)c5)c4c3c2)cc1]

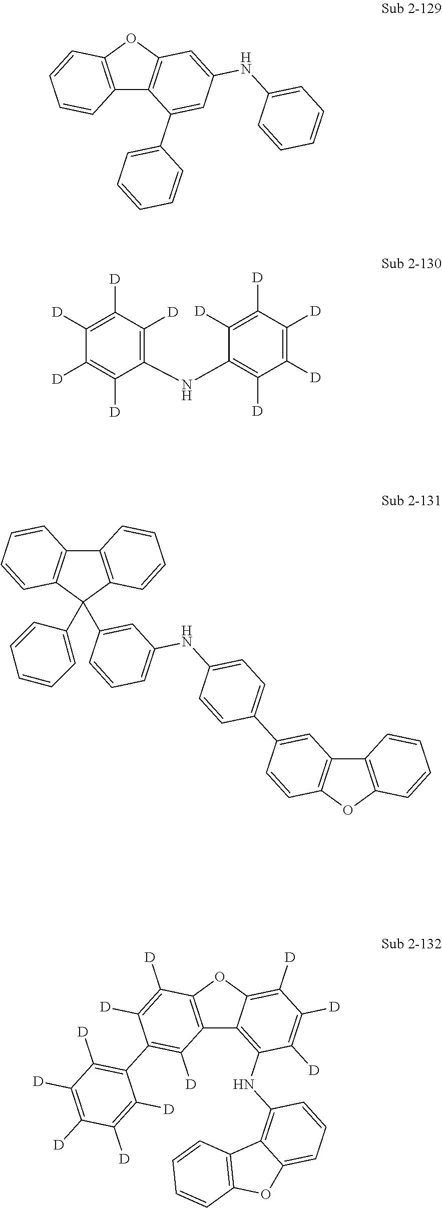 [SMILES: c1ccc(Nc2cc(-c3ccccc3)c3c(c2)oc2ccccc23)cc1 ; [2H]c1c([2H])c([2H])c(Nc2c([2H])c([2H])c([2H])c([2H])c2[2H])c([2H])c1[2H] ; c1ccc(C2(c3cccc(Nc4ccc(-c5ccc6oc7ccccc7c6c5)cc4)c3)c3ccccc3-c3ccccc32)cc1 ; [2H]c1c([2H])c([2H])c(-c2c([2H])c([2H])c3oc4c([2H])c([2H])c([2H])c(Nc5cccc6oc7ccccc7c56)c4c3c2[2H])c([2H])c1[2H]]

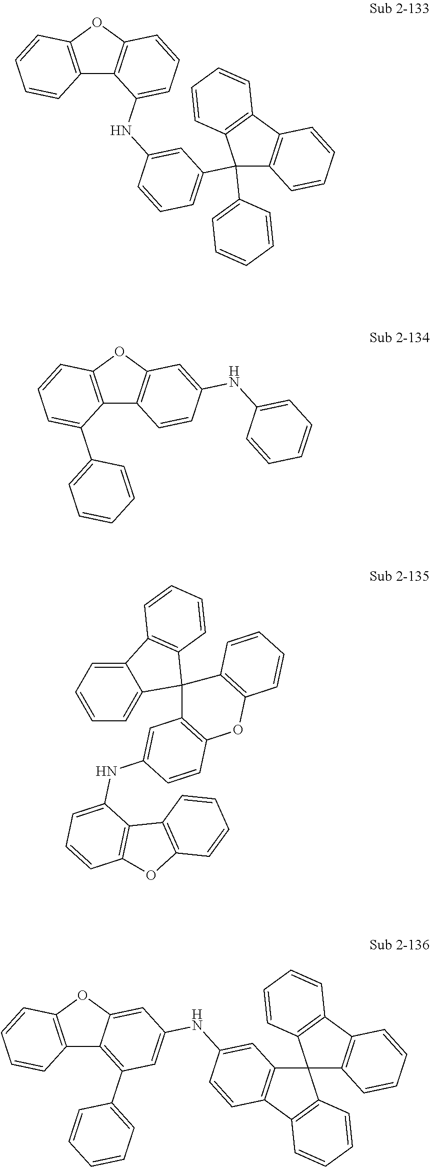 [SMILES: c1ccc(C2(c3cccc(Nc4cccc5oc6ccccc6c45)c3)c3ccccc3-c3ccccc32)cc1 ; c1ccc(Nc2ccc3c(c2)oc2cccc(-c4ccccc4)c23)cc1 ; c1ccc2c(c1)Oc1ccc(Nc3cccc4oc5ccccc5c34)cc1C21c2ccccc2-c2ccccc21 ; c1ccc(-c2cc(Nc3ccc4c(c3)C3(c5ccccc5-c5ccccc53)c3ccccc3-4)cc3oc4ccccc4c23)cc1]

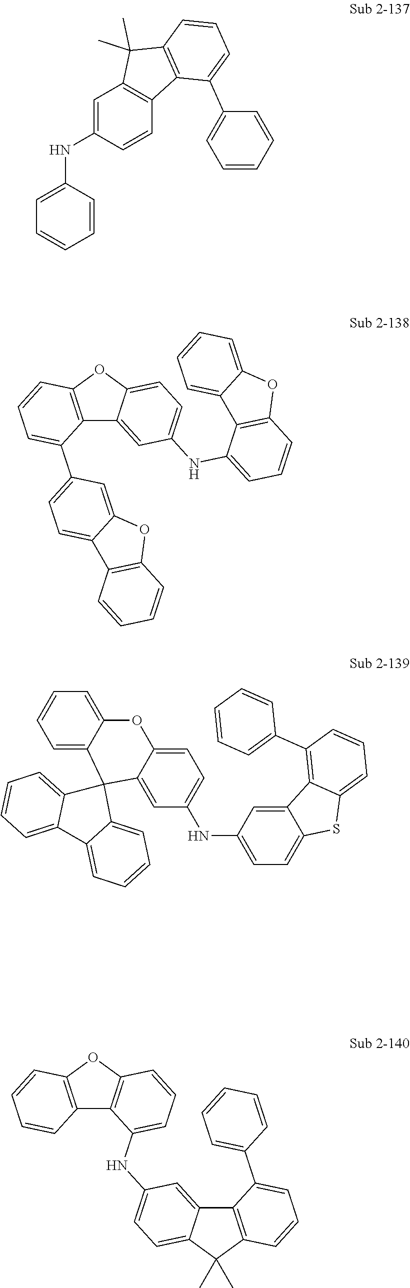 [SMILES: CC1(C)c2cc(Nc3ccccc3)ccc2-c2c(-c3ccccc3)cccc21 ; c1ccc2c(c1)oc1cc(-c3cccc4oc5ccc(Nc6cccc7oc8ccccc8c67)cc5c34)ccc12 ; c1ccc(-c2cccc3sc4ccc(Nc5ccc6c(c5)C5(c7ccccc7O6)c6ccccc6-c6ccccc65)cc4c23)cc1 ; CC1(C)c2ccc(Nc3cccc4oc5ccccc5c34)cc2-c2c(-c3ccccc3)cccc21]

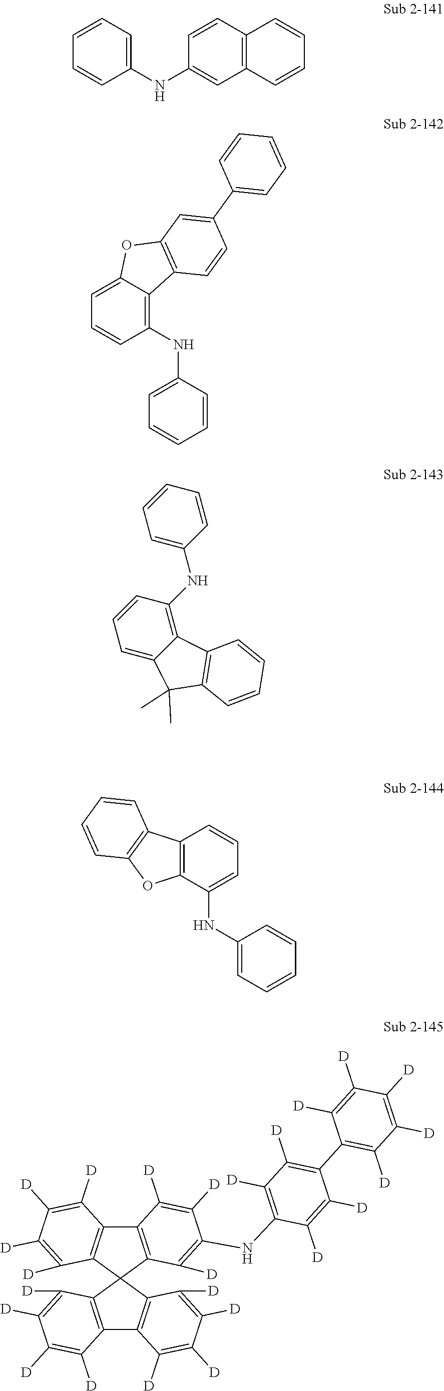

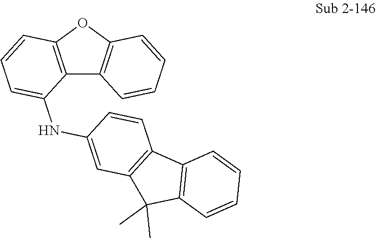 [SMILES: CC1(C)c2ccccc2-c2ccc(Nc3cccc4oc5ccccc5c34)cc21]

TABLE 2

| compound | FD-MS | compound | FD-MS |
|---|---|---|---|
| Sub 2-1 | m/z = 321.15(C₂₄H₁₉N = 321.42) | Sub 2-2 | m/z = 345.15(C₂₆H₁₉N = 345.44) |
| Sub 2-3 | m/z = 497.21(C₃₈H₂₇N = 497.64) | Sub 2-4 | m/z = 495.2(C₃₈H₂₅N = 495.62) |
| Sub 2-5 | m/z = 471.2(C₃₆H₂₅N = 471.6) | Sub 2-6 | m/z = 339.26(C₂₄HD₁₈N = 339.53) |
| Sub 2-7 | m/z = 419.32(C₃₀HD₂₂N = 419.66) | Sub 2-8 | m/z = 321.15(C₂₄H₁₉N = 321.42) |
| Sub 2-9 | m/z = 371.17(C₂₈H₂₁N = 371.48) | Sub 2-10 | m/z = 385.15(C₂₈H₁₉NO = 385.47) |
| Sub 2-11 | m/z = 349.11(C₂₄H₁₅NO₂ = 349.39) | Sub 2-12 | m/z = 335.13(C₂₄H₁₇NO = 335.41) |
| Sub 2-13 | m/z = 507.11(C₃₄H₂₁NS₂ = 507.67) | Sub 2-14 | m/z = 391.14(C₂₇H₂₁NS = 391.53) |
| Sub 2-15 | m/z = 361.18(C₂₇H₂₃N = 361.49) | Sub 2-16 | m/z = 401.21(C₃₀H₂₇N = 401.55) |
| Sub 2-17 | m/z = 525.25(C₄₀H₃₁N = 525.69) | Sub 2-18 | m/z = 485.21(C₃₇H₂₇N = 485.63) |
| Sub 2-19 | m/z = 599.26(C₄₆H₃₃N = 599.78) | Sub 2-20 | m/z = 401.21(C₃₀H₂₇N = 401.55) |
| Sub 2-21 | m/z = 415.23(C₃₁H₂₉N = 415.58) | Sub 2-22 | m/z = 451.19(C₃₃H₂₅NO = 451.57) |
| Sub 2-23 | m/z = 411.16(C₃₀H₂₁NO = 411.5) | Sub 2-24 | m/z = 361.18(C₂₇H₂₃N = 361.49) |
| Sub 2-25 | m/z = 527.26(C₄₀H₃₃N = 527.71) | Sub 2-26 | m/z = 391.14(C₂₇H₂₁NS = 391.53) |
| Sub 2-27 | m/z = 467.17(C₃₃H₂₅NS = 467.63) | Sub 2-28 | m/z = 391.19(C₂₈H₂₅NO = 391.51) |
| Sub 2-29 | m/z = 451.19(C₃₃H₂₅NO = 451.57) | Sub 2-30 | m/z = 553.28(C₄₂H₃₅N = 553.75) |
| Sub 2-31 | m/z = 285.15(C₂₁H₁₉N = 285.39) | Sub 2-32 | m/z = 334.15(C₂₄H₁₈N₂ = 334.42) |
| Sub 2-33 | m/z = 485.21(C₃₇H₂₇N = 485.63) | Sub 2-34 | m/z = 497.18(C₃₇H₂₃NO = 497.6) |
| Sub 2-35 | m/z = 533.21(C₄₁H₂₇N = 533.67) | Sub 2-36 | m/z = 411.16(C₃₀H₂₁NO = 411.5) |
| Sub 2-37 | m/z = 591.2(C₄₃H₂₉NS = 591.77) | Sub 2-38 | m/z = 450.21(C₃₃H₂₆N₂ = 450.59) |
| Sub 2-39 | m/z = 485.21(C₃₇H₂₇N = 485.63) | Sub 2-40 | m/z = 485.21(C₃₇H₂₇N = 485.63) |
| Sub 2-41 | m/z = 533.21(C₄₁H₂₇N = 533.67) | Sub 2-42 | m/z = 385.28(C₂₈H₃₅N = 385.59) |
| Sub 2-43 | m/z = 397.28(C₂₉H₃₅N = 397.61) | Sub 2-44 | m/z = 437.31(C₃₂H₃₉N = 437.67) |
| Sub 2-45 | m/z = 333.25(C₂₄H₃₁N = 333.52) | Sub 2-46 | m/z = 339.2(C₂₅H₂₅N = 339.48) |
| Sub 2-47 | m/z = 377.21(C₂₈H₂₇N = 377.53) | Sub 2-48 | m/z = 393.25(C₂₉H₃₁N = 393.57) |
| Sub 2-49 | m/z = 493.28(C₃₇H₃₅N = 493.69) | Sub 2-50 | m/z = 501.25(C₃₈H₃₁N = 501.67) |
| Sub 2-51 | m/z = 459.29(C₃₄H₃₇N = 459.68) | Sub 2-52 | m/z = 501.17(C₃₆H₂₃NO₂ = 501.58) |
| Sub 2-53 | m/z = 483.2(C₃₇H₂₅N = 483.61) | Sub 2-54 | m/z = 377.28(C₂₇H₇D₁₆N = 377.59) |
| Sub 2-55 | m/z = 437.21(C₃₃H₂₇N = 437.59) | Sub 2-56 | m/z = 401.21(C₃₀H₂₇N = 401.55) |
| Sub 2-57 | m/z = 345.15(C₂₆H₁₉N = 345.44) | Sub 2-58 | m/z = 525.25(C₄₀H₃₁N = 525.69) |
| Sub 2-59 | m/z = 477.25(C₃₆H₃₁N = 477.65) | Sub 2-60 | m/z = 451.19(C₃₃H₂₅NO = 451.57) |
| Sub 2-61 | m/z = 285.15(C₂₁H₁₉N = 285.39) | Sub 2-62 | m/z = 375.16(C₂₇H₂₁NO = 375.47) |
| Sub 2-63 | m/z = 451.19(C₃₃H₂₅NO = 451.57) | Sub 2-64 | m/z = 451.19(C₃₃H₂₅NO = 451.57) |
| Sub 2-65 | m/z = 451.19(C₃₃H₂₅NO = 451.57) | Sub 2-66 | m/z = 477.25(C₃₆H₃₁N = 477.65) |
| Sub 2-67 | m/z = 379.23(C₂₈H₂₉N = 379.55) | Sub 2-68 | m/z = 462.26(C₃₃H₁₄D₁₁NO = 462.64) |
| Sub 2-69 | m/z = 457.23(C₃₃H₁₉D₆NO = 457.61) | Sub 2-70 | m/z = 349.11(C₂₄H₁₅NO₂ = 349.39) |
| Sub 2-71 | m/z = 485.21(C₃₇H₂₇N = 485.63) | Sub 2-72 | m/z = 401.21(C₃₀H₂₇N = 401.55) |
| Sub 2-73 | m/z = 409.18(C₃₁H₂₃N = 409.53) | Sub 2-74 | m/z = 499.19(C₃₇H₂₅NO = 499.61) |
| Sub 2-75 | m/z = 573.21(C₄₃H₂₇NO = 573.69) | Sub 2-76 | m/z = 515.17(C₃₇H₂₅NS = 515.67) |
| Sub 2-77 | m/z = 321.15(C₂₄H₁₉N = 321.42) | Sub 2-78 | m/z = 321.15(C₂₄H₁₉N = 321.42) |
| Sub 2-79 | m/z = 295.14(C₂₂H₁₇N = 295.38) | Sub 2-80 | m/z = 395.17(C₃₀H₂₁N = 395.5) |
| Sub 2-81 | m/z = 219.1(C₁₆H₁₃N = 219.29) | Sub 2-82 | m/z = 295.14(C₂₂H₁₇N = 295.38) |
| Sub 2-83 | m/z = 169.09(C₁₂H₁₁N = 169.23) | Sub 2-84 | m/z = 421.18(C₃₂H₂₃N = 421.54) |
| Sub 2-85 | m/z = 245.12(C₁₈H₁₅N = 245.32) | Sub 2-86 | m/z = 321.15(C₂₄H₁₉N = 321.42) |
| Sub 2-87 | m/z = 259.1(C₁₈H₁₃NO = 259.31) | Sub 2-88 | m/z = 319.14(C₂₄H₁₇N = 319.41) |
| Sub 2-89 | m/z = 375.16(C₂₇H₂₁NO = 375.47) | Sub 2-90 | m/z = 275.08(C₁₈H₁₃NS = 275.37) |
| Sub 2-91 | m/z = 335.13(C₂₄H₁₇NO = 335.41) | Sub 2-92 | m/z = 334.15(C₂₄H₁₈N₂ = 334.42) |
| Sub 2-93 | m/z = 409.18(C₃₁H₂₃N = 409.53) | Sub 2-94 | m/z = 391.14(C₂₇H₂₁NS = 391.53) |
| Sub 2-95 | m/z = 409.18(C₃₁H₂₃N = 409.53) | Sub 2-96 | m/z = 575.22(C₄₃H₂₉NO = 575.71) |
| Sub 2-97 | m/z = 561.25(C₄₃H₃₁N = 561.73) | Sub 2-98 | m/z = 259.1(C₁₈H₁₃NO = 259.31) |
| Sub 2-99 | m/z = 391.14(C₂₇H₂₁NS = 391.53) | Sub 2-100 | m/z = 269.12(C₂₀H₁₅N = 269.35) |
| Sub 2-101 | m/z = 335.13(C₂₄H₁₇NO = 335.41) | Sub 2-102 | m/z = 335.13(C₂₄H₁₇NO = 335.41) |
| Sub 2-103 | m/z = 459.2(C₃₅H₂₅N = 459.59) | Sub 2-104 | m/z = 295.14(C₂₂H₁₇N = 295.38) |
| Sub 2-105 | m/z = 573.21(C₄₃H₂₇NO = 573.69) | Sub 2-106 | m/z = 361.18(C₂₇H₂₃N = 361.49) |
| Sub 2-107 | m/z = 553.28(C₄₂H₃₅N = 553.75) | Sub 2-108 | m/z = 285.15(C₂₁H₁₉N = 285.39) |
| Sub 2-109 | m/z = 423.16(C₃₁H₂₁NO = 423.51) | Sub 2-110 | m/z = 497.18(C₃₇H₂₃NO = 497.6) |
| Sub 2-111 | m/z = 423.2(C₃₂H₂₅N = 423.56) | Sub 2-112 | m/z = 245.12(C₁₈H₁₅N = 245.32) |
| Sub 2-113 | m/z = 425.18(C₃₁H₂₃NO = 425.53) | Sub 2-114 | m/z = 527.26(C₄₀H₃₃N = 527.71) |
| Sub 2-115 | m/z = 451.19(C₃₃H₂₅NO = 451.57) | Sub 2-116 | m/z = 589.2(C₄₃H₂₇NO₂ = 589.69) |
| Sub 2-117 | m/z = 477.25(C₃₆H₃₁N = 477.65) | Sub 2-118 | m/z = 451.19(C₃₃H₂₅NO = 451.57) |
| Sub 2-119 | m/z = 219.1(C₁₆H₁₃N = 219.29) | Sub 2-120 | m/z = 335.13(C₂₄H₁₇NO = 335.41) |
| Sub 2-121 | m/z = 361.18(C₂₇H₂₃N = 361.49) | Sub 2-122 | m/z = 483.2(C₃₇H₂₅N = 483.61) |
| Sub 2-123 | m/z = 309.12(C₂₂H₁₅NO = 309.37) | Sub 2-124 | m/z = 351.11(C₂₄H₁₇NS = 351.47) |
| Sub 2-125 | m/z = 351.11(C₂₄H₁₇NS = 351.47) | Sub 2-126 | m/z = 407.17(C₃₁H₂₁N = 407.52) |
| Sub 2-127 | m/z = 391.19(C₂₈H₂₅NO = 391.51) | Sub 2-128 | m/z = 543.26(C₄₀H₃₃NO = 543.71) |
| Sub 2-129 | m/z = 335.13(C₂₄H₁₇NO = 335.41) | Sub 2-130 | m/z = 179.15(C₁₂HD₁₀N = 179.29) |
| Sub 2-131 | m/z = 575.22(C₄₃H₂₉NO = 575.71) | Sub 2-132 | m/z = 436.21(C₃₀H₈D₁₁NO₂ = 436.55) |
| Sub 2-133 | m/z = 499.19(C₃₇H₂₅NO = 499.61) | Sub 2-134 | m/z = 335.13(C₂₄H₁₇NO = 335.41) |
| Sub 2-135 | m/z = 513.17(C₃₇H₂₃NO₂ = 513.6) | Sub 2-136 | m/z = 573.21(C₄₃H₂₇NO = 573.69) |
| Sub 2-137 | m/z = 361.18(C₂₇H₂₃N = 361.49) | Sub 2-138 | m/z = 515.15(C₃₆H₂₁NO₃ = 515.57) |
| Sub 2-139 | m/z = 605.18(C₄₃H₂₇NOS = 605.75) | Sub 2-140 | m/z = 451.19(C₃₃H₂₅NO = 451.57) |
| Sub 2-141 | m/z = 219.1(C₁₆H₁₃N = 219.29) | Sub 2-142 | m/z = 335.13(C₂₄H₁₇NO = 335.41) |
| Sub 2-143 | m/z = 285.15(C₂₁H₁₉N = 285.39) | Sub 2-144 | m/z = 259.1(C₁₈H₁₃NO = 259.31) |
| Sub 2-145 | m/z = 507.35(C₃₇HD₂₄N = 507.76) | Sub 2-146 | m/z = 375.16(C₂₇H₂₁NO = 375.47) |

### III. Synthesis of Final Product 1

### 1. Synthesis Example of P1-6

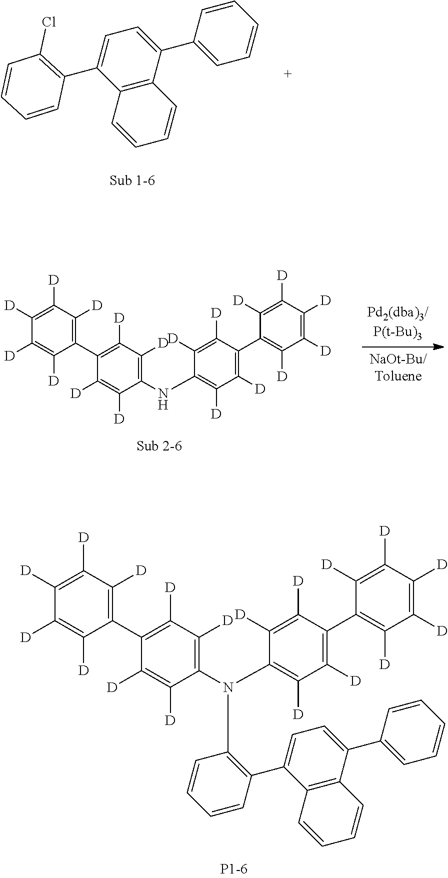 [SMILES: Clc1ccccc1-c1ccc(-c2ccccc2)c2ccccc12 ; [2H]c1c([2H])c([2H])c(-c2c([2H])c([2H])c(Nc3c([2H])c([2H])c(-c4c([2H])c([2H])c([2H])c([2H])c4[2H])c([2H])c3[2H])c([2H])c2[2H])c([2H])c1[2H] ; [2H]c1c([2H])c([2H])c(-c2c([2H])c([2H])c(N(c3ccccc3-c3ccc(-c4ccccc4)c4ccccc34)c3c([2H])c([2H])c(-c4c([2H])c([2H])c([2H])c([2H])c4[2H])c([2H])c3[2H])c([2H])c2[2H])c([2H])c1[2H]]

Sub 1-6 (20 g, 63.5 mmol), Toluene (150 mL), Sub 2-6 (21.6 g, 63.5 mmol), Pd₂(dba)₃ (1.7 g, 1.9 mmol), P(t-Bu)₃ (12.2 g, 3.8 mmol), NaOt-Bu (12.2 g, 127.1 mmol) were added and stirred at 100° C. When the reaction was completed, the organic layer was extracted with Toluene and water, dried over MgSO₄, concentrated, and the resulting compound was recrystallized using a silica gel column to obtain the product (30.2 g, 77%).

### 2. Synthesis Example of P1-11

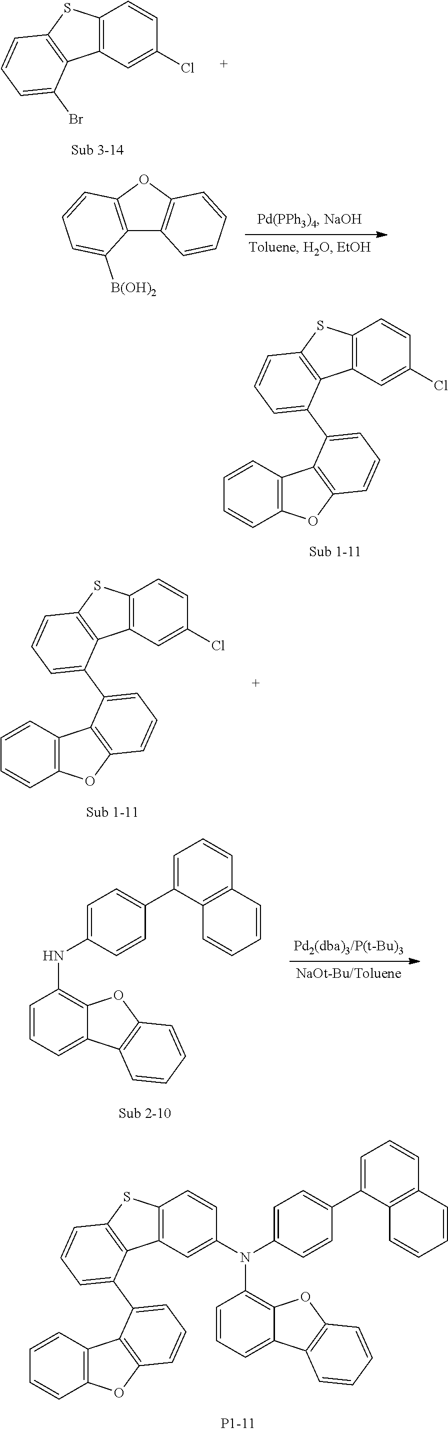 [SMILES: Clc1ccc2sc3cccc(Br)c3c2c1 ; OB(O)c1cccc2oc3ccccc3c12 ; Clc1ccc2sc3cccc(-c4cccc5oc6ccccc6c45)c3c2c1 ; Clc1ccc2sc3cccc(-c4cccc5oc6ccccc6c45)c3c2c1 ; c1ccc2c(-c3ccc(Nc4cccc5c4oc4ccccc45)cc3)cccc2c1 ; c1ccc2c(-c3ccc(N(c4ccc5sc6cccc(-c7cccc8oc9ccccc9c78)c6c5c4)c4cccc5c4oc4ccccc45)cc3)cccc2c1]

### (1) Synthesis of Sub 1-11

Sub 3-14 (30 g, 100.8 mmol), Toluene (270 mL), H₂O (30 mL), Ethanol (30 mL), 1-Dibenzofuranylboronic acid (22.4 g, 105.9 mmol), Pd(PPh₃)₄ (3.5 g, 3.0 mmol), NaOH (8.1 g, 201.6 mmol) were added and stirred at 80° C. When the reaction is complete, the solution is extracted with Toluene and water, the organic layer is dried with MgSO₄, and the solvent is completely removed. The concentrate is dissolved in Toluene, concentrated, and the compound is subjected to silica gel column and recrystallization to obtain the product (27.5 g, 71%).

### (2) Synthesis of P1-11

Sub 1-11 (25 g, 87.8 mmol), Toluene (220 mL), Sub 2-10 (33.8 g, 87.8 mmol), Pd₂(dba)₃ (2.4 g, 2.6 mmol), P(t-Bu)₃ (1.1 g, 5.3 mmol), NaOt-Bu (16.9 g, 175.5 mmol) were added and stirred at 100° C. When the reaction was completed, the organic layer was extracted with Toluene and water, dried over MgSO₄, concentrated, and the resulting compound was recrystallized using a silica gel column to obtain the product (46.4 g, 72%).

### 3. Synthesis Example of P1-15

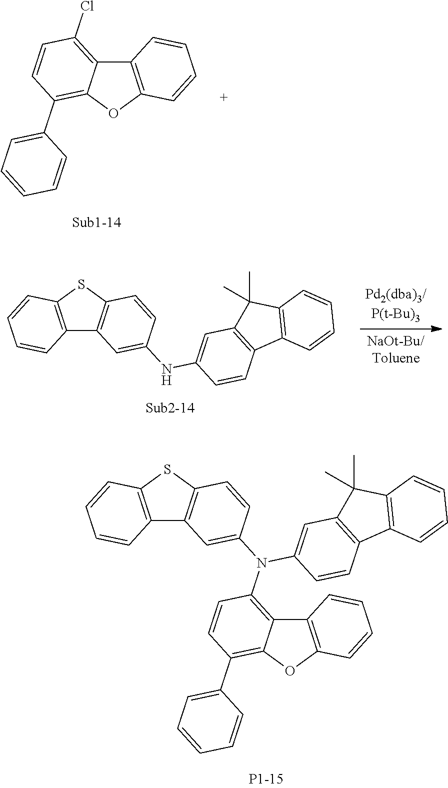 [SMILES: Clc1ccc(-c2ccccc2)c2oc3ccccc3c12 ; CC1(C)c2ccccc2-c2ccc(Nc3ccc4sc5ccccc5c4c3)cc21 ; CC1(C)c2ccccc2-c2ccc(N(c3ccc4sc5ccccc5c4c3)c3ccc(-c4ccccc4)c4oc5ccccc5c34)cc21]

Sub 1-14 (20 g, 71.8 mmol), Toluene (180 mL), Sub 2-14 (28.1 g, 71.8 mmol), Pd₂(dba)₃ (2.0 g, 2.2 mmol), P(t-Bu)₃ (13.8 g, 4.3 mmol), NaOt-Bu (13.8 g, 143.5 mmol) were added and stirred at 100° C. When the reaction was completed, the organic layer was extracted with Toluene and water, dried over MgSO₄, concentrated, and the resulting compound was recrystallized using a silica gel column to obtain the product (36.8 g, 81%).

### 4. Synthesis Example of P1-22

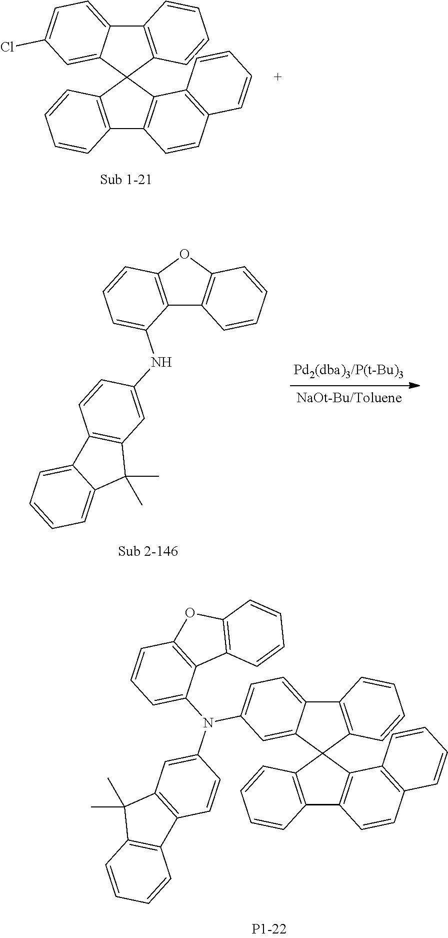

Sub 1-14 (20 g, 71.8 mmol), Toluene (180 mL), Sub 2-14 (28.1 g, 71.8 mmol), Pd₂(dba)₃ (2.0 g, 2.2 mmol), P(t-Bu)₃ (13.8 g, 4.3 mmol), NaOt-Bu (13.8 g, 143.5 mmol) were added and stirred at 100° C. When the reaction was completed, the organic layer was extracted with Toluene and water, dried over MgSO₄, concentrated, and the resulting compound was recrystallized using a silica gel column to obtain the product (27.3 g, 74%).

### 5. Synthesis Example of P1-46

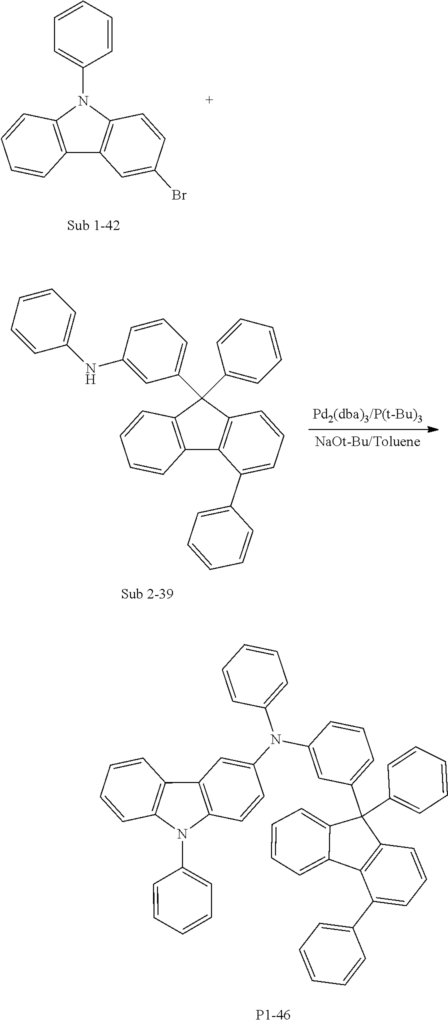 [SMILES: Brc1ccc2c(c1)c1ccccc1n2-c1ccccc1 ; c1ccc(Nc2cccc(C3(c4ccccc4)c4ccccc4-c4c(-c5ccccc5)cccc43)c2)cc1 ; c1ccc(-c2cccc3c2-c2ccccc2C3(c2ccccc2)c2cccc(N(c3ccccc3)c3ccc4c(c3)c3ccccc3n4-c3ccccc3)c2)cc1]

Sub 1-42 (20 g, 62.1 mmol), Toluene (155 mL), Sub 2-39 (30.1 g, 62.1 mmol), Pd₂(dba)₃ (1.7 g, 1.9 mmol), P(t-Bu)₃ (0.8 g, 3.7 mmol), NaOt-Bu (11.9 g, 124.1 mmol) were added and stirred at 100° C. When the reaction was completed, the organic layer was extracted with Toluene and water, dried over MgSO₄, concentrated, and the resulting compound was recrystallized using a silica gel column to obtain the product (30.7 g, 68%).

### 6. Synthesis Example of P1-63

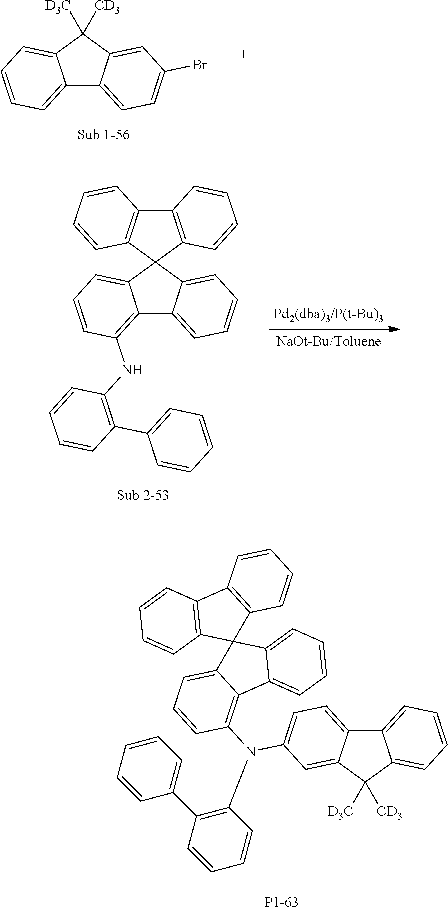 [SMILES: [2H]C([2H])([2H])C1(C([2H])([2H])[2H])c2ccccc2-c2ccc(Br)cc21 ; c1ccc(-c2ccccc2Nc2cccc3c2-c2ccccc2C32c3ccccc3-c3ccccc32)cc1 ; [2H]C([2H])([2H])C1(C([2H])([2H])[2H])c2ccccc2-c2ccc(N(c3ccccc3-c3ccccc3)c3cccc4c3-c3ccccc3C43c4ccccc4-c4ccccc43)cc21]

Sub 1-56 (20 g, 71.6 mmol), Toluene (180 mL), Sub 2-53 (34.6 g, 71.6 mmol), Pd₂(dba)₃ (2.0 g, 2.1 mmol), P(t-Bu)₃ (0.9 g, 4.3 mmol), NaOt-Bu (13.8 g, 143.3 mmol) were added and stirred at 100° C. When the reaction was completed, the organic layer was extracted with Toluene and water, dried over MgSO₄, concentrated, and the resulting compound was recrystallized using a silica gel column to obtain the product (39.1 g, 80%).

### 7. Synthesis Example of P1-64

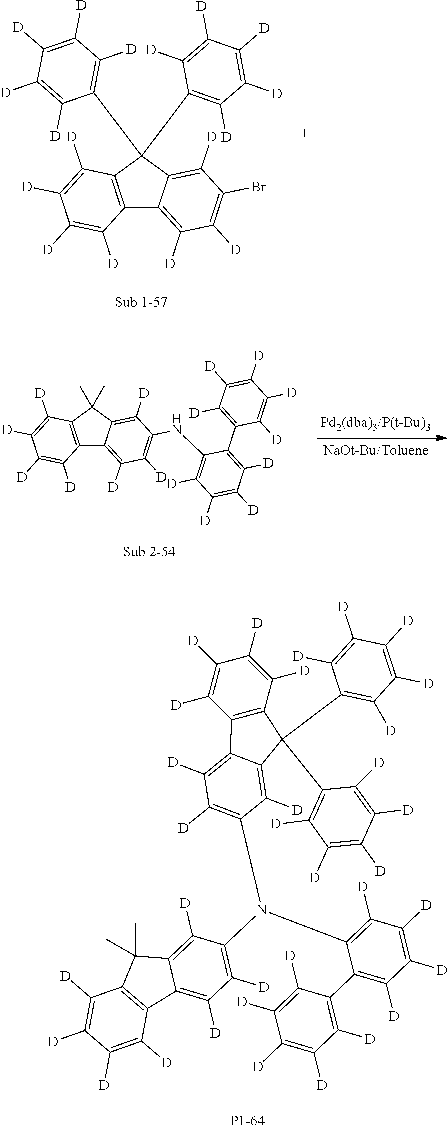

Sub 1-57 (20 g, 48.3 mmol), Toluene (120 mL), Sub 2-54 (18.2 g, 48.3 mmol), Pd₂(dba)₃ (1.3 g, 1.4 mmol), P(t-Bu)₃ (0.6 g, 2.9 mmol), NaOt-Bu (9.3 g, 96.5 mmol) were added and stirred at 100° C. When the reaction was completed, the organic layer was extracted with Toluene and water, dried over MgSO₄, concentrated, and the resulting compound was recrystallized using a silica gel column to obtain the product (27.8 g, 81%).

The FD-MS values of compounds P1-1 to P1-96 of the present invention manufactured according to the above synthetic examples are as shown in Table 3.

TABLE 3

| compound | FD-MS | compound | FD-MS |
|---|---|---|---|
| P1-1 | m/z = 473.21(C₃₆H₂₇N = 473.62) | P1-2 | m/z = 547.23(C₄₂H₂₉N = 547.7) |
| P1-3 | m/z = 775.32(C₆₀H₄₁N = 775.99) | P1-4 | m/z = 849.34(C₆₆H₄₃N = 850.08) |
| P1-5 | m/z = 684.35(C₅₂H₂₄D₁₁N = 684.93) | P1-6 | m/z = 617.37(C₄₆H₁₅D₁₈N = 617.89) |
| P1-7 | m/z = 740.55(C₅₄D₃₉N = 741.15) | P1-8 | m/z = 503.17(C₃₆H₂₅NS = 503.66) |
| P1-9 | m/z = 563.22(C₄₂H₂₉NO = 563.7) | P1-10 | m/z = 705.25(C₅₂H₃₅NS = 705.92) |
| P1-11 | m/z = 733.21(C₅₂H₃₁NO₂S = 733.88) | P1-12 | m/z = 531.13(C₃₆H₂₁NO₂S = 531.63) |
| P1-13 | m/z = 703.25(C₅₂H₃₃NO₂ = 703.84) | P1-14 | m/z = 815.18(C₅₆H₃₃NS₃ = 816.07) |
| P1-15 | m/z = 633.21(C₄₅H₃₁NOS = 633.81) | P1-16 | m/z = 603.26(C₄₅H₃₃NO = 603.76) |
| P1-17 | m/z = 629.31(C₄₈H₃₉N = 629.85) | P1-18 | m/z = 793.37(C₆₁H₄₇N = 794.05) |
| P1-19 | m/z = 753.34(C₅₈H₄₃N = 753.99) | P1-20 | m/z = 857.31(C₆₄H₄₃NS = 858.12) |
| P1-21 | m/z = 715.32(C₅₅H₄₁N = 715.94) | P1-22 | m/z = 739.29(C₅₆H₃₇NO = 739.92) |
| P1-23 | m/z = 791.36(C₆₁H₄₅N = 792.04) | P1-24 | m/z = 807.39(C₆₂H₄₉N = 808.08) |
| P1-25 | m/z = 815.32(C₆₂H₄₁NO = 816.02) | P1-26 | m/z = 853.33(C₆₅H₄₃NO = 854.06) |
| P1-27 | m/z = 705.34(C₅₄H₄₃N = 705.94) | P1-28 | m/z = 953.5(C₇₃H₆₃N = 954.31) |
| P1-29 | m/z = 695.36(C₅₀H₄₉NS = 696.01) | P1-30 | m/z = 721.28(C₅₃H₃₉NS = 721.96) |
| P1-31 | m/z = 721.33(C₅₄H₄₃NO = 721.94) | P1-32 | m/z = 781.3(C₅₈H₃₉NO₂ = 781.95) |
| P1-33 | m/z = 562.24(C₄₂H₃₀N₂ = 562.72) | P1-34 | m/z = 602.27(C₄₅H₃₄N₂ = 602.78) |
| P1-35 | m/z = 768.31(C₅₇H₄₀N₂O = 768.96) | P1-36 | m/z = 870.4(C₆₆H₅₀N₂ = 871.14) |
| P1-37 | m/z = 678.3(C₅₁H₃₈N₂ = 678.88) | P1-38 | m/z = 602.27(C₄₅H₃₄N₂ = 602.78) |
| P1-39 | m/z = 726.3(C₅₅H₃₈N₂ = 726.92) | P1-40 | m/z = 814.3(C₆₁H₃₈N₂O = 814.99) |
| P1-41 | m/z = 900.35(C₆₉H₄₄N₂ = 901.12) | P1-42 | m/z = 638.27(C₄₈H₃₄N₂ = 638.81) |
| P1-43 | m/z = 728.28(C₅₄H₃₆N₂O = 728.89) | P1-44 | m/z = 832.29(C₆₁H₄₀N₂S = 833.07) |
| P1-45 | m/z = 691.3(C₅₁H₃₇N₃ = 691.88) | P1-46 | m/z = 726.3(C₅₅H₃₈N₂ = 726.92) |
| P1-47 | m/z = 802.33(C₆₁H₄₂N₂ = 803.02) | P1-48 | m/z = 850.33(C₆₅H₄₂N₂ = 851.06) |
| P1-49 | m/z = 571.32(C₄₃H₄₁N = 571.81) | P1-50 | m/z = 653.4(C₄₉H₅₁N = 653.95) |
| P1-51 | m/z = 713.4(C₅₄H₅₁N = 714.01) | P1-52 | m/z = 751.42(C₅₇H₅₃N = 752.06) |
| P1-53 | m/z = 725.4(C₅₅H₅₁N = 726.02) | P1-54 | m/z = 765.43(C₅₈H₅N = 766.08) |
| P1-55 | m/z = 701.4(C₅₃H₅₁N = 702) | P1-56 | m/z = 697.37(C₅₃H₄₇N = 697.97) |
| P1-57 | m/z = 651.39(C₄₉H₄₉N = 651.94) | P1-58 | m/z = 693.34(C₅₃H₄₃N = 693.93) |
| P1-59 | m/z = 787.42(C₆₀H₅₃N = 788.09) | P1-60 | m/z = 745.46(C₅₆H₅₉N = 746.09) |
| P1-61 | m/z = 635.26(C₄₉H₃₃N = 635.81) | P1-62 | m/z = 743.25(C₅₄H₃₃NO₃ = 743.86) |
| P1-63 | m/z = 681.33(C₅₂H₃₁D₆N = 681.91) | P1-64 | m/z = 710.52(C₅₂H₆D₃₃N = 711.09) |
| P1-65 | m/z = 753.34(C₅₈H₄₃N = 753.99) | P1-66 | m/z = 715.32(C₅₅H₄₁N = 715.94) |
| P1-67 | m/z = 629.27(C₄₇H₃₅NO = 629.8) | P1-68 | m/z = 663.26(C₅₀H₃₃NO = 663.82) |
| P1-69 | m/z = 707.26(C₅₂H₃₇NS = 707.93) | P1-70 | m/z = 717.34(C₅₅H₄₃N = 717.96) |
| P1-71 | m/z = 553.28(C₄₂H₃₅N = 553.75) | P1-72 | m/z = 691.29(C₅₂H₃₇NO = 691.87) |
| P1-73 | m/z = 643.29(C₄₈H₃₇NO = 643.83) | P1-74 | m/z = 709.24(C₅₁H₃₅NOS = 709.91) |
| P1-75 | m/z = 677.31(C₅₂H₃₉N = 677.89) | P1-76 | m/z = 665.4(C₅₀H₅₁N = 665.96) |
| P1-77 | m/z = 643.29(C₄₈H₃₇NO = 643.83) | P1-78 | m/z = 633.21(C₄₅H₃₁NOS = 633.81) |
| P1-79 | m/z = 693.27(C₅₁H₃₅NO₂ = 693.85) | P1-80 | m/z = 719.32(C₅₄H₄₁NO = 719.93) |
| P1-81 | m/z = 699.35(C₅₂H₄₅NO = 699.94) | P1-82 | m/z = 639.29(C₄₉H₃₇N = 639.84) |
| P1-83 | m/z = 645.3(C₄₈H₃₉NO = 645.85) | P1-84 | m/z = 663.39(C₅₀H₄₉N = 663.95) |
| P1-85 | m/z = 617.24(C₄₅H₃₁NO₂ = 617.75) | P1-86 | m/z = 715.4(C₅₁H₁₃D₂₂NO₂ = 715.98) |
| P1-87 | m/z = 699.3(C₅₁H₂₉D₆NO₂ = 699.88) | P1-88 | m/z = 591.18(C₄₂H₂₅NO₃ = 591.67) |
| P1-89 | m/z = 801.34(C₆₂H₄₃N = 802.03) | P1-90 | m/z = 617.27(C₄₆H₃₅NO = 617.79) |
| P1-91 | m/z = 815.33(C₆₁H₄₁N₃ = 816.02) | P1-92 | m/z = 691.3(C₅₁H₃₇N₃ = 691.88) |
| P1-93 | m/z = 757.24(C₅₅H₃₅NOS = 757.95) | P1-94 | m/z = 815.28(C₆₁H₃₇NO₂ = 815.97) |
| P1-95 | m/z = 697.19(C₄₉H₃₁NS₂ = 697.91) | P1-96 | m/z = 781.3(C₅₈H₃₉NO₂ = 781.95) |

### [Synthesis Example 2] Synthesis Example of Formula 2

The compound (final product 2) represented by Formula 2 according to the present invention can be synthesized according to the reaction path of Reaction scheme 2, but is not limited thereto.

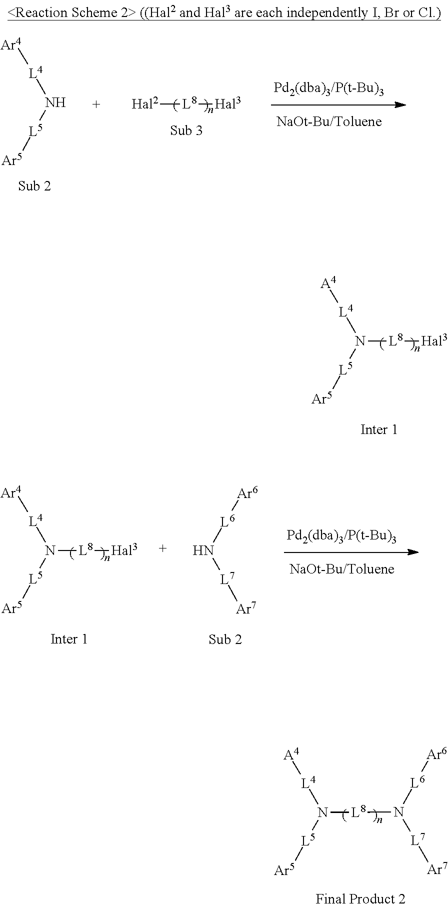

### I. Synthesis of Sub 3

Compounds belonging to Sub 3 of Reaction scheme 2 may be, but are not limited to, the compounds below, and Table 4 shows the FD-MS (Field Desorption-Mass Spectrometry) values of the compounds below.

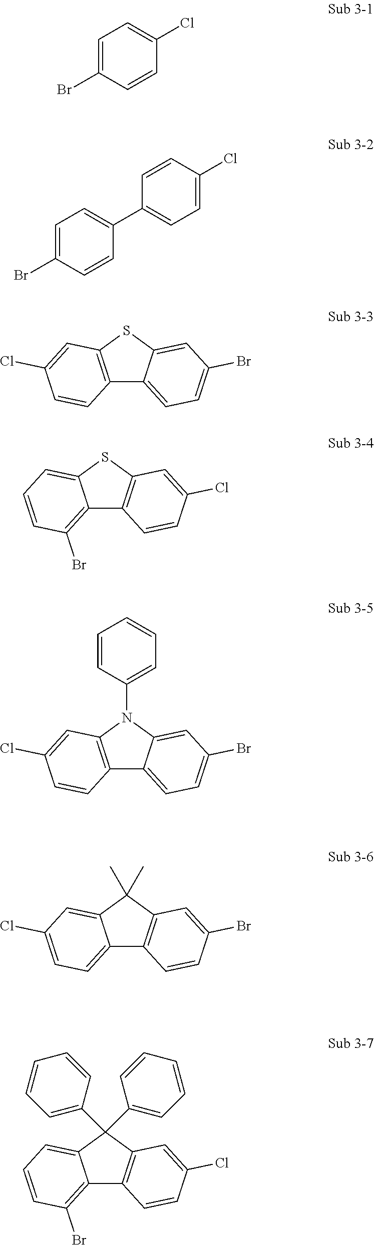

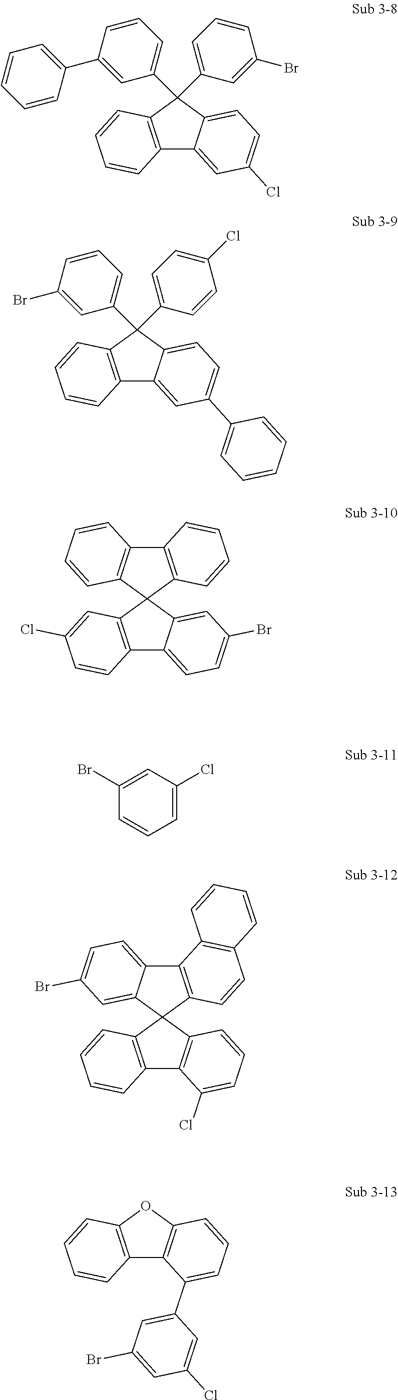 [SMILES: Clc1ccc2c(c1)-c1ccccc1C2(c1cccc(Br)c1)c1cccc(-c2ccccc2)c1 ; Clc1ccc(C2(c3cccc(Br)c3)c3ccccc3-c3cc(-c4ccccc4)ccc32)cc1 ; Clc1ccc2c(c1)C1(c3ccccc3-c3ccccc31)c1cc(Br)ccc1-2 ; Clc1cccc(Br)c1 ; Clc1cccc2c1-c1ccccc1C21c2cc(Br)ccc2-c2c1ccc1ccccc21 ; Clc1cc(Br)cc(-c2cccc3oc4ccccc4c23)c1]

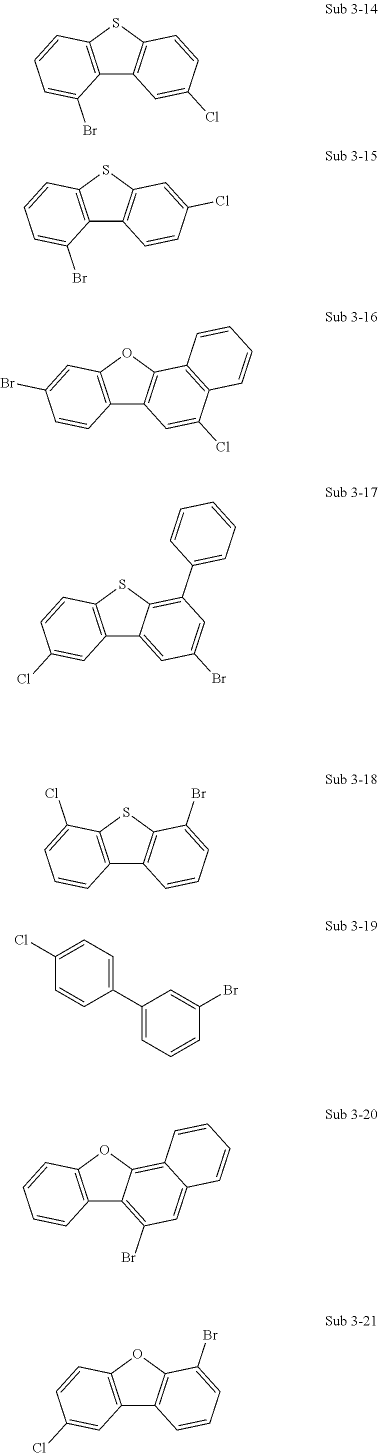

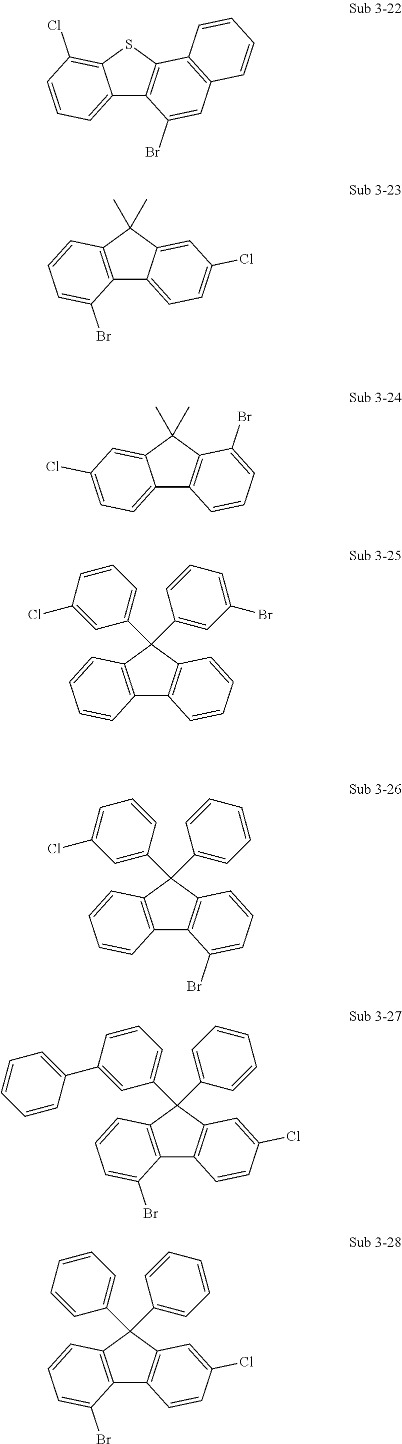

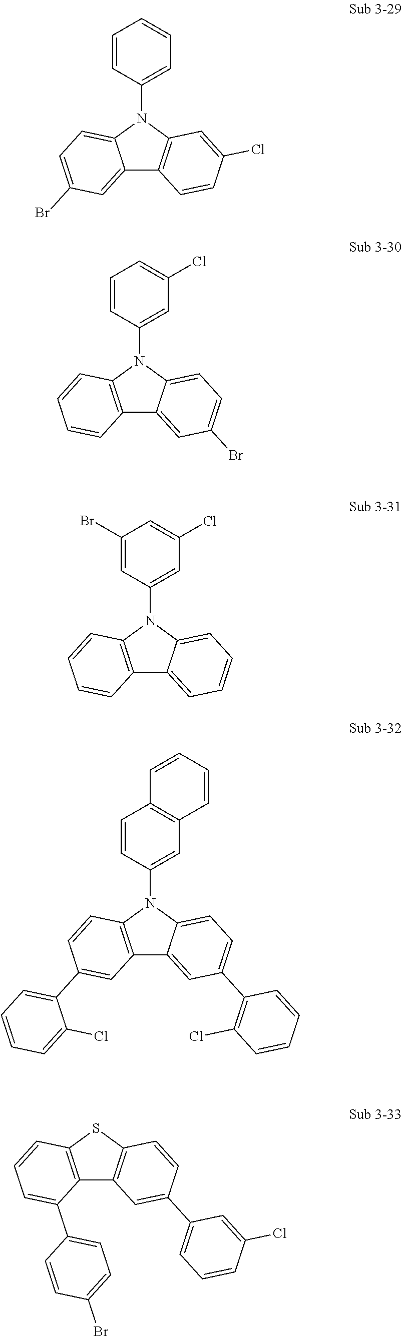 [SMILES: Clc1ccc2c3cc(Br)ccc3n(-c3ccccc3)c2c1 ; Clc1cccc(-n2c3ccccc3c3cc(Br)ccc32)c1 ; Clc1cc(Br)cc(-n2c3ccccc3c3ccccc32)c1 ; Clc1ccccc1-c1ccc2c(c1)c1cc(-c3ccccc3Cl)ccc1n2-c1ccc2ccccc2c1 ; Clc1cccc(-c2ccc3sc4cccc(-c5ccc(Br)cc5)c4c3c2)c1]

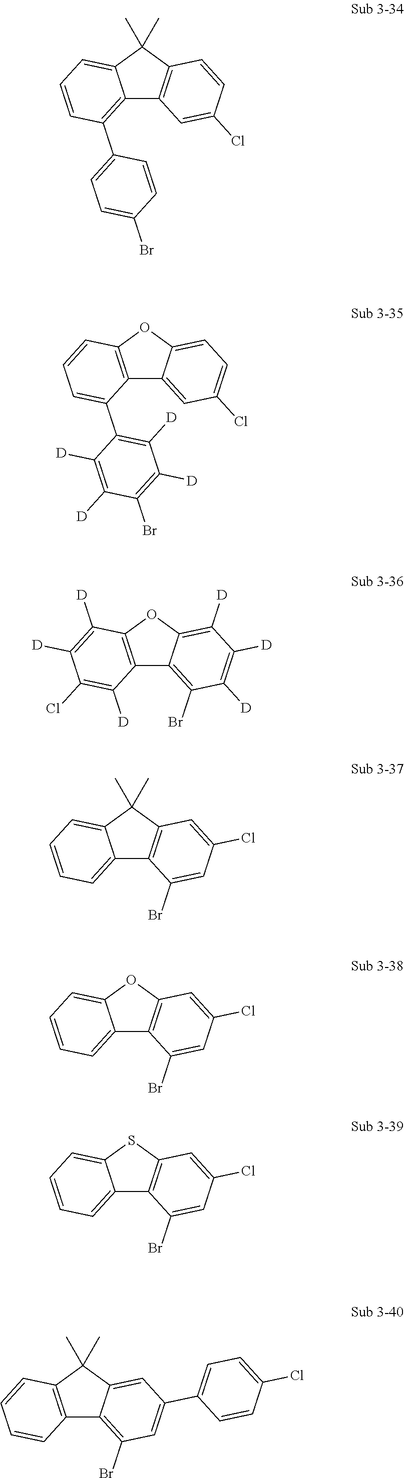

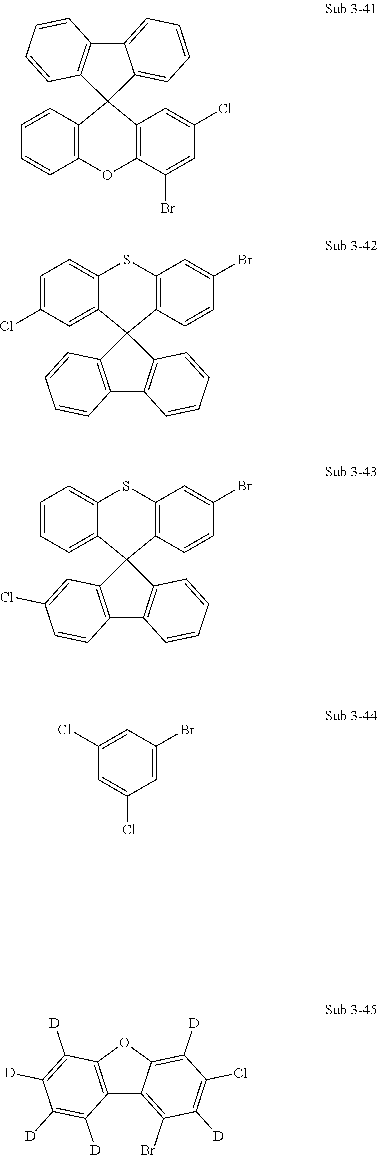 [SMILES: Clc1cc(Br)c2c(c1)C1(c3ccccc3O2)c2ccccc2-c2ccccc21 ; Clc1ccc2c(c1)C1(c3ccc(Br)cc3S2)c2ccccc2-c2ccccc21 ; Clc1ccc2c(c1)C1(c3ccccc3Sc3cc(Br)ccc31)c1ccccc1-2 ; Clc1cc(Cl)cc(Br)c1 ; [2H]c1c([2H])c([2H])c2c(oc3c([2H])c(Cl)c([2H])c(Br)c32)c1[2H]]

TABLE 4

| compound | FD-MS | compound | FD-MS |
|---|---|---|---|
| Sub 3-1 | m/z = 189.92(C₆H₄BrCl = 191.45) | Sub 3-2 | m/z = 265.95(C₁₂H₈BrCl = 267.55) |
| Sub 3-3 | m/z = 295.91(C₁₂H₆BrClS = 297.59) | Sub 3-4 | m/z = 279.93(C₁₂H₆BrClO = 281.53) |
| Sub 3-5 | m/z = 354.98(C₁₈H₁₁BrClN = 356.65) | Sub 3-6 | m/z = 305.98(C₁₅H₁₂BrCl = 307.61) |
| Sub 3-7 | m/z = 430.01(C₂₅H₁₆BrCl = 431.76) | Sub 3-8 | m/z = 506.04(C₃₁H₂₀BrCl = 507.85) |
| Sub 3-9 | m/z = 506.04(C₃₁H₂₀BrCl = 507.85) | Sub 3-10 | m/z = 428(C₂₅H₁₄BrCl = 429.74) |
| Sub 3-11 | m/z = 189.92(C₆H₄BrCl = 191.45) | Sub 3-12 | m/z = 478.01(C₂₉H₁₆BrCl = 479.8) |
| Sub 3-13 | m/z = 355.96(C₁₈H₁₀BrClO = 357.63) | Sub 3-14 | m/z = 295.91(C₁₂H₆BrClS = 297.59) |
| Sub 3-15 | m/z = 295.91(C₁₂H₆BrClS = 297.59) | Sub 3-16 | m/z = 329.94(C₁₆H₈BrClO = 331.59) |
| Sub 3-17 | m/z = 371.94(C₁₈H₁₀BrClS = 373.69) | Sub 3-18 | m/z = 295.91(C₁₂H₆BrClS = 297.59) |
| Sub 3-19 | m/z = 265.95(C₁₂H₈BrCl = 267.55) | Sub 3-20 | m/z = 295.98(C₁₆H₉BrO = 297.15) |
| Sub 3-21 | m/z = 279.93(C₁₂H₆BrClO = 281.53) | Sub 3-22 | m/z = 345.92(C₁₆H₈BrClS = 347.65) |
| Sub 3-23 | m/z = 305.98(C₁₅H₁₂BrCl = 307.61) | Sub 3-24 | m/z = 305.98(C₁₅H₁₂BrCl = 307.61) |
| Sub 3-25 | m/z = 430.01(C₂₅H₁₆BrCl = 431.76) | Sub 3-26 | m/z = 430.01(C₂₅H₁₆BrCl = 431.76) |
| Sub 3-27 | m/z = 506.04(C₃₁H₂₀BrCl = 507.85) | Sub 3-28 | m/z = 430.01(C₂₅H₁₆BrCl = 431.76) |
| Sub 3-29 | m/z = 354.98(C₁₈H₁₁BrClN = 356.65) | Sub 3-30 | m/z = 354.98(C₁₈H₁₁BrClN = 356.65) |
| Sub 3-31 | m/z = 354.98(C₁₈H₁₁BrClN = 356.65) | Sub 3-32 | m/z = 513.11(C₃₄H₂₁Cl₂N = 514.45) |
| Sub 3-33 | m/z = 447.97(C₂₄H₁₄BrClS = 449.79) | Sub 3-34 | m/z = 382.01(C₂₁H₁₆BrCl = 383.71) |
| Sub 3-35 | m/z = 359.99(C₁₈H₆D4BrClO = 361.66) | Sub 3-36 | m/z = 285.97(C₁₂D₆BrClO = 287.57) |
| Sub 3-37 | m/z = 305.98(C₁₅H₁₂BrCl = 307.61) | Sub 3-38 | m/z = 279.93(C₁₂H₆BrClO = 281.53) |
| Sub 3-39 | m/z = 295.91(C₁₂H₆BrClS = 297.59) | Sub 3-40 | m/z = 382.01(C₂₁H₁₆BrCl = 383.71) |
| Sub 3-41 | m/z = 443.99(C₂₅H₁₄BrClO = 445.74) | Sub 3-42 | m/z = 459.97(C₂₅H₁₄BrClS = 461.8) |
| Sub 3-43 | m/z = 459.97(C₂₅H₁₄BrClS = 461.8) | Sub 3-44 | m/z = 223.88(C₆H₃BrCl₂ = 225.89) |
| Sub 3-45 | m/z = 285.97(C₁₂D₆BrClO = 287.57) | | |

### II. Synthesis of Final Product 2

### 1. Synthesis Example of P2-22

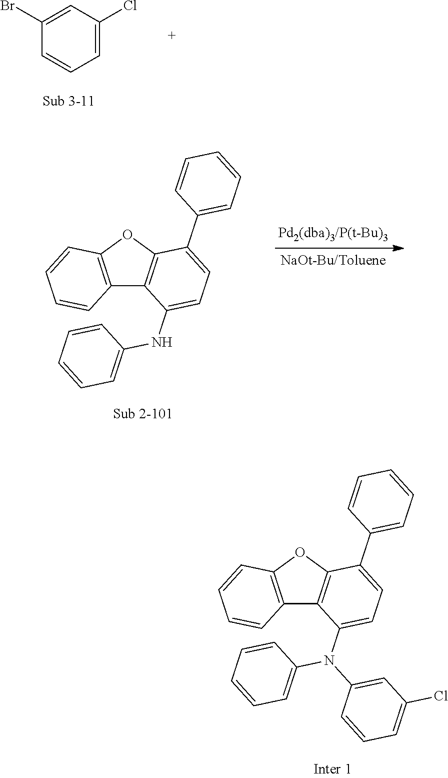 [SMILES: Clc1cccc(Br)c1 ; c1ccc(Nc2ccc(-c3ccccc3)c3oc4ccccc4c23)cc1 ; Clc1cccc(N(c2ccccc2)c2ccc(-c3ccccc3)c3oc4ccccc4c23)c1]

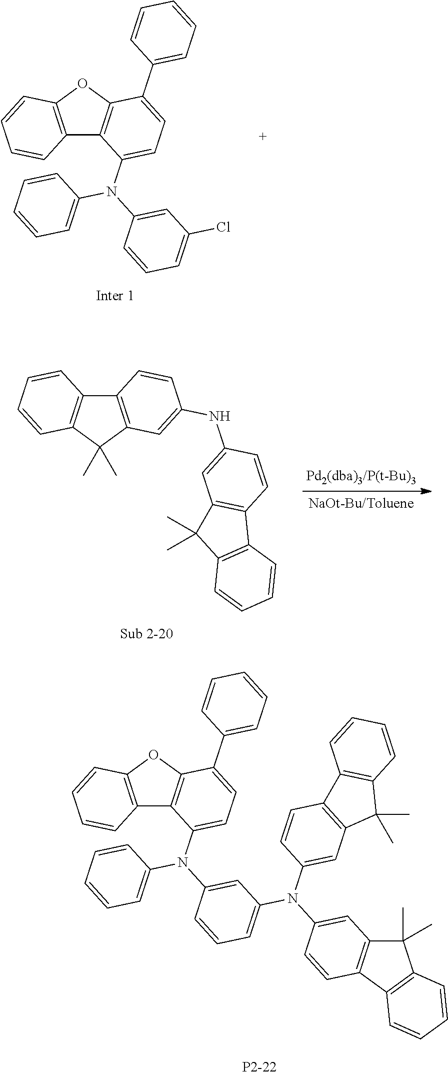 [SMILES: Clc1cccc(N(c2ccccc2)c2ccc(-c3ccccc3)c3oc4ccccc4c23)c1 ; CC1(C)c2ccccc2-c2ccc(Nc3ccc4c(c3)C(C)(C)c3ccccc3-4)cc21 ; CC1(C)c2ccccc2-c2ccc(N(c3cccc(N(c4ccccc4)c4ccc(-c5ccccc5)c5oc6ccccc6c45)c3)c3ccc4c(c3)C(C)(C)c3ccccc3-4)cc21]

### (1) Synthesis of Inter 1

Sub 3-11 (30 g, 156.7 mmol), Toluene (390 mL), Sub 2-101 (52.6 g, 156.7 mmol), Pd₂(dba)₃ (4.3 g, 4.7 mmol), P(t-Bu)₃ (1.9 g, 9.4 mmol), NaOt-Bu (30.1 g, 313.4 mmol) were added and stirred at 50° C. When the reaction was completed, the organic layer was extracted with Toluene and water, dried over MgSO₄, concentrated, and the resulting compound was recrystallized using a silica gel column to obtain the product (49.6 g, 71%).

### (2) Synthesis of P2-22

Inter 1 (20 g, 44.8 mmol), Toluene (110 mL), Sub 2-20 (18.0 g, 44.8 mmol), Pd₂(dba)₃ (1.2 g, 1.3 mmol), P(t-Bu)₃ (0.5 g, 2.7 mmol), NaOt-Bu (8.6 g, 89.7 mmol) were added and stirred at 100° C. When the reaction was completed, the organic layer was extracted with Toluene and water, dried over MgSO₄, concentrated, and the resulting compound was recrystallized using a silica gel column to obtain the product (29.5 g, 81%).

### 2. Synthesis Example of P2-36

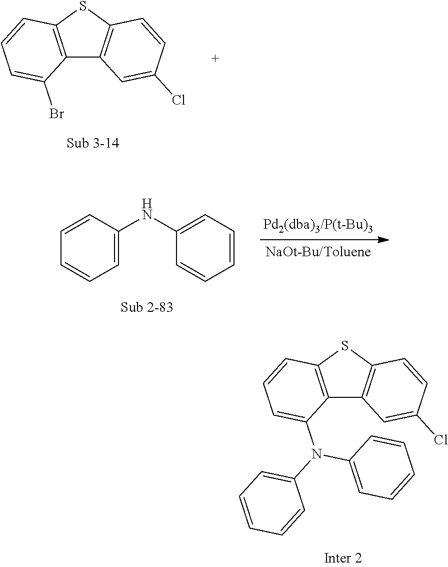

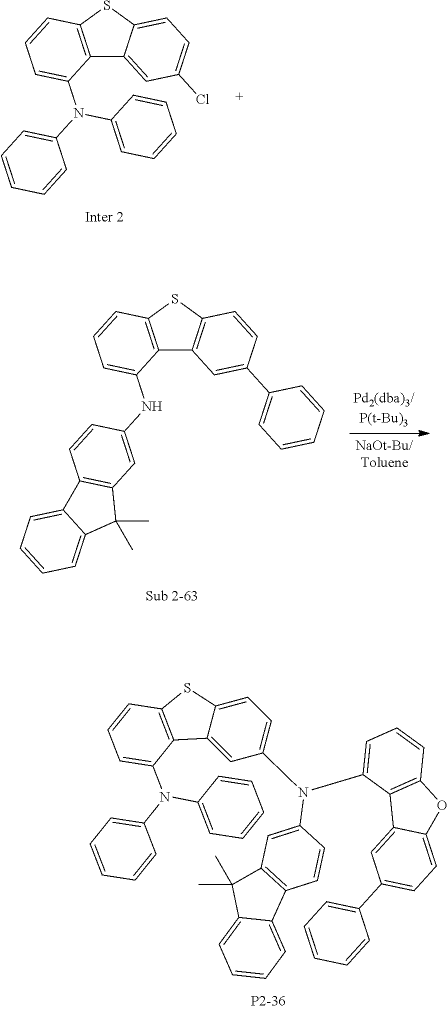

### (1) Synthesis of Inter 2

Sub 3-14 (30 g, 100.8 mmol), Toluene (250 mL), Sub 2-83 (17.1 g, 100.8 mmol), Pd₂(dba)₃ (2.8 g, 3.0 mmol), P(t-Bu)₃ (1.2 g, 6.0 mmol), NaOt-Bu (19.4 g, 201.6 mmol) were added and stirred at 50° C. When the reaction was completed, the organic layer was extracted with Toluene and water, dried over MgSO₄, concentrated, and the resulting compound was recrystallized using a silica gel column to obtain the product (30.7 g, 79%).

### (2) Synthesis of P2-36

Inter 2 (20 g, 51.8 mmol), Toluene (130 mL), Sub 2-63 (23.4 g, 51.8 mmol), Pd₂(dba)₃ (1.4 g, 1.6 mmol), P(t-Bu)₃ (0.6 g, 3.1 mmol), NaOt-Bu (10.0 g, 103.7 mmol) were added and stirred at 100° C. When the reaction was completed, the organic layer was extracted with Toluene and water, dried over MgSO₄, concentrated, and the resulting compound was recrystallized using a silica gel column to obtain the product (32.0 g, 77%).

### 3. Synthesis Example of P2-45

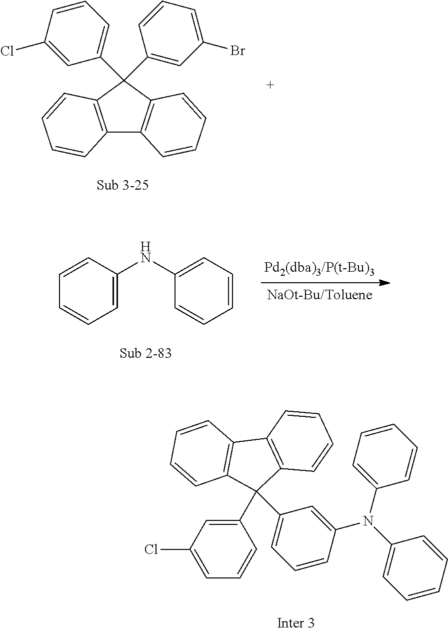

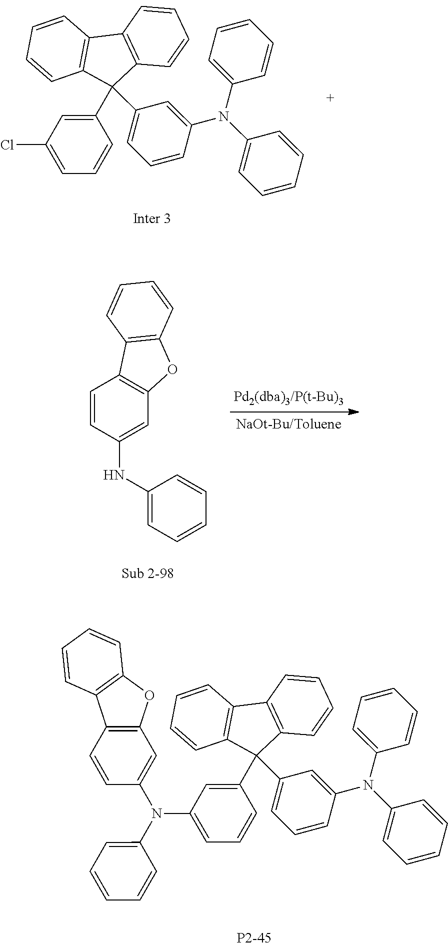

### (1) Synthesis of Inter 3

Sub 3-25 (30 g, 69.5 mmol), Toluene (175 mL), Sub 2-83 (11.8 g, 69.5 mmol), Pd₂(dba)₃ (1.9 g, 2.1 mmol), P(t-Bu)₃ (0.8 g, 4.2 mmol), NaOt-Bu (13.4 g, 139.0 mmol) were added and stirred at 50° C. When the reaction was completed, the organic layer was extracted with Toluene and water, dried over MgSO₄, concentrated, and the resulting compound was recrystallized using a silica gel column to obtain the product (23.8 g, 66%).

### (2) Synthesis of P2-45

Inter 3 (20 g, 38.5 mmol), Toluene (145 mL), Sub 2-98 (10.0 g, 38.5 mmol), Pd₂(dba)₃ (1.1 g, 1.2 mmol), P(t-Bu)₃ (0.5 g, 2.3 mmol), NaOt-Bu (7.4 g, 76.9 mmol) were added and stirred at 100° C. When the reaction was completed, the organic layer was extracted with Toluene and water, dried over MgSO₄, concentrated, and the resulting compound was recrystallized using a silica gel column to obtain the product (20.6 g, 72%).

### 4. Synthesis Example of P2-61

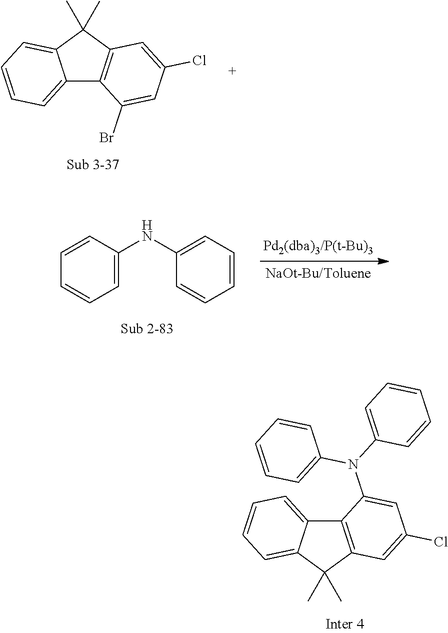

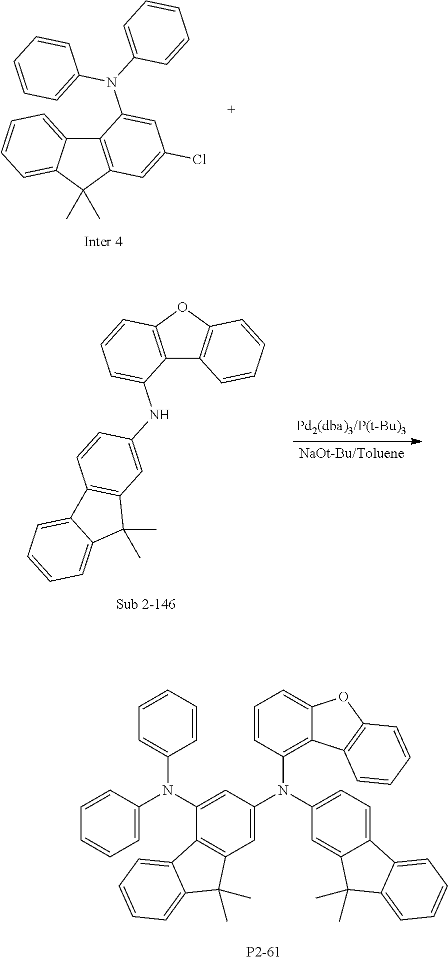

### (1) Synthesis of Inter 4

Sub 3-37 (30 g, 97.5 mmol), Toluene (245 mL), Sub 2-83 (16.5 g, 97.5 mmol), Pd₂(dba)₃ (2.7 g, 2.9 mmol), P(t-Bu)₃ (1.2 g, 5.9 mmol), NaOt-Bu (18.8 g, 195.1 mmol) were added and stirred at 50° C. When the reaction was completed, the organic layer was extracted with Toluene and water, dried over MgSO₄, concentrated, and the resulting compound was recrystallized using a silica gel column to obtain the product (33.2 g, 86%).

### (2) Synthesis of P2-61

Inter 4 (20 g, 50.5 mmol), Toluene (130 mL), Sub 2-146 (19.0 g, 50.5 mmol), Pd₂(dba)₃ (1.4 g, 1.5 mmol), P(t-Bu)₃ (0.6 g, 3.0 mmol), NaOt-Bu (9.7 g, 101.0 mmol) were added and stirred at 100° C. When the reaction was completed, the organic layer was extracted with Toluene and water, dried over MgSO₄, concentrated, and the resulting compound was recrystallized using a silica gel column to obtain the product (27.5 g, 74%).

The FD-MS values of compounds P2-1 to P2-76 of the present invention manufactured according to the synthetic examples are as shown in Table 5.

TABLE 5

| compound | FD-MS | compound | FD-MS |
|---|---|---|---|
| P2-1 | m/z = 716.32(C₅₄H₄₀N₂ = 716.93) | P2-2 | m/z = 792.35(C₆₀H₄₄N₂ = 793.03) |
| P2-3 | m/z = 840.35(C₆₄H₄₄N₂ = 841.07) | P2-4 | m/z = 694.24(C₅₀H₃₄N₂S = 694.9) |
| P2-5 | m/z = 754.3(C₅₆H₃₈N₂O = 754.93) | P2-6 | m/z = 805.35(C₆₀H₄₃N₃ = 806.02) |
| P2-7 | m/z = 768.31(C₅₇H₄₀N₂O = 768.96) | P2-8 | m/z = 858.36(C₆₄H₄₆N₂O = 859.09) |
| P2-9 | m/z = 893.38(C₆₇H₄₇N₃ = 894.13) | P2-10 | m/z = 924.32(C₆₇H₄₄N₂OS = 925.16) |
| P2-11 | m/z = 816.31(C₆₁H₄₀N₂O = 817) | P2-12 | m/z = 865.35(C₆₅H₄₃N₃ = 866.08) |
| P2-13 | m/z = 768.35(C₅₈H₄₄N₂ = 769) | P2-14 | m/z = 634.24(C₄₅H₃₄N₂S = 634.84) |
| P2-15 | m/z = 652.29(C₄₉H₃₆N₂ = 652.84) | P2-16 | m/z = 818.33(C₆₁H₄₂N₂O = 819.02) |
| P2-17 | m/z = 694.3(C₅₁H₃₈N₂O = 694.88) | P2-18 | m/z = 894.36(C₆₇H₄₆N₂O = 895.12) |
| P2-19 | m/z = 742.3(C₅₅H₃₈N₂O = 742.92) | P2-20 | m/z = 856.29(C₆₀H₄₄N₂S₂ = 857.15) |
| P2-21 | m/z = 718.3(C₅₃H₃₈N₂O = 718.9) | P2-22 | m/z = 810.36(C₆₀H₄₆N₂O = 811.04) |
| P2-23 | m/z = 868.35(C₆₅H₄₄N₂O = 869.08) | P2-24 | m/z = 942.36(C₇₁H₄₆N₂O = 943.16) |
| P2-25 | m/z = 886.39(C₆₆H₅₀N₂O = 887.14) | P2-26 | m/z = 796.38(C₆₀H₄₈N₂ = 797.06) |
| P2-27 | m/z = 782.33(C₅₈H₄₂N₂O = 782.99) | P2-28 | m/z = 846.27(C₆₁H₃₈N₂OS = 847.05) |
| P2-29 | m/z = 758.28(C₅₅H₃₈N₂S = 758.98) | P2-30 | m/z = 694.3(C₅₁H₃₈N₂O = 694.88) |
| P2-31 | m/z = 756.31(C₅₆H₄₀N₂O = 756.95) | P2-32 | m/z = 718.26(C₅₂H₃₄N₂O₂ = 718.86) |
| P2-33 | m/z = 850.3(C₆₁H₄₂N₂OS = 851.08) | P2-34 | m/z = 876.35(C₆₄H₄₈N₂S = 877.16) |
| P2-35 | m/z = 840.32(C₆₀H₄₄N₂OS = 841.09) | P2-36 | m/z = 800.29(C₅₇H₄₀N₂OS = 801.02) |
| P2-37 | m/z = 901.31(C₆₄H₄₃N₃OS = 902.13) | P2-38 | m/z = 922.32(C₆₇H₄₂N₂O₃ = 923.08) |
| P2-39 | m/z = 810.36(C₆₀H₄₆N₂O = 811.04) | P2-40 | m/z = 784.31(C₅₇H₄₀N₂O₂ = 784.96) |
| P2-41 | m/z = 1008.33(C₇₀H₄₈N₄S₂ = 1009.3) | P2-42 | m/z = 809.3(C₅₈H₃₉N₃O₂ = 809.97) |
| P2-43 | m/z = 850.39(C₆₃H₅₀N₂O = 851.11) | P2-44 | m/z = 694.3(C₅₁H₃₈N₂O = 694.88) |
| P2-45 | m/z = 742.3(C₅₅H₃₈N₂O = 742.92) | P2-46 | m/z = 818.33(C₆₁H₄₂N₂O = 819.02) |
| P2-47 | m/z = 920.41(C₇₀H₅₂N₂ = 921.2) | P2-48 | m/z = 966.4(C₇₄H₅₀N₂ = 967.23) |
| P2-49 | m/z = 833.34(C₆₁H₄₃N₃O = 834.03) | P2-50 | m/z = 835.3(C₆₀H₄₁N₃S = 836.07) |
| P2-51 | m/z = 997.35(C₇₃H₄₇N₃S = 998.26) | P2-52 | m/z = 779.33(C₅₈H₄₁N₃ = 779.99) |
| P2-53 | m/z = 892.35(C₆₄H₄₈N₂OS = 893.16) | P2-54 | m/z = 978.45(C₇₃H₅₈N₂O = 979.28) |
| P2-55 | m/z = 758.37(C₅₄H₂₂D₁₄N₂O₂ = 758.98) | P2-56 | m/z = 785.3(C₅₄H₂₃D₁₁N₂O₂S = 786.01) |
| P2-57 | m/z = 924.44(C₆₇H₂₈D₁₆N₂O₂ = 925.2) | P2-58 | m/z = 835.32(C₆₀H₄₁N₃O₂ = 836.01) |
| P2-59 | m/z = 925.33(C₆₆H₄₃N₃O₃ = 926.09) | P2-60 | m/z = 891.33(C₆₃H₄₅N₃OS = 892.13) |
| P2-61 | m/z = 734.33(C₅₄H₄₂N₂O = 734.94) | P2-62 | m/z = 832.31(C₆₁H₄₀N₂O₂ = 833) |
| P2-63 | m/z = 1028.31(C₇₃H₄₄N₂O₃S = 1029.23) | P2-64 | m/z = 906.32(C₆₇H₄₂N₂O₂ = 907.09) |
| P2-65 | m/z = 784.31(C₅₇H₄₀N₂O₂ = 784.96) | P2-66 | m/z = 980.31(C₆₉H₄₄N₂O₃S = 981.18) |
| P2-67 | m/z = 784.31(C₅₇H₄₀N₂O₂ = 784.96) | P2-68 | m/z = 938.3(C₆₇H₄₂N₂O₂S = 939.14) |
| P2-69 | m/z = 900.37(C₆₆H₄₈N₂O₂ = 901.12) | P2-70 | m/z = 922.36(C₆₈H₄₆N₂O₂ = 923.13) |
| P2-71 | m/z = 938.3(C₆₇H₄₂N₂O₂S = 939.14) | P2-72 | m/z = 888.32(C₆₄H₄₄N₂OS = 889.13) |
| P2-73 | m/z = 780.3(C₅₄H₃₂D₅N₃OS = 781) | P2-74 | m/z = 849.3(C₆₀H₃₉N₃O₃ = 849.99) |
| P2-75 | m/z = 849.3(C₆₀H₃₉N₃O₃ = 849.99) | P2-76 | m/z = 856.57(C₆₁D₄₀N₂O = 857.25) |

Meanwhile, exemplary synthesis examples of the present invention represented by Formula 1 and Formula 2 have been described, but these are all based on the Buchwald-Hartwig cross coupling reaction, Miyaura boration reaction, Suzuki cross-coupling reaction, Intramolecular acid-induced cyclization reaction (J. mater. Chem. 1999, 9, 2095), Pd(II)-catalyzed oxidative cyclization reaction (Org. Lett. 2011, 13, 5504), and PPh₃-mediated reductive cyclization reaction (J. Org. Chem. 2005, 70, 5014), and it will be easily understood by those skilled in the art that the reaction proceeds even when other substituents defined in Formula 1 are bonded in addition to the substituents specified in the specific synthesis examples.

### Capacitance Measurement

In the present invention, an ALPHA-AN Analyzer was used as an impedance measuring instrument, and a device having a BNC (input)/RF (output) terminal was used as a jig. The measurement conditions were based on a frequency of 500 Hz, the DC voltage was measured from 0 V to 4 V in 0.01 increments, and the AC voltage was set to ±0.1 V.

Capacitance was measured using an organic electronic element configured as shown in FIG. 1, and the difference in capacitance characteristic values was calculated as shown in Equation 2. The capacitance characteristic values measured according to the capacitance measurement method and the photoelectrical characteristics of the organic electronic element are as shown in Table 6.

### Manufacturing and Evaluation of Organic Electronic Elements

### [Example 1] Green Organic Light Emitting Device

After vacuum-depositing N¹-(naphthalen-2-yl)-N⁴,N⁴-bis(4-(naphthalen-2-yl(phenyl)amino)phenyl)-N¹-phenylbenzene-1,4-diamine (hereinafter ‘2-TNATA’) film on top of a 150 nm thick ITO (Indium Tin Oxide) anode formed on an organic substrate, a 10 nm thick hole injection layer was formed, a hole transport layer was formed by vacuum depositing P1-39 as shown in Table 6 to a thickness of 120 nm on the hole injection layer. Compound P1-15 was vacuum-deposited to a thickness of 30 nm on the hole transport layer to form a buffer layer, and then compound P1-86 was vacuum-deposited to a thickness of 10 nm on the buffer layer to form an emitting-auxiliary layer. On the emitting-auxiliary layer, an emitting layer with a thickness of 30 nm was formed by doping 4,4′-N,N′-dicarbazole-biphenyl (hereinafter, CBP) as a host material and tris[2-phenylpyridinato-C2,N]iridium(III) (hereinafter, ‘Ir(ppy)₃’) as a dopant at a weight ratio of 92:8. 2,2′,2″-(1,3,5-benzinetriyl)-tris(1-phenyl-1-Hbenzimidazole) (hereinafter abbreviated as ‘TPBi’) was deposited on the emitting layer to a thickness of 40 nm, LiF was deposited to a thickness of 1 nm to form an electron injection layer, and Mg and Ag were deposited at a weight ratio of 1:9 on the electron injection layer to form a cathode to a thickness of 20 nm.

### [Example 2] to [Example 15] or [Comparative Example 1] to [Comparative Example 2]

An organic electronic element was manufactured in the same manner as in Example 1, except that the compound of the present invention described in Table 6 was used.

The electroluminescence (EL) characteristics were measured using CS-2000 from Minolta by applying a positive DC voltage to the organic electronic elements manufactured in the present invention, and the capacitance was measured using an ALPHA-AN Analyzer impedance measuring instrument manufactured by Novocontrol. The luminescence lifetime of the organic electronic element was measured at room temperature up to T95 (95% of the initial luminance of 100%) using the M6100 equipment manufactured by Mcscience.

Additionally, among the device characteristics of the organic electronic element in Table 1, the driving voltage and current density represent characteristics at 5,000 nit, and the Luminescence efficiency, etc. represent characteristics at 15,000 nit.

The measuring apparatus can evaluate the performance of new materials compared to comparative compounds under identical conditions, without being affected by possible daily fluctuations in deposition rate, vacuum quality or other parameters.

During the evaluation, one batch contains 4 identically prepared OLEDs including a comparative compound, and the performance of a total of 12 OLEDs is evaluated in 3 batches, so the value of the experimental results obtained in this way indicates statistical significance.

TABLE 6

| | | | | | | | | Current | | | |
|---|---|---|---|---|---|---|---|---|---|---|---|
| | Hole | | Emission | Driving | | | | Density | | V_{cmax -} | |
| | Transport | Buffer | Auxiliary | Voltage | Efficiency | V_{cmax} | Vₜᵤᵣₙ₋ₒₙ | (@V_{c(0.8nF)}) | V_{c(0.8nF)} | V_{c(0.8nF)} | T₉₅ |
| | Layer | Layer | Layer | (V) | (cd/A) | (V) | (V) | (mA/cm²) | (V) | (V) | (hr) |
| Comparative | P1-39 | P2-61 | P1-65 | 3.4 | 152.88 | 2.35 | 2.2 | 1.02E−05 | 0.4 | 1.95 | 69 |
| Example (1) | | | | | | | | | | | |
| Comparative | P1-37 | P1-78 | P1-65 | 3.53 | 153.1 | 2.25 | 2.2 | 9.38E−06 | 0.86 | 1.39 | 74 |
| Example (2) | | | | | | | | | | | |
| Example (1) | P1-39 | P1-15 | P1-86 | 3.28 | 179.28 | 2.45 | 2.25 | 1.03E−05 | 1.95 | 0.5 | 92 |
| Example (2) | P1-37 | P2-38 | P1-65 | 3.61 | 169.03 | 2.1 | 2.25 | 7.75E−05 | 1.25 | 0.85 | 86 |
| Example (3) | P1-39 | P1-70 | P2-62 | 3.3 | 166.32 | 2.55 | 2.3 | 1.14E−05 | 2.1 | 0.45 | 97 |
| Example (4) | P1-39 | P2-30 | P2-62 | 3.25 | 179.52 | 2.55 | 2.35 | 7.43E−06 | 2.05 | 0.5 | 93 |
| Example (5) | P1-39 | P2-58 | P2-62 | 3.59 | 167 | 2.7 | 2.3 | 8.02E−05 | 2.13 | 0.57 | 91 |
| Example (6) | P1-75 | P2-36 | P1-72 | 3.66 | 171.38 | 2.15 | 2.35 | 4.38E−05 | 1.36 | 0.79 | 92 |
| Example (7) | P1-39 | P1-69 | P1-86 | 3.31 | 182.71 | 2.45 | 2.2 | 3.76E−05 | 1.83 | 0.62 | 89 |
| Example (8) | P1-37 | P2-36 | P1-65 | 3.25 | 165.4 | 2.35 | 2.15 | 6.31E−06 | 1.12 | 1.23 | 81 |
| Example (9) | P1-39 | P1-70 | P1-85 | 3.24 | 168.05 | 2.35 | 2.1 | 5.43E−06 | 1.38 | 0.77 | 82 |
| Example | P1-39 | P1-70 | P1-88 | 3.59 | 177.9 | 2.6 | 2.4 | 9.48E−04 | 1.94 | 0.66 | 95 |
| (10) | | | | | | | | | | | |
| Example | P1-39 | P2-36 | P2-62 | 3.49 | 179.7 | 2.6 | 2.3 | 6.82.E−04 | 2.2 | 0.4 | 96 |
| (11) | | | | | | | | | | | |
| Example | P1-39 | P2-36 | P2-57 | 3.35 | 177.4 | 2.45 | 2.2 | 6.62E−06 | 2.09 | 0.36 | 92 |
| (12) | | | | | | | | | | | |
| Example | P1-39 | P1-23 | P2-56 | 3.35 | 179.7 | 2.5 | 2.3 | 2.79E−05 | 2.02 | 0.48 | 99 |
| (13) | | | | | | | | | | | |
| Example | P1-39 | P2-36 | P1-89 | 3.44 | 181.1 | 2.6 | 2.3 | 5.56E−04 | 2.15 | 0.45 | 103 |
| (14) | | | | | | | | | | | |
| Example | P1-39 | P2-36 | P1-93 | 3.4 | 203.8 | 2.55 | 2.3 | 3.74E−05 | 2.14 | 0.41 | 117 |
| (15) | | | | | | | | | | | |

As can be seen from the results in Table 6, it can be confirmed that the examples of organic electronic element satisfying Equation 2, which are fabricated by combining various hole transport layers, buffer layers, and emitting-auxiliary layers, have significantly improved element characteristics compared to the comparative examples that do not satisfy Equation 2, and in partl179.7icular, the lifetime is greatly improved.

The timing of V_{c(0.8nF)} and V_{cmax} may vary depending on the interaction of the hole transport layer, buffer layer, and emitting-auxiliary layer, thereby controlling the Hole trap and changing the performance of the organic electronic element. In particular, in terms of lifetime, since the voltage of V_{c(0.8nF)} increases and the range of voltage difference up to V_{cmax} is small, the deterioration of the interface can be minimized through rapid exhaustion of carriers stored inside.

This means that from the perspective of the lifetime of organic electronic elements, having an appropriate level of Capacitance characteristics may be more appropriate for improving element performance, since unconditional rapid carrier consumption can result in an extremely narrow recombination region where Exciton Confinement occurs. Depending on the structure and material properties of the element, appropriate Capacitance characteristics may vary.

Therefore, in the present invention, it was confirmed that the lifetime and efficiency of the element can be improved depending on the values of V_{c(0.8nF)} and V_{cmax} among the Capacitance characteristics.

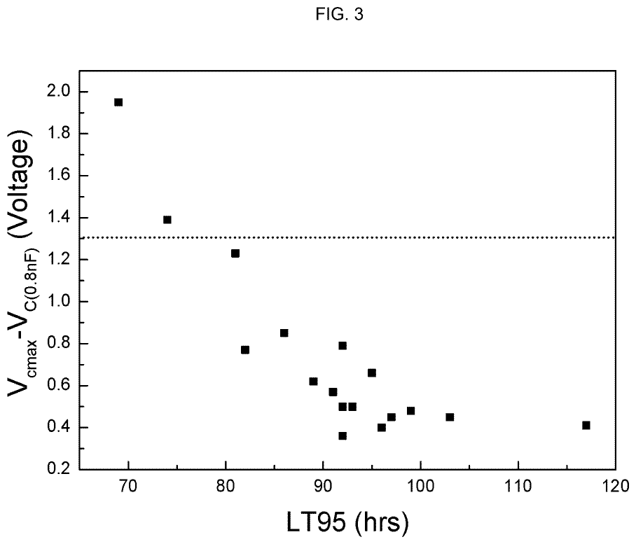

FIG. 3 is a graph showing the lifetime of an organic electronic element according to the V_{Cmax}-V_{C(0.8nF)} value according to one embodiment of the present invention.

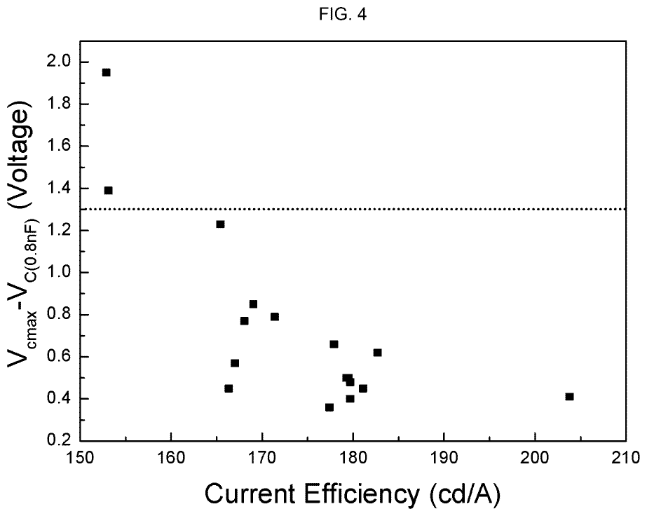

FIG. 4 is a graph showing the efficiency of an organic electronic element according to the V_{Cmax}-V_{C(0.8 nF)} value according to one embodiment of the present invention.

That is, as can be seen in FIGS. 3 and 4, the lifetime and efficiency of the element increase according to the V_{Cmax}-V_{C(0.8nF)} value, and in particular, it can be seen that the lifetime and efficiency increase significantly in an element having a V_{Cmax}-V_{C(0.8nF)} value of 1.3 or less, as in the present invention.

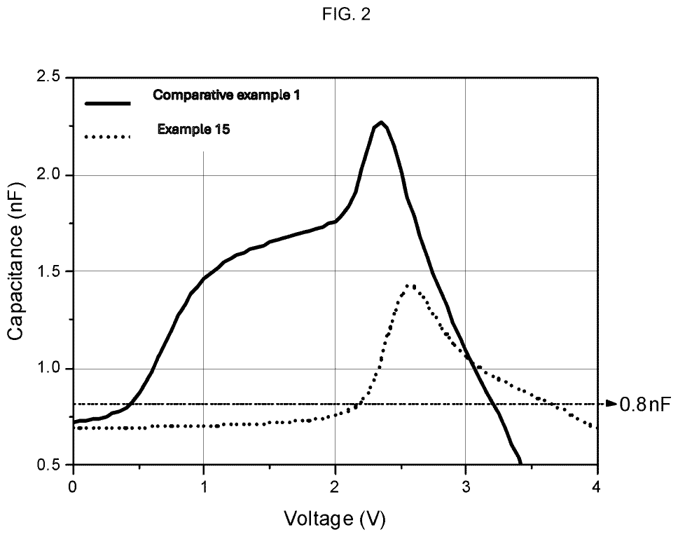

Additionally, FIG. 2 is a graph showing the results of a Capacitance measurement experiment. Example 15 shows that V_{Cmax}-V_{C(0.8nF)} value is less than or equal to 1.3 V, while Comparative Example 1 shows that V_{Cmax}-V_{C(0.8nF)} value exceeds 1.3 V. It appears that when V_{Cmax}-V_{C(0.8nF)} value exceeds 1.3 V, unnecessary charge accumulation at the interface occurs due to an increase in trapped holes. This causes the formation of the exciton recombination zone to move to the interface of the emitting-auxiliary layer, which lowers the charge carrier balance and reduces the emitting efficiency and lifetime. Also, in the case of Comparative Example 1, holes are accumulated more at the interface between the emitting-auxiliary layer and the emitting layer than in Example 15. As the hole accumulation progresses more, the hole release in the emitting layer also occurs more rapidly and excitons are also generated more rapidly, which causes deterioration at the interface between the emitting-auxiliary layer and the emitting layer and roll-off of the efficiency of the entire element. In summary, more stable structure of the organic electronic devices results in a delayed onset of VC(0.8 nF) and a more rapid decrease in capacitance.

In Comparative Example 1, the accumulation of holes started before 1 V, and after the electric capacity increased, a voltage of 2 V or more was consumed for the consumption of internally stored carriers at 3 V or more, but in Example 11, the accumulation of holes started at 2 V or more, and a voltage of about 1 V was consumed for the consumption of internally stored carriers at 3 V or more, so it seems to exhibit excellent characteristics in terms of efficiency and lifetime. It can be understood that organic electronic elements with suitable interactions between the hole transport layer, buffer layer, and emitting-auxiliary layer have a characteristic of rapid decrease in capacitance due to rapid consumption of charged carriers within a short voltage range.

Although exemplary embodiments of the present invention have been described for illustrative purposes, those skilled in the art will appreciate that various modifications, additions and substitutions are possible, without departing from the scope and spirit of the invention as disclosed in the accompanying claims. Therefore, the embodiment disclosed in the present invention is intended to illustrate the scope of the technical idea of the present invention, and the scope of the present invention is not limited by the embodiment.

The scope of the present invention shall be construed on the basis of the accompanying claims, and it shall be construed that all of the technical ideas included within the scope equivalent to the claims belong to the present invention.

What is claimed is:

1. An organic electronic element comprising a first electrode; a second electrode; and an organic material layer comprising an emitting layer formed between the first electrode and the second electrode;
wherein the organic material layer comprises a hole transport layer formed between the first electrode and the emitting layer, and an emitting-auxiliary layer formed between the hole transport layer and the emitting layer, and
wherein the organic electronic element has capacitance characteristics satisfying Equation 2:
$${V}_{cmax} - {V}_{c ( 0.8 nF )} \leq 1.3 V \qquad [ Equation 2 ]$$
1) V_{Cmax} is a voltage value at which the capacitance of an organic electronic element after deposition is measured to be maximum;
2) V_{C(0.8nF)} is a voltage value at which the capacitance of the organic electronic element after deposition is measured to be 0.8 nF.

2. The organic electronic element according to claim 1, wherein the V_{Cmax} is the driving voltage range of exciton recombination of the organic electronic element which is ±0.5 of Vₜᵤᵣₙ₋ₒₙ.

3. The organic electronic element according to claim 1, wherein the range of the V_{C(0.8nF)} is the driving voltage range of the organic electronic element having a current density range of 1.0×10⁻⁷ to 1.0×10⁻⁴ mA/cm².

4. The organic electronic element according to claim 1, wherein a buffer layer is formed between the hole transport layer and the emitting-auxiliary layer.

5. The organic electronic element according to claim 4, wherein at least one of the hole transport layer, the buffer layer and the emitting-auxiliary layer comprises a compound represented by Formula 1 or Formula 2: 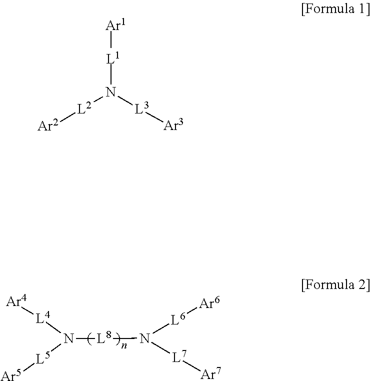
wherein:
L¹, L², L³, L⁴, L⁵, L⁶ and L⁷ are each independently selected from the group consisting of a single bond; a C₆-C₆₀ arylene group; a fluorenylene group; a C₂-C₆₀ heterocyclic group including at least one heteroatom of O, N, S, Si or P; and a fused ring group of a C₃-C₆₀ aliphatic ring and a C₆-C₆₀ aromatic ring;
L⁸ is selected from the group consisting of a C₆-C₆₀ arylene group; a fluorenylene group; a C₂-C₆₀ heterocyclic group including at least one heteroatom of O, N, S, Si or P; and a fused ring group of a C₃-C₆₀ aliphatic ring and a C₆-C₆₀ aromatic ring;
Ar¹, Ar², Ar³, Ar⁴, Ar⁵, Ar⁶ and Ar⁷ are each independently selected from the group consisting of an C₆-C₆₀ aryl group; a fluorenyl group; a C₂-C₆₀ heterocyclic group including at least one heteroatom of O, N, S, Si or P; a fused ring group of a C₃-C₆₀ aliphatic ring and a C₆-C₆₀ aromatic ring; a C₃-C₆₀ aliphatic ring; a C₁-C₆₀ alkyl group; a C₂-C₂₀ alkenyl group; a C₂-C₂₀ alkynyl group; a C₁-C₃₀ alkoxyl group; a C₆-C₆₀ aryloxy group; and -L′-N(R′)(R″); or Ar⁴ and Ar⁵ or Ar⁶ and Ar⁷ can be bonded to each other to form a ring,
wherein L′ is selected from the group consisting of a single bond; a C₆-C₆₀ arylene group; a fluorenylene group; a C₃-C₆₀ aliphatic ring; and a C₂-C₆₀ heterocyclic group including at least one heteroatom of O, N, S, Si or P, and
wherein R′ and R″ are each independently selected from the group consisting of an C₆-C₆₀ aryl group; a fluorenyl group; a C₃-C₆₀ aliphatic ring; and a C₂-C₆₀ heterocyclic group including at least one heteroatom of O, N, S, Si or P,
n is an integer of 1 to 3,
wherein the aryl group, arylene group, heterocyclic group, fluorenyl group, fluorenylene group, fused ring group, aliphatic ring group, alkyl group, alkenyl group, alkynyl group, alkoxy group and aryloxy group may be substituted with one or more substituents selected from the group consisting of deuterium; halogen; a silane group substituted or unsubstituted with a C₁-C₂₀ alkyl group or a C₆-C₂₀ aryl group; a siloxane group; a boron group; a germanium group; a cyano group; a nitro group; a C₁-C₂₀ alkylthio group; a C₁-C₂₀ alkoxyl group; a C₆-C₂₀ aryloxy group; a C₁-C₂₀ alkyl group; a C₂-C₂₀ alkenyl group; a C₂-C₂₀ alkynyl group; a C₆-C₂₀ aryl group; a C₆-C₂₀ aryl group substituted with deuterium; a fluorenyl group; a C₂-C₂₀ heterocyclic group; a C₃-C₂₀ cycloalkyl ring; a C₇-C₂₀ arylalkyl group; a C₈-C₂₀ arylalkenyl group; and -L′-NR′R″, and the hydrogen of the substituents may also be substituted with one or more deuterium, and the substituents may be bonded to each other to form a saturated or unsaturated ring, wherein the term ‘ring’ means a C₃-C₆₀ aliphatic ring or a C₆-C₆₀ aromatic ring or a C₂-C₆₀ heterocyclic group or a fused ring formed by the combination thereof.

6. The organic electronic element according to claim 5, wherein at least one of Ar¹, Ar² and Ar³ and/or at least one of Ar⁴, Ar⁵, Ar⁶ and Ar⁷ is represented by any one of Formulae Ar-a to Ar-d: 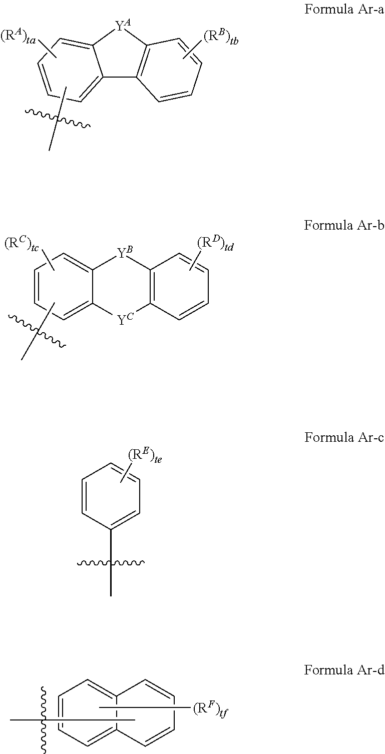
wherein:
Y^{A}, Y^{B} and Y^{C} are each independently O, S, NR^{1A}, Si(R^{1B})(R^{1C}) or C(R^{1B})(R^{1C}),
R^{A}, R^{B}, R^{C}, R^{D}, R^{E}, R^{F}, R^{1A}, R^{1B} and R^{1C} are each the same or different, and each independently selected from the group consisting of hydrogen; deuterium; halogen; a cyano group; a C₆-C₂₀ aryl group; a C₆-C₂₀ aryl group substituted with deuterium; a fluorenyl group; a C₂-C₆₀ heterocyclic group including at least one heteroatom of O, N, S, Si or P; a C₁-C₂₀ alkyl group; a C₂-C₂₀ alkenyl group; a C₂-C₂₀ alkynyl group; a C₁-C₂₀ alkoxyl group; a C₆-C₂₀ aryloxy group; and -L′-N(R′)(R″), or an adjacent plurality of R^{A}s or plurality of R^{B}s or plurality of R^{C}s or plurality of R^{D}s or plurality of R^{E}s or plurality of R^{F}s may be bonded to each other to form a ring, or R^{1B} and R^{1C} can be bonded to each other to form a spiro ring,
ta and tc are each independently an integer of 0 to 3, tb and td are each independently an integer of 0 to 4, te is an integer of 0 to 5, tf is an integer of 0 to 7,
L′, R′ and R″ are the same as defined in claim 5, and [symbol]
indicates the binding position.

7. The organic electronic element according to claim 1, further comprising a light efficiency enhancing layer formed on at least one surface of the first electrode and the second electrode, the surface being opposite to the organic material layer.

8. The organic electronic element according to claim 1, wherein the organic material layer comprises 2 or more stacks comprising a hole transport layer, an emitting layer and an electron transport layer on the first electrode, and at least one of the stacks comprises an emitting auxiliary-layer between the hole transport layer and the emitting layer.

9. The organic electronic element according to claim 8, wherein the organic material layer further comprises a charge generation layer formed between the 2 or more stacks.

10. An electronic device comprising a display device comprising the organic electronic element of claim 1; and a control unit for driving the display device.

11. The electronic device according to claim 10, wherein the organic electronic element is at least one of an OLED, an organic solar cell, an organic photo conductor(OPC), organic transistor (organic TFT) and an element for monochromic or white illumination.
